(19) United States
(12) Patent Application Publication
(10) Pub. No.: US 2010/0075118 A1
(43) Pub. Date: Mar. 25, 2010

(54) RESIN COMPOSITION FOR LASER ENGRAVING, RELIEF PRINTING PLATE PRECURSOR FOR LASER ENGRAVING, RELIEF PRINTING PLATE AND METHOD OF PRODUCING THE SAME

(75) Inventor: Atsushi SUGASAKI, Shizuoka-ken (JP)

Correspondence Address: Solaris Intellectual Property Group, PLLC, 401 Holland Lane, Suite 407, Alexandria, VA, 22314, US

(73) Assignee: FUJIFILM CORPORATION, Tokyo (JP)

(21) Appl. No.: 12/562,155

(22) Filed: Sep. 18, 2009

(30) Foreign Application Priority Data
Sep. 24, 2008 (JP) 2008-244607

(51) Int. Cl. B32B 3/10; G03F 7/004; G03F 7/20

(52) U.S. Cl. 428/195.1; 430/270.1; 430/306; 430/286.1

(57) ABSTRACT

The present invention provides a resin composition for laser engraving, including at least a complex between a layered inorganic compound and a cationic organic compound, and a binder polymer that is insoluble in water and soluble in an alcohol having 1 to 4 carbon atoms; a relief printing plate precursor for laser engraving using the same, a relief printing plate; and a method of producing the relief printing plate.

### CROSS REFERENCE TO RELATED APPLICATION

This application claims priority under 35 USC 119 from Japanese Patent Application No. 2008-244607 filed on Sep. 24, 2008, the disclosure of which is incorporated by reference herein.

### BACKGROUND OF THE INVENTION

1. Field of the Invention

The present invention relates to a resin composition for laser engraving, a relief printing plate precursor for laser engraving, a method of producing a relief printing plate, and a relief printing plate.

2. Description of the Related Art

As a method for forming a printing plate by forming a concave-convex structure on a photosensitive resin layer laminated on the surface of a support, a method of exposing a relief forming layer which has been formed using a photosensitive composition, to ultraviolet radiation through an original image film so as to selectively cure image areas, and removing uncured parts by means of a developer solution, that is, so-called “analogue plate making”, is well known.

A relief printing plate is a letterpress printing plate having a relief layer with a concave-convex structure, and such a relief layer having a concave-convex structure may be obtained by patterning a relief forming layer formed from a photosensitive composition containing, as a main component, for example, an elastomeric polymer such as synthetic rubber, a resin such as a thermoplastic resin, or a mixture of a resin and a plasticizer, to thus form a concave-convex structure. Among such relief printing plates, a printing plate having a flexible relief layer is often referred to as a flexo plate.

In the case of producing a relief printing plate by analogue plate making, since an original image film using a silver salt material is needed in general, the plate making process requires time and costs for the production of original image films. Furthermore, since chemical treatments are required in the development of original image films, and also treatments of development waste water are necessary, investigations on simpler methods of plate making, for example, methods which do not use original image films or methods which do not necessitate development treatments, are being undertaken.

In recent years, a method of making a plate having a relief forming layer by means of scanning exposure, without requiring an original image film, is being investigated. As a technique which does not require an original image film, there has been proposed a relief printing plate precursor in which a laser-sensitive type mask layer element capable of forming an image mask is provided on a relief forming layer (see, for example, Japanese Patent No. 2773847 and Japanese Patent Application Laid-Open (JP-A) No. 9-171247). The method of making such a plate precursor is referred to as a “mask CTP method”, because an image mask having the same function as the original image film is formed from the mask layer element by means of laser irradiation that is based on image data. This method does not require an original image film, but the subsequent plate making treatment involves a process of exposing the plate precursor to ultraviolet radiation through an image mask, and then removing uncured parts by development, and from the viewpoint of requiring a development treatment, the method has a room for further improvement.

As a method of plate making which does not require a development process, a so-called “direct engraving CTP method”, in which plate making is carried out by directly engraving a relief forming layer using laser, has been proposed a number of times. The direct engraving CTP method is literally a method of forming a concave-convex structure which will serve as relief, by engraving the structure with laser. This method is advantageous in that the relief shape can be freely controlled, unlike the relief formation processes using original image films. For this reason, in the case of forming images like cutout characters, it is possible to engrave the image regions deeper than other regions, or for microdot images, to carry out shouldered engraving in consideration of resistance to the printing pressure, or the like. Hitherto, as the plate material which has been used in the direct engraving CTP, a number of various plate materials have been proposed, for example, U.S. Pat. No. 5,798,202, JP-A No. 2002-3665, Japanese Patent No. 3438404, JP-A No. 2004-262135, JP-A No. 2001-121833, JP-A No. 2006-2061, JP-A No. 2007-148322, and the like.

The resin composition for laser engraving used in the direct engraving CTP method generates an engraving residue, which is formed from a low molecular weight polymerizable compound or the like, when a relief forming layer is directly subjected to platemaking with laser light. Since the presence of engraving residue on the surface of a plate after platemaking seriously affects print quality, it is necessary to facilitate removal of any engraving residue that is generated. In order to facilitate the removal of engraving residue, for example, JP-A 2008-31414 discloses a laser-degradable resin composition containing a complex formed between a layered inorganic compound and an organic compound. By this laser-degradable resin composition, the ability to remove generated engraving residue can be improved. However, this laser-degradable resin composition does not always exhibit sufficient engraving sensitivity since the binder polymer in the resin composition is mainly +a synthetic rubber such as SBR (styrene-butadiene co-polymer) and the like, and there has been demand for further improvement in engraving sensitivity upon laser engraving.

### SUMMARY OF THE INVENTION

The present invention has been made in view of the circumstances described above.

A first aspect of the invention is to provide a resin composition for laser engraving, comprising at least a complex formed between a layered inorganic compound and a cationic organic compound, and a binder polymer that is insoluble in water and soluble in an alcohol having 1 to 4 carbon atoms.

A second aspect of the invention is to provide a relief printing plate precursor for laser engraving, which has a relief forming layer containing the resin composition for laser engraving of the invention.

A third aspect of the invention is to provide a method of producing a relief printing plate, the method including: (1) crosslinking the relief forming layer in the relief printing plate precursor for laser engraving of the invention by applying light or heat, and (2) laser engraving the relief forming layer that has been subjected to crosslinking to form a relief layer.

A fourth aspect of the invention is to provide a relief printing plate having a relief layer, which is produced by the method of producing a relief printing plate of the invention.

### BRIEF DESCRIPTION OF THE DRAWING

FIG. 1 is a schematic constitution view (perspective view) showing a platemaking device provided with a semiconductor laser recording device equipped with a fiber, which may be applied to the invention.

### DETAILED DESCRIPTION OF THE INVENTION

Hereinafter, the resin composition for laser engraving, the relief printing plate precursor for laser engraving, the relief printing plate and the method of producing a relief printing plate according to the present invention will be described in detail.

In the present specification “ . . . to . . . ” represents a range including the numeral values represented before and after “to” as a minimum value and a maximum value, respectively.

1. Resin Composition for Laser Engraving

The resin composition for laser engraving of the invention (hereinafter, may also be referred to as the “resin composition of the invention”) contains at least (A) a complex formed between a layered inorganic compound and a cationic organic compound, and (B) a binder polymer insoluble in water and soluble in an alcohol having 1 to 4 carbon atoms.

The resin composition of the invention is a resin composition that can be polymerized and cured by heat energy. The action mechanism of the resin composition of the invention is not clear, but it is thought to be as follows:

First, the reason why the resin composition of the invention has an excellent ability to remove engraving residue generated by engraving is thought to be as follows: That is, it is thought that (A) a complex formed between a layered inorganic compound and a cationic organic compound in the invention is finely dispersed in a delaminated state in the resin composition of the invention, as will be described later, and when a film produced from the resin composition is subsequently laser engraved, the cationic organic compound contained in the complex is thermally decomposed and, as a result, holes are formed at positions where the organic compound existed between delaminated layers, and engraving residue generated by engraving is adsorbed into the holes, thereby improving the ability to remove engraving residue.

The resin composition of the invention can exhibit excellent engraving sensitivity by using at least (A) a complex formed between a layered inorganic compound and a cationic organic compound, and (B) a binder polymer that is insoluble in water and soluble in an alcohol having 1 to 4 carbon atoms. In this respect, it is thought that the layered inorganic compound contained in the complex is classified as a layered silicate as described later, and Al ions and Mg ions necessarily contained in the layered silicate act on heteroatoms and electron-enriched moieties in the binder polymer, thereby lowering the energy of covalent bonding, thus inducing a reduction in the thermal decomposition temperature of the binder polymer, resulting in improvement in engraving sensitivity.

That is, it is thought that the engraving sensitivity is improved because (A) a complex formed between a layered inorganic compound and a cationic organic compound acts as a catalyst for thermal decomposition with respect to (B) a binder polymer that is insoluble in water and soluble in an alcohol having 1 to 4 carbon atoms and has an ether bond or a polar group such as a hydroxyl group. In this regard, employment of a synthetic rubber as a binder polymer does not exhibit improved engraving sensitivity since (A) a complex formed between a layered inorganic compound and a cationic organic compound cannot act as a catalyst for thermal decomposition with respect to the synthetic rubber that does not have an ether bond or a polar group.

The resin composition of the invention is highly sensitive to engraving when subjected to laser engraving, thus enabling laser engraving at high speed, whereby the engraving time of laser engraving can be reduced.

The resin composition of the invention having such properties can, without particular limitation, be applied widely for forming a resin molded product to be subjected to laser engraving. For example, the resin composition of the invention, although its application is not particularly limited, can be applied specifically to a relief forming layer in a relief printing plate precursor for forming a convex relief by laser engraving, as well as to an intaglio printing plate, a stencil printing plate and a stamp. The resin composition of the invention can be used particularly preferably in forming a relief forming layer in a relief printing plate precursor for laser engraving.

Hereinafter, the constituent elements of the resin composition for laser engraving of the invention will be described.

(A) Complex Formed Between a Layered Inorganic Compound and a Cationic Organic Compound

The resin composition of the invention contains a complex formed between a layered inorganic compound and a cationic organic compound (hereinafter, may also be referred to as the “specific complex”). Hereinafter, the specific complex will be described in detail.

(Layered Inorganic Compound)

The layered inorganic compound in the specific complex means a compound that is classified as a layered silicate, and is not particularly limited as long as it is included in the layered silicate.

Specific examples of the layered inorganic compound are preferably those belonging to a kaolinite group, a pyrophyllite group, a talc group, a smectites group, a vermiculite group, and a mica group, from the viewpoint of easy formability of a complex with a cationic organic compound. Particularly, the layered inorganic compounds are more preferably (i) kaolinite, dickite, halloysite, chrysotile, lizardite and amesite belonging to the kaolinite group, (ii) pyrophyllite belonging to the pyrophyllite group, (iii) talc belonging to the talc group, (iv) montmorillonite, hectorite and saponite belonging to the smectite group and (v) white mica and black mica belonging to the mica group. The layered inorganic compounds are even more preferably (iv) montmorillonite, hectorite and saponite belonging to the smectite group, and (v) white mica and black mica belonging to the mica group, most preferably (iv) montmorillonite and hectorite belonging to the smectite group.

The layered inorganic compound may be a natural or synthetic product or a combination of natural and synthetic products. From the viewpoint of improving its interaction with a cationic organic compound, the layered inorganic compound is preferably swellable rather than non-swellable.

It is meant by “the layered inorganic compound is swellable” that the turbidity of the layered inorganic compound, as determined by placing it at a concentration of 0.1 to 20% by mass in water or an organic solvent, stirring it for 10 minutes at room temperature and then measuring its turbidity with a turbidimeter (integrating spherical turbidimeter manufactured by Mitsubishi Chemical Corporation), is 1000 ppm or less. The swellable layered compound is preferably selected from the group consisting of talc, montmorillonite, hectorite, saponite, white mica, and black mica.

From the viewpoint of keeping the excellent water dispersibility, the amount of the layered inorganic compound in the specific complex is preferably from 0.05 to 80% by mass, more preferably from 0.1 to 50% by mass, particularly preferably from 0.5 to 20% by mass, relative to the total mass of the specific complex.

(Cationic Organic Compound)

The cationic organic compound in the specific complex may be a low- or high-molecular compound or a combination thereof. The cationic organic compound is preferably a high-molecular compound from the viewpoint of improving the strength of a film formed by the resin composition of the invention.

When the cationic organic compound is a low-molecular compound, the low-molecular compound is preferably an ammonium salt. The ammonium salt is preferably one containing an organized ammonium cation. The ammonium salt is more preferably one having an alkyl group and/or an alkyleneglycol group in its cation moiety, particularly preferably an ammonium salt having both an alkyl group and an alkyleneglycol group in its cation moiety. The alkyl group included in the cation moiety of the ammonium salt may be any of alkyl groups having various numbers of carbon atoms depending on an organic solvent that can be contained in the resin composition of the invention. From the viewpoint of film strength, the alkyl group is preferably an alkyl group having 1 to 30 carbon atoms, more preferably an alkyl group having 1 to 20 carbon atoms, even more preferably an alkyl group having 1 to 15 carbon atoms. From the same viewpoint as that of the alkyl group, the alkyleneglycol group included in the cation moiety of the ammonium salt is preferably an ethyleneglycol group or a propyleneglycol group.

Hereinafter, specific examples of the cationic organic compound that is a low-molecular compound are shown below, but the invention is not limited thereto.

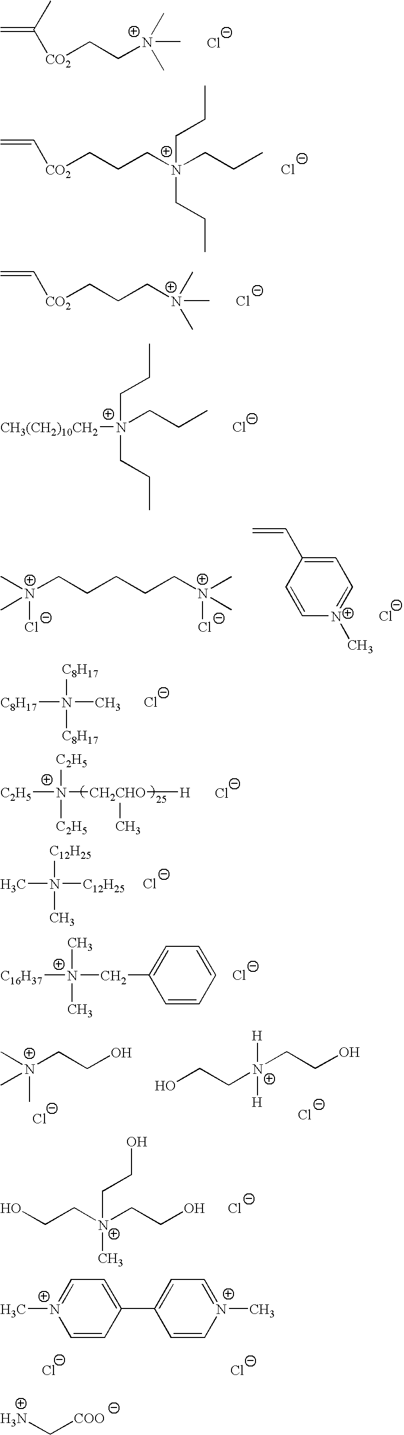

When the cationic organic compound is a high-molecular compound, its main-chain structure is not particularly limited as long as it has a cationic group-containing unit, and various skeletons can be applied. From the viewpoint of ease of synthesis, the high-molecular compound is preferably a (meth)acrylic resin, an urethane resin, a styryl resin or an acetal resin, each of which has a cationic group-containing unit. The weight-average molecular weight (polystyrene-equivalent molecular weight by GPC) of the high-molecular compound is generally from 1000 to 1000000, preferably from 5000 to 500000.

The high-molecular compound that is the cationic organic compound is more preferably a (meth)acrylic resin, an urethane resin or a styryl resin, each of which has a cationic group-containing unit, from the viewpoint of easy introduction of various functional groups into its side chain. The high-molecular compound is even more preferably a (meth)acrylic resin or an urethane resin, most preferably a (meth)acrylic resin.

The high-molecular compound that is the cationic organic compound is more preferably one having a cationic functional group in its side chain, and is particularly preferably one having an ammonium group as the cationic functional group. Examples of the cationic organic compound include a cationic polymer having a structure in which a small amount of ammonium groups are introduced into the polymer described in paragraphs (0033) to (0050) in JP-A No. 2008-31414.

The content (calculated assuming that the sum of total monomers in the starting material of the high-molecular compound is 100 mol%) of the cation group-containing unit in the high-molecular compound that is the cationic organic compound is from 0.01 to 50 mol %, more preferably from 0.1 to 30 mol %, particularly preferably from 1 to 15 mol %, from the viewpoint of preventing a reduction in the strength of a film of the resin composition.

Hereinafter, specific examples of the cationic organic compound that is the high-molecular compound are shown below, but the invention is not limited thereto.

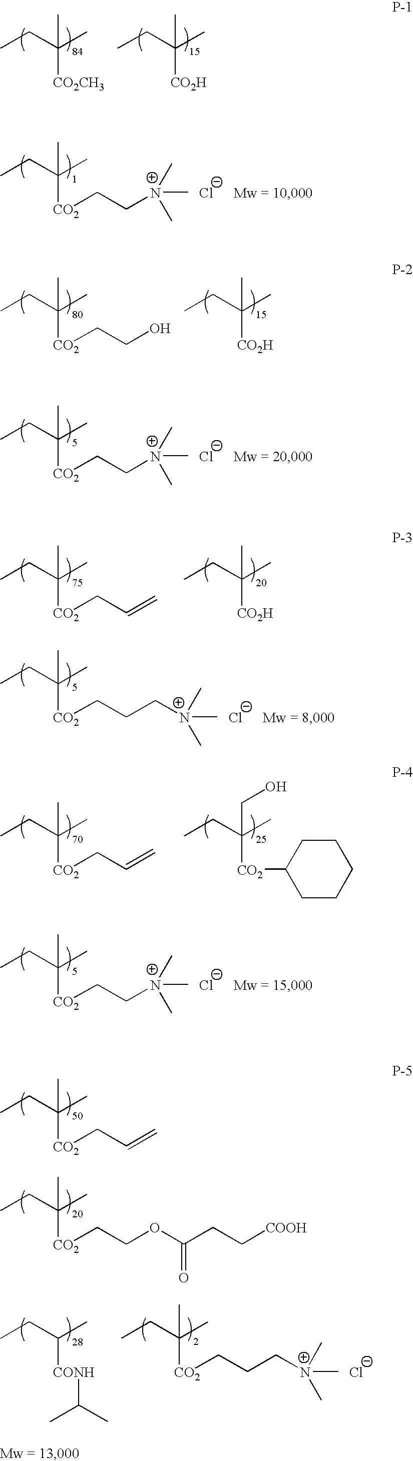

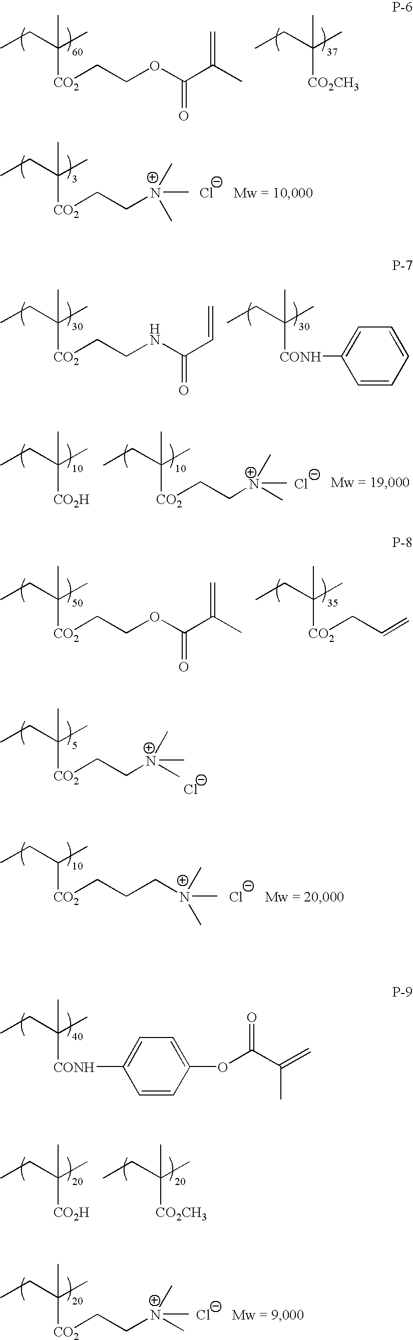

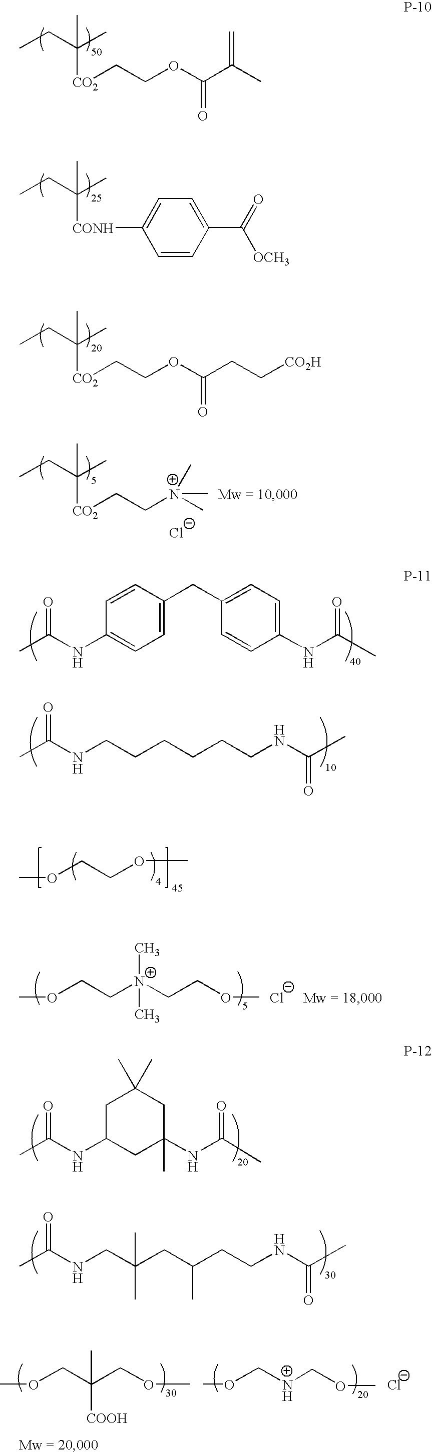

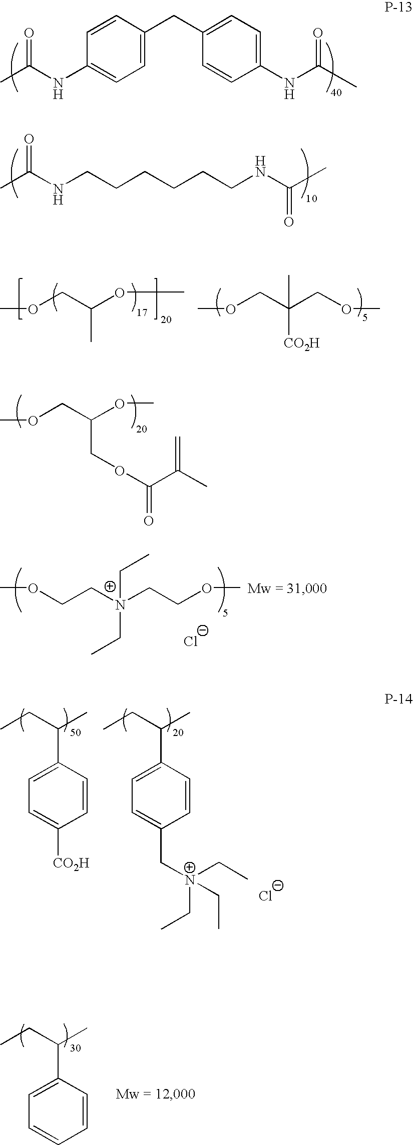

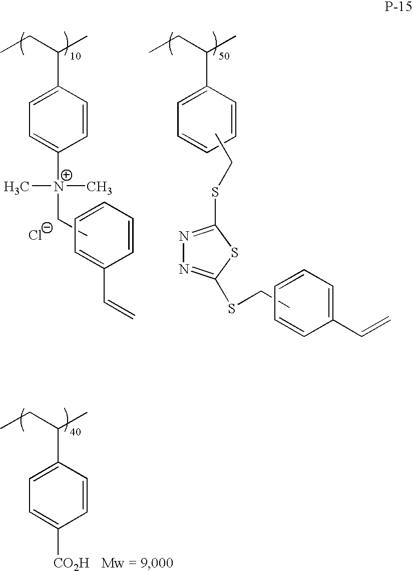

The specific complex is particularly preferably a complex between a swellable layered inorganic compound and a cationic organic compound, from the viewpoints of improving water dispersibility in the resin composition and improving the ability to remove engraving residue generated during laser engraving.

When the layered inorganic compound is swellable, the laminated inorganic compound is swollen with a medium and released, thereby exposing the charge at the surface of the inorganic compound and solvating the inorganic compound, resulting in efficient interaction with the organic compound to form a complex. This complex is in a form having an inorganic compound (a moiety that promotes water dispersion) combined with an organic compound (a moiety that promotes mixing with another coexistent polymer), and can thus be mixed at the molecular level with the coexistent other polymer (which in the invention, is the binder polymer), so that in the resulting resin composition of the complex and the binder polymer, the inorganic compound is finely dispersed in the polymer binder. Accordingly, the excellent water-dispersibility of the inorganic compound is thought to promote the dispersion of the binder polymer in water.

When the organic compound is cationic, its interaction with the negative charge of the layered inorganic compound is improved, thereby effectively forming a complex. As a result, the fine dispersion of the inorganic compound is promoted, and as with the case described above, the excellent water dispersibility of the inorganic compound is thought to promote the dispersion of the binder polymer in water.

When the layered inorganic compound is swellable, and the organic compound is cationic, in the specific complex, the working effects described above are thought to be synergistically exhibited.

The specific complex is preferably formed via a process of mixing the layered inorganic compound with the cationic organic compound in a medium.

The medium may be water or an organic solvent. The organic solvent is not particularly limited. From the viewpoint of easily dispersing the layered inorganic compound in forming the complex, the organic solvent includes 1-methoxy-2-propanol, 1-butanone, N,N-dimethylacetamide, N,N-dimethylformamide, dimethylsulfoxide, 1-methyl-2-pyrrolidone, acetone, alcohol solvents (methanol, ethanol, 2-propanol, and the like), tetrahydrofuran, γ-butyrolactone, and the like.

A mixed medium of water and an organic solvent is also preferably used. The ratio of water to an organic solvent can be regulated appropriately depending on properties such as hydrophilicity and hydrophobicity of the layered inorganic compound and organic compound used. For circumventing the deterioration of workability by preventing precipitation of the complex during formation, the water/organic solvent ratio (by mass) is preferably 95/5 to 5/95, more preferably 80/20 to 20/80 (by mass), even more preferably 70/30 to 30/70 (by mass).

The process of mixing the layered inorganic compound with the cationic organic compound is not particularly limited and can be carried out by an arbitrary method. For example, a container such as a sample bottle is charged with a medium in an amount of about 1 to 100 parts by mass per part of the cationic organic compound, and then the layered inorganic compound and the organic compound are added in a desired ratio and stirred at room temperature to 50° C. for about 1 to 5 hours. By so doing, the specific complex can be prepared as a dispersion.

The specific complex may be a commercial product. Examples of the commercial product include Lucentite SPN, Lucentite SEN, Lucentite STN, Lucentite SAN, Lucentite STN, Somasif MEE, Somasif MTE, and Somasif MAE (all manufactured by Co-op Chemical Co., Ltd.).

The specific complex may be contained alone or as a mixture of two or more thereof in the resin composition of the invention.

The content of the specific complex in the resin composition of the invention is preferably 0.01 to 99.9% by mass, more preferably 0.1 to 95% by mass, even more preferably 1 to 80% by mass, based on the total solid content of the resin composition.

(B) Binder Polymer Being Insoluble in Water and Soluble in an Alcohol having 1 to 4 Carbon Atoms

The resin composition of the invention contains a binder polymer that is that is insoluble in water and soluble in an alcohol having 1 to 4 carbon atoms (hereinafter may be referred to as the “specific binder polymer”). Hereinafter, the alcohol having 1 to 4 carbon atoms may be referred to as a lower alcohol.

The engraving sensitivity of the resin composition of the invention can be improved by using both of the specific binder polymer and the specific complex. Its supposed action mechanism is as described above.

The specific binder polymer has a characteristic being highly polar but water-insoluble, so that when the resin composition of the invention is used in a relief forming layer in the relief printing plate precursor in a preferable exemplary embodiment of the invention, both aqueous ink suitability and UV ink suitability may be achieved.

When the specific binder polymer is used, an action mechanism which may achieve both aqueous ink suitability and UV ink suitability is not clear, but it is thought to be as follows.

Since the specific binder polymer is water-insoluble, its suitability for aqueous ink is enhanced, and the binder swells in the aqueous ink during printing so that the binder may prevent low molecular weight components in the relief layer from bleeding out, and thus prevent the film strength from being decreased. Furthermore, since the specific binder polymer is soluble in alcohol, the alcohol molecules in the solvent that is used at the time of forming a relief forming layer have high affinity to this specific binder polymer. As a result, it is supposed that the chain-like structure of the specific binder polymer may be broken down; that is, voids at the molecular level may be effectively formed in the polymer structure. Thereby, it becomes easy for the components for combined use that are contained in the relief forming layer to penetrate into the broken-down parts of the specific binder polymer as described above, that is, the voids at the molecular level, and a homogeneous relief forming layer in which the specific binder polymer and other components are mixed at the molecular level may be obtained. Thus, it is supposed that, as a result, the specific binder polymer imparts properties whereby such a relief forming layer is less likely to be subject to damage attributable to penetration of various inks, as compared to films that are not homogeneous at the molecular level.

Herein, in the invention, the term “insoluble” in a predetermined liquid refers to that when 0.1 g of a binder polymer and 2 ml of a predetermined liquid (e.g. water or organic solvent) are mixed, sealed, allowed to stand at room temperature for 24 hours, and observed visually, precipitation of the binder polymer is recognized, or precipitation is not recognized but the solution (dispersion) is cloudy. The term “soluble” refers to the case where, under the above condition, when observed visually, there is no precipitate, and a transparent and uniform state is given.

The specific binder polymer in the invention is required to be soluble in an alcohol having 1 to 4 carbon atoms. Examples of the alcohol having 1 to 4 carbon atoms include methanol, ethanol, 2-propanol, 1-propanol, 1-methoxy-2-propanol, 1-butanol, and tert-butanol from a viewpoint of good UV ink suitability. The specific binder polymer is preferably soluble in at least one of these alcohols.

The specific binder polymer is more preferably soluble in at least one of methanol, ethanol, 2-propanol, and 1-methoxy-2-propanol, and particularly soluble in all of methanol, ethanol, and 1-methoxy-2-propanol.

The specific binder polymer is more preferably insoluble in an ester solvent such as ethyl acetate. When the specific binder polymer which is insoluble in the ester solvent is selected, UV ink suitability of the invention is further improved. Thereby, a phenomenon of elution of low molecular components from the relief layer due to swelling of the relief layer by a UV ink during printing can be suppressed so that the deterioration of the film strength of the relief forming can be prevented.

The glass transition temperature of the specific binder polymer is preferably from 20° C. to 200° C., more preferably from 20° C. to 170° C., particularly preferably from 25° C. to 150° C. from a viewpoint of balance between an engraving sensitivity and film forming property.

In the invention, a glass transition temperature (Tg) of room temperature or higher refers to a Tg of 20° C. or higher.

In case of the specific binder polymer which is used in the invention has the above range of the glass transition temperature, when the polymer is combined with (E) a photothermal conversion agent described later, which is a preferable additional component for constituting the relief forming layer in the invention, and which may absorb light having a wavelength of 700 nm to 1300 nm, an engraving sensitivity is improved. The binder polymer having such a glass transition temperature is referred to as “non-elastomer”, hereinafter.

That is, the elastomer is generally academically defined as a polymer having a glass transition temperature of a normal temperature or lower (see, Kagaku Daijiten second edition, edited by Foundation for Advancement of International Science, published by Maruzen, p. 154). Therefore, the non-elastomer refers to a polymer having a glass transition temperature higher than a normal temperature.

When a glass transition temperature of the specific binder polymer is room temperature (20° C.) or higher, since the specific binder polymer has a glass state at a normal temperature, the specific binder polymer is in the state where thermal molecular movement is considerably suppressed as compared with the case where the specific binder polymer has a rubber state.

In laser engraving on the relief printing plate precursor of the invention, at laser irradiation (preferably, at infrared laser irradiation), applied heat and heat produced by the function of a (E) photothermal conversion agent optionally used are transmitted to the specific binder polymer at the periphery, and this is thermally decomposed and dissipated and, as a result, engraved to form a concave portion.

In a preferable embodiment of the invention, it is thought that when the (E) photothermal conversion agent is present in the state where thermal molecular movement of the specific binder polymer is suppressed, heat transmission to, and thermal decomposition of the specific binder polymer effectively occur, and it is presumed that an engraving sensitivity has been further increased due to such an effect.

On the other hand, in the state (rubber state) where the glass transition temperature is lower than room temperature and thermal molecular movement of the specific binder polymer is not suppressed, since due to an intensity of its vibration, that is, thermal molecular movement, an intermolecular distance between the (E) photothermal conversion agent and the specific binder polymer becomes great, and a volume (space) present between them becomes very great, it is presumed that not only an efficacy of heat transmission from the (E) photothermal conversion agent to the specific binder polymer is reduced, but also the transmitted heat contributes to active thermal movement, heat loss is generated, and contribution to occurrence of effective thermal decomposition is decreased, and thereby, it is difficult to contribute to improvement in an engraving sensitivity.

From a viewpoint of attaining high engraving sensitivity, satisfying both aqueous ink suitability and UV ink suitability, and being excellent in film properties, examples of the specific binder polymers include a polymer being water-insoluble and lower-alcohol soluble that is selected from a group consisting of a polyester, a polyurethane, a polyvinyl butyral (including a derivative thereof; also abbreviated hereinafter as PVB), an alcohol-soluble polyamide, a cellulose derivative, and an acrylic resin

Among those polymers, the specific binder polymer is more preferably a polymer being water-insoluble and lower-alcohol soluble that is selected from the group consisting of a polyester, a polyurethane, a polyvinyl butyral, and an alcohol-soluble polyamide.

Hereinafter, each polymers that are suitably used as the specific polymer will be described in detail.

(1) Polyester

A polyester which is suitably used as the specific binder polymer is at least one polyester selected from the group consisting of a polyester including a hydroxycarboxylic acid unit and derivatives thereof, polycaprolactone (PCL) and derivatives thereof, and poly(butylenesuccinic acid) and derivatives thereof (hereinafter may be referred to as the “specific polyester”). The specific polyester may be contained in the resin composition of the invention individually or in combination thereof.

In the specification, the term “polyester including a hydroxycarboxylic acid unit” refers to a polyester obtainable by a polymerization reaction using a hydroxycarboxylic acid as one of the raw materials. Furthermore, according to the present specification, the term “hydroxycarboxylic acid” refers to a compound having at least one OH group and at least one COOH group in the molecule. It is preferable that the at least one OH group and the at least one COOH group of the “hydroxycarboxylic acid” exist closely to each other, and it is also preferable that the OH group and the COOH group are linked through a linker having 6 or fewer atoms, and more preferably 4 or fewer atoms.

Specific example of the specific polyester is preferably selected from the group consisting of a polyhydroxyalkanoate (PHA), a lactic acid-based polymer, a polyglycolic acid (PGA), a polycaprolactone (PCL) and a poly(butylenesuccinic acid), and derivatives or mixtures thereof.

When the specific polyester is used, an action mechanism thereof is not clear, but is supposed to be as follows.

The specific polyester is characterized in that when it is thermally decomposed (that is, at a time corresponding to the occasion of laser engraving according to the present application), a part of the main chain is thermally decomposed at a relatively low temperature, such as approximately 300° C., and a depolymerization reaction (which is a reverse reaction of a polymerization reaction, whereby the polymer is thermally broken down into the raw material low molecular weight monomer units) occurs beginning from this part.

The laser engraving (particularly, in the case of near-infrared laser light) that is carried out on the resin composition of the invention is thought to include five steps: (1) light absorption by a compound having a maximum absorption wavelength at 700 to 1300 nm [symbol] (2) photothermal conversion by the compound having a maximum absorption wavelength at 700 to 1300 nm [symbol] (3) heat transfer from the compound having a maximum absorption wavelength at 700 to 1300 nm to a binder existing nearby [symbol] (4) thermal decomposition of the binder [symbol] (5) dissipation of the decomposed binder.

Since the specific polyester has the characteristic of low temperature thermal decomposition and the characteristic of depolymerization as described above, the step (4) is accelerated by the characteristic of low temperature thermal decomposition, and since the low molecular weight monomers (many of which volatilize below 250° C.) generated by depolymerization are instantly volatilized, the step (5) occurs very efficiently. Thus, it is thought that these two effects result in a large increase in laser engraving sensitivity.

Examples of the specific polyester, which are obtainable by a polymerization reaction using hydroxycarboxylic acid as one of raw materials, are shown below.

As the PHA of the specific polyester, those polymers having a repeating monomer unit represented by the following Formula (a) are preferable.

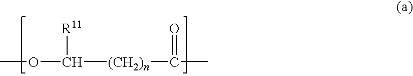

In Formula (a), n represents an integer from 1 to 5; and R¹¹ represents a hydrogen atom, an alkyl group or an alkenyl group. These alkyl group and alkenyl group are preferably such groups having 1 to 20 carbon atoms. Here, the polymer may be a homopolymer in which the combination of R¹¹ and n is fixed to be constant, or may be a copolymer having at least two different repeating monomer units with different combinations of R¹¹ and n. The copolymer may be a random copolymer, a block copolymer, an alternating copolymer or a graft copolymer. The molecular weight of PHA is in the range of from 500 to 5,000,000 g/mol, preferably from 1,000 to 2,500,000 g/mol, and more preferably from 2,500 to 1,000,000 g/mol.

Examples of PHA that are applicable to the invention include poly-3-hydroxybutyrate, poly-3-hydroxyvalerate, poly-3-hydroxyheptanoate, poly-3-hydroxyoctanoate, poly-4-hydroxybutyrate, poly(3-hydroxybutyrate-co-3-hydroxyvalerate), poly(3-hydroxybutyrate-co-4-hydroxybutyrate), poly(3-hydroxybutyrate-co-3-hydroxyoctanoate), and other copolymers. The copolymers of PHA mentioned herein usually have 40 to 100%, and preferably 60 to 98%, of a 3-hydroxybutyrate monomer.

Additionally, as the specific polyester, copolymers using the monomers mentioned as those usable in the polyester that may be used in combination, which will be described later, as the co-monomers that are copolymerizable with the repeating monomer unit represented by Formula (a), may also be used.

The lactic acid-based polymer that may be used in the invention is a poly lactic acid (in Formula (a), R¹¹ is a methyl group, and n=0) or a copolymer of lactic acid and hydroxycarboxylic acid. Examples of the hydroxycarboxylic acid include glycolic acid (in Formula (a), R¹¹ is H, and n=0), hydroxybutyric acid, hydroxyvaleric acid, hydroxypentanoic acid, hydroxycaproic acid, hydroxyheptanoic acid, and the like. A preferred molecular structure of polylactic acid consists of 85 to 100% by mole of either an L-lactic acid unit or a D-lactic acid unit, and 0 to 15% by mole of the corresponding enantiomer lactic acid unit. The copolymer of lactic acid and hydroxycarboxylic acid includes 85% by mole or more and less than 100% by mole of either an L-lactic acid unit or a D-lactic acid unit, and more than 0% to 15% by mole or less of a hydroxycarboxylic acid unit. In view of the ease of obtaining the raw material, the lactic acid that is used may be DL-lactic acid (racemate). Preferred hydroxycarboxylic acids include glycolic acid and hydroxycaproic acid.

Such a lactic acid-based polymer may be obtained by selecting a monomer having a required structure from L-lactic acid, D-lactic acid and hydroxycarboxylic acid to use the monomer as a raw material monomer, and subjecting the monomer to dehydration polycondensation. Preferably, the lactic acid-based polymer may be obtained by selecting a monomer having a required structure from lactide, which is a cyclic dimer of lactic acid; glycolide, which is a cyclic dimer of glycolic acid; lactone; and the like, and subjecting the monomer to ring-opening polymerization. Examples of the lactide include L-lactide, which is a cyclic dimer of L-lactic acid; D-lactide, which is a cyclic dimer of D-lactic acid; mesolactide, which is a cyclic dimerization product of D-lactic acid and L-lactic acid; and DL-lactide which is a racemic mixture of a D-lactide and an L-lactide. According to the invention, any lactide may be used, but as a main raw material, D-lactide, L-lactide, glycolide or caprolactone is preferred.

As the polylactic acid and the lactic acid-glycolic acid copolymer, polymers having a ratio of lactic acid/glycolic acid (molar ratio) of 100/0 to 30/70, and more preferably 100/0 to 40/60, and having a molecular weight of about 1,000 to 100,000, and more preferably 2,000 to 80,000, are exemplified.

Among the polylactic acid and the lactic acid-glycolic acid copolymer, the polylactic acid copolymer is preferred from the viewpoint that the polylactic acid copolymer maintains the film properties strong compared to the lactic acid-glycolic acid copolymer.

The polycaprolactone (PCL) that may be used as the specific polyester (in Formula (a), R¹¹ is H, and n=4) may be a homopolymer or a combination with other lactones, or may also be a polyester which is structurally identical with Formula (a), or the like.

The poly(butylenesuccinic acid) that may be used as the specific polyester is not a polyester formed only from a hydroxycarboxylic acid unit, but is a polymer synthesized from 1,4-butanediol and succinic acid. However, hydroxycarboxylic acid may be used in combination.

The polyester described as the specific polyester may be a copolymer using a copolymerizable comonomer which is exemplified as a monomer usable in the polyester described below.

When the specific polyester is used as the binder polymer, examples of the polyester which are preferably used in combination with the specific polyester are given below. However, poly(butylenesuccinic acid) may be used as the specific polyester.

Such a polyester may be a polyester formed from an aliphatic (including alicyclic) glycol, an aromatic dicarboxylic acid or an acid anhydride thereof, or an aliphatic dicarboxylic acid or an acid anhydride thereof (hereinafter, simply referred to as aliphatic dicarboxylic acid) as the monomer, for the purpose of controlling water resistance or flexibility of the film.

Furthermore, if necessary, the polyester may also include, as a third component monomer, at least one polyfunctional component selected from a trifunctional or tetrafunctional polyhydric alcohol, and a polyvalent carboxylic acid (or an acid anhydride thereof).

Examples of the glycol that may be preferably used include ethylene glycol, 1,4-butanediol, 1,6-hexanediol, 1,8-octanediol, 1,10-decanediol, 1,4-cyclohexanediol and mixtures thereof, but are not intended to be limited to these.

Examples of the aromatic dicarboxylic acid that may be preferably used include terephthalic acid, isophthalic acid, phthalic acid, naphthalenedicarboxylic acid and mixtures thereof, but are not intended to be limited to these.

Examples of the aliphatic dicarboxylic acid that may be preferably used include succinic acid, adipic acid, suberic acid, sebacic acid, 1,10-decanedicarboxylic acid, succinic anhydride, 1,4-cyclohexanedicarboxylic acid and mixtures thereof, but are not intended to be limited to these.

As a particularly suitable embodiment of the specific polyester, the lactic acid-based polymer is preferable, and from the viewpoint of high engraving sensitivity, the polylactic acid-based polymer and the polyglycolic acid-based polymer r are more preferable.

### (2) Polyvinyl Butyral and Derivatives Thereof

As polyvinyl butyral (hereinafter, referred to as PVB), a homopolymer may be used, or a polyvinyl butyral derivative may be used.

A content of butyral in the PVB derivative (total mole number of raw material monomer is 100%) is preferably 30% to 90%, more preferably 50% to 85%, particularly preferably 55% to 78%.

From a viewpoint that balance between an engraving sensitivity and film forming property is retained, a weight average molecular weight of PVB and a derivative thereof is preferably 5000 to 800000, more preferably 8000 to 500000. Further, from a viewpoint of improvement in the rinsing property of an engraving residue, 50000 to 300000 is particularly preferable.

PVB and a derivative thereof are also available as a commercialized product, and preferable examples, from a viewpoint of alcohol solubility (particularly, ethanol), include “ESLEC B” Series, “ESLEC K (KS)” Series manufactured by Sekisui Chemical Co., Ltd., and “Denka Butyral” manufactured by Denki Kagaku Kogyo Co., Ltd.. From a viewpoint of alcohol solubility (particularly ethanol), further preferable are “ESLEC B” Series manufactured by Sekisui Chemical Co., Ltd. and “Denka Butyral” manufactured by Denki Kagaku Kogyo Co., Ltd., and particularly preferable are “BL-1”, “BL-1H”, “BL-2”, “BL-5”, “BL-S”, “BX-L”, “BM-S”, “BH-S” in “ESLEC B” Series manufactured by Sekisui Chemical Co., Ltd., and “#3000-1”, “#3000-2”, “#3000-4”, “#4000-2”, “#6000-C”, “#6000-EP”, “#6000-CS”, “#6000-AS” in “Denka Butyral” manufactured by Denki Kagaku Kogyo Co., Ltd..

When a film of the relief forming layer, which is formed by applying the resin composition of the invention, is made using PVB as the specific binder polymer, a method of casting and drying a solution of the polymer dissolved in a solvent is preferable from a viewpoint of smoothness of a surface of a film.

### (3) Alcohol-Soluble Polyamide

Since a polyamide in which a polar group such as polyethylene glycol and piperazine is introduced into a main chain improves alcohol solubility due to working of the polar group, it is suitable as the specific binder polymer used in the invention.

By reacting ε-caprolactam and/or adipic acid with polyethylene glycol having both terminals modified with amine, a polyamide having a polyethylene glycol unit (also called polyethylene oxide segment) is obtained and, by reacting this with piperazine, a polyamide having a piperazine skeleton is obtained.

As a polyamide containing a polyethylene glycol unit, usually, polyether amide obtained by polycondensing or copolycondensing α•ω-diaminoproplypolyoxyethylene as at least a part of a raw material diamine component by the known method (e.g. JP-A No. 55-79437), or polyether ester amide obtained by polycondensing or copolycondensing polyethylene glycol as at least a part of a raw material diol component by the known method (e.g. JP-A No. 50-159586) is used without any limitation, and a polymer having an amide bond in a main chain may be widely used.

Herein, a number average molecular weight of the polyethylene oxide segment in a polyamide is preferably in the range of 150 to 5000, more preferably in the range of 200 to 3000 from a viewpoint of the form retainability of the relief forming layer. A number average molecular weight of these polyamides having the polyethylene oxide segment is preferably in the range of 5000 to 300000, further preferably in the range of 10000 to 200000, particularly preferably in the range of 10000 to 50000.

As the polyamide, a polyamide having a highly polar unit such as polyethylene oxide in a main chain is preferably used, but since even when a side chain of a polyamide has a highly polar functional group, the same function may be obtained, a polyamide having a polar group in a side chain is also suitable in the specific binder polymer in the invention.

From a viewpoint of an engraving sensitivity, more preferable is the case where a side chain of a polyamide has a highly polar functional group. As such a polyamide, specifically, methoxymethylated polyamide, and methoxymethylated nylon are preferable. As a commercialized product of such a polyamide derivative, a methoxymethylated polyamide “TORESIN” Series manufactured by Nagase Chemtex is preferable. Particularly preferable is a methoxymethylated polyamide “TORESIN F-30K”, and “TORESIN EF-30T” manufactured by Nagase Chemitex.

(4) Cellulose Derivative

Usual cellulose is hardly dissolved in water and an alcohol, but water- or solvent-solubility may be controlled by modifying remaining OH of a glucopyranose unit with a specified functional group, and a cellulose derivative which is thus insoluble in water, but is made to be soluble in an alcohol having 1 to 4 carbon atoms is also suitable as the specific binder polymer used in the invention.

Examples of the cellulose derivative suitable in the invention include alkylcellulose such as ethylcellulose and methylcellulose, hydroxyethylenecellulose, hydroxypropylenecellulose, and cellulose acetate butyrate, which have physical property of being water-insoluble and lower alcohol-soluble.

Further, specific examples thereof include Metholose Series manufactured by Shin-Etsu Chemical Co., Ltd.. This series is such that a part of a hydrogen atom of a hydroxy group of cellulose is replaced with a methyl group (—CH₃), a hydroxypropyl group (—CH₂CHOHCH₃), or a hydroxyethyl group (—CH₂CH₂OH).

In addition, in the invention, particularly preferable in solubility in a lower alcohol and an engraving sensitivity is alkylcellulose, inter alia, ethylcellulose and methylcellulose.

(5) Epoxy Resin

As a water-insoluble and alcohol-soluble epoxy resin which may be used in the invention, a modified epoxy resin in which a bisphenol A-type epoxy resin or a bisphenol A-type epoxy resin is high-molecularized or highly functionalized with a modifying agent is preferable from a viewpoint of water-insolubility. Particularly preferable is a modified epoxy resin.

Preferable examples of the modified epoxy resin include “Arakyd 9201N”, “Arakyd 9203N”, “Arakyd 9205”, “Arakyd 9208”, “KA-1439A”, “MODEPICS 401”, and “MODEPICS 402” manufactured by Arakawa Chemical Industries Ltd..

(6) Acrylic Resin

As the specific binder polymer in the invention, a water-insoluble and lower alcohol-soluble acryl resin may be also used.

As such an acryl resin, an acryl resin obtained by using the known acryl monomer, solubility of which has been controlled so as to satisfy the aforementioned physical conditions, may be used. As an acryl monomer used in synthesizing an acryl resin, for example, (meth)acrylic acid esters, and crotonic acid esters, (meth)acrylamides are preferable. Examples of such a monomer include the following compounds.

That is, examples of (meth)acrylic acid esters include methyl(meth)acrylate, ethyl(meth)acrylate, n-propyl(meth)acrylate, isopropyl(meth)acrylate, n-butyl(meth)acrylate, isobutyl(meth)acrylate, tert-butyl(meth)acrylate, n-hexyl(meth)acrylate, 2-ethylhexyl(meth)acrylate, acetoxyethyl(meth)acrylate, phenyl(meth)acrylate, 2-hydroxyethyl(meth)acrylate, 2-hydroxypropyl(meth)acrylate, 4-hydroxybutyl(meth)acrylate, 2-methoxyethyl(meth)acrylate, 2-ethoxyethyl(meth)acrylate, 2-(2-methoxyethoxy)ethyl(meth)acrylate, cyclohexyl(meth)acrylate, benzyl(meth)acrylate, diethylene glycol monomethyl ether(meth)acrylate, diethylene glycol monoethyl ether(meth)acrylate, diethylene glycol monophenyl ether(meth)acrylate, triethylene glycol monomethyl ether(meth)acrylate, triethylene glycol monoethyl ether(meth)acrylate, dipropylene glycol monomethyl ether(meth)acrylate, polyethylene glycol monomethyl ether(meth)acrylate, polypropylene glycol monomethyl ether(meth)acrylate, monomethyl ether(meth)acrylate of a copolymer of ethylene glycol and propylene glycol, N,N-dimethylaminoethyl(meth)acrylate, N,N-diethylaminoethyl(meth)acrylate, and N,N-dimethylaminopropyl(meth)acrylate.

From a viewpoint of alcohol solubility, diethylene glycol monomethyl ether(meth)acrylate, diethylene glycol monoethyl ether(meth)acrylate, diethylene glycol monophenyl ether(meth)acrylate, triethylene glycol monomethyl ether(meth)acrylate, triethylene glycol monoethyl ether(meth)acrylate, dipropylene glycol monomethyl ether(meth)acrylate, polyethylene glycol monomethyl ether(meth)acrylate, polypropylene glycol monomethyl ether(meth)acrylate, and monomethyl ether(meth)acrylate of a copolymer of ethylene glycol and propylene glycol are preferable.

Examples of crotonic acid esters include butyl crotonate, and hexyl crotonate.

Examples of (meth)acrylamides include (meth)acrylamide, N-methyl(meth)acrylamide, N-ethyl(meth)acrylamide, N-propyl(meth)acrylamide, N-n-butyl(meth)acrylamide, N-tert-butyl(meth)acrylamide, N-cyclohexyl(meth)acrylamide, N-(2-methoxyethyl)(meth)acrylamide, N,N-dimethyl(meth)acrylamide, N,N-diethyl(meth)acrylamide, N-phenyl(meth)acrylamide, N-benzyl(meth)acrylamide, and (meth)acryloylmorpholine.

As the acryl resin, a modified acryl resin containing an acryl monomer having a urethane group or a urea group may be also preferably used.

Examples of an acryl monomer used in synthesis of an acryl resin used as the specific binder polymer include compounds such as the following exemplified monomers (AM-1) to (AM-22).

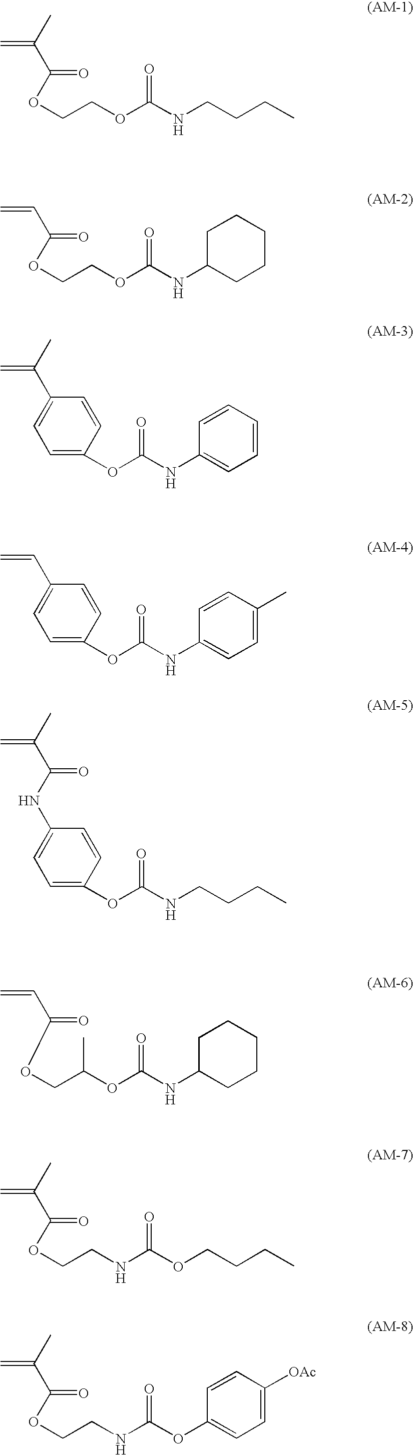

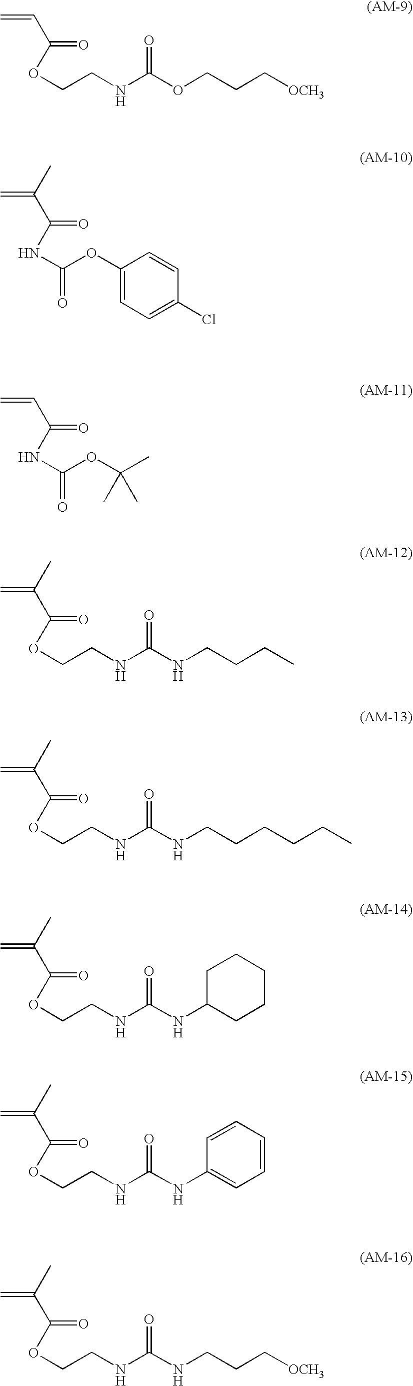

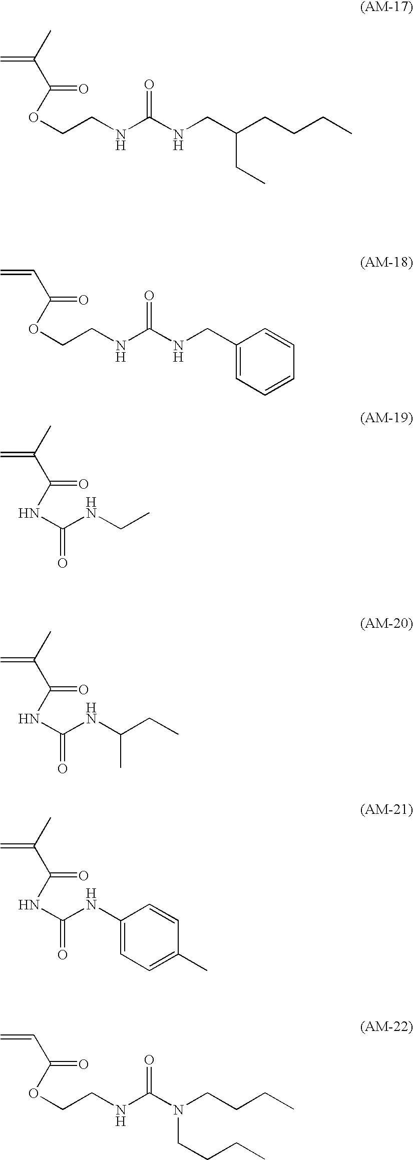

Examples of the acryl resin which may be suitably used as the specific binder polymer are shown below together with a weight average molecular weight measured by the GPC method [described as Mw (GPC)], but the acryl resin which may be used in the invention is not limited to them as far as it has the aforementioned preferable properties.

| | Mw (GPC) |
|---|---|
| 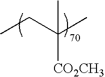 | 22,000 |
| 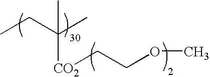 | |
| 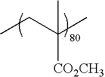 | 25,000 |
| 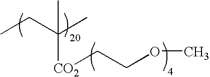 | |
| 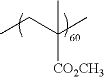 | 32,000 |
| 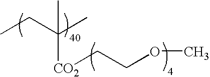 | |
| 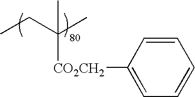 | 62,000 |
| 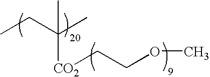 | |
| 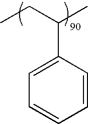 | 36,000 |
| 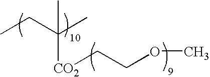 | |
| 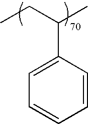 | 12,000 |
| 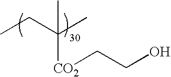 | |
| 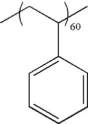 | 92,000 |
| 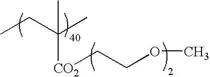 | |
| 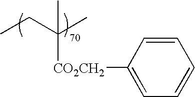 | 105,000 |
| 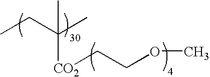 | |
| 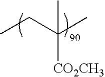 | 113,000 |
| 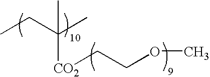 | |
| 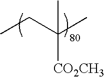 | 15,000 |
| 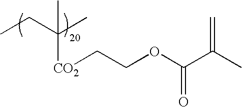 | |
| 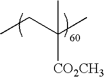 | 62,000 |
| 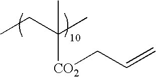 | |
| 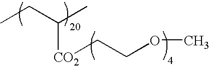 | |
| 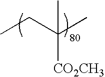 | 33,000 |
| 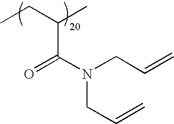 | |
| 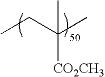 | 32,000 |
| 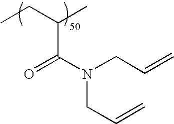 | |

(7) Polyurethane Resin

As the specific binder polymer a water-insoluble and lower alcohol-soluble polyurethane resin may be also used.

A polyurethane resin which may be used as the specified alcoholphilic polymer in the invention is a polyurethane resin having, as a fundamental skeleton, a structural unit which is a reaction product of at least one kind of a diisocyanate compound represented by the following Formula (U-1), and at least one kind of a diol compound represented by the following Formula (U-2).

OCN—X⁰—NCO (U-1)

HO—Y⁰—OH (U-2)

In Formulae (U-1) and (U-2), X⁰ and Y⁰ each represent independently a divalent organic residue, provided that at least one of organic residues represented by X⁰ and Y⁰ is linked to a NCO group or an OH group through an aromatic group.

Diisocyanate Compound

It is preferable that in a diisocyanate compound represented by Formula (U-1), an organic residue represented by X⁰ contains, in a structure, an aromatic group directly linked to a NCO group.

A preferable diisocyanate compound is a diisocyanate compound represented by the following Formula (U-3).

OCN-L¹-NCO (U-3)

In Formula (U-3), L¹ represents a divalent aromatic hydrocarbon group optionally having a substituent. Examples of the substituent include an alkyl group, an aralkyl group, an aryl group, an alkoxy group, an aryloxy group, and a halogen atom (—F, —Cl, —Br, —I). If necessary, L¹ may have other functional group which does not react with an isocyanate group, for example, an ester group, a urethane group, an amido group, and a ureido group.

Examples of the diisocyanate compound represented by Formula (U-3) include the following compounds.

That is, examples of the aromatic diisocyanate compound include 2,4-tolylene diisocyanate, 2,4-tolylene diisocyanate dimer, 2,6-tolylenedilene diisocyanate, p-xylylene diisocyanate, m-xylylene diisocyanate, 4,4′-diphenylmethane diisocyanate, 1,5-naphthylene diisocyanate, and 3,3′-dimethylbiphenyl-4,4′-diisocyanate.

Particularly, from a viewpoint of thermal decomposability, 4,4′-diphenylmethane diisocyanate, and 1,5-naphthylene diisocyanate are preferable.

The polyurethane resin used as the specific binder polymer may be a polymer synthesized by using a diisocyanate compound other than the aforementioned diisocyanate compounds, for example, from a viewpoint that compatibility with other components in the resin composition is improved, and storage stability is improved.

Examples of the diisocyanate compound which may be used together include aliphatic diisocyanate compounds such as hexamethylene diisocyanate, trimethylhexamethylene diisocyanate, lysine diisocyanate, and dimer acid diisocyanate; alicyclic diisocyanate compounds such as isophorone diisocyanate, 4,4′-methylene bis(cyclohexylisocyanate), methylcyclohexane-2,4 (or 2,6) diisocyanate, 1,3-(isocyanatemethyl)cyclohexane; and diisocyanate compounds which are a reaction product of diol and diisocyanate, such as an adduct of 1 mol of 1,3-butylene glycol and 2 mol of tolylene diisocyanete.

Diisocyanate obtained by adding a monofunctional alcohol to one of three NCOs of triisocyanate may be also used.

Diol Compound

It is preferable that in the diol compound represented by Formula (U-2), an organic residue represented by Y⁰ contains, in a structure, an aromatic group directly linked to an OH group.

More specifically, diol compounds represented by the following formulas (A-1) to (A-3) are preferable.

HO—Ar¹—OH Formula (A-1)

HO—(Ar¹—Ar²)ₘ—OH Formula (A-2)

HO—Ar¹—X—Ar²—OH Formula (A-3)

In Formulae (A-1) to (A-3), Ar¹ and Ar² may be the same or different, and each represent an aromatic ring. Examples of such an aromatic ring include a benzene ring, a naphthalene ring, an anthracene ring, a pyrene ring, and a heterocyclic ring. These aromatic rings may have a substituent. Examples of the substituent include an alkyl group, an aralkyl group, an aryl group, an alkoxy group, an aryloxy group, and a halogen atom (—F, —Cl, —Br, —I).

From a viewpoint of easy availability of a raw material, preferable is a benzene ring and a naphthalene ring. Also in view of film forming property, a benzene ring is particularly preferable.

X is a divalent organic residue. And, m is preferably 1 to 3, particularly preferably 1, from a viewpoint of film forming property.

Preferable examples of the diol compound represented by Formula (A-1) are 1,4-dihydroxybenzene, and 1,8-dihydroxynaphthalene.

Preferable examples of the diol compound represented by Formula (A-2) are 4,4-dihydroxybiphenyl, and 2,2-hydroxybinaphthyl.

Preferable examples of the diol compound represented by Formula (A-3) are bisphenol A, and 4,4-bis(hydroxyphenyl)methane.

The polyurethane resin used as the specific binder polymer in the invention may be a polymer synthesized by using an additional diol compound other than the aforementioned diol compounds, for example, from a viewpoint that compatibility with other components in the resin composition is improved, and storage stability is improved.

Examples of the diol compound which may be used together include a polyether diol compound, a polyester diol compound, and a polycarbonate diol compound.

Examples of the polyether diol compound include compounds represented by the following formulas (U-4), (U-5), (U-6), (U-7), and (U-8), and a random copolymer of ethylene oxide and propylene oxide having hydroxyl groups at the terminal positions.

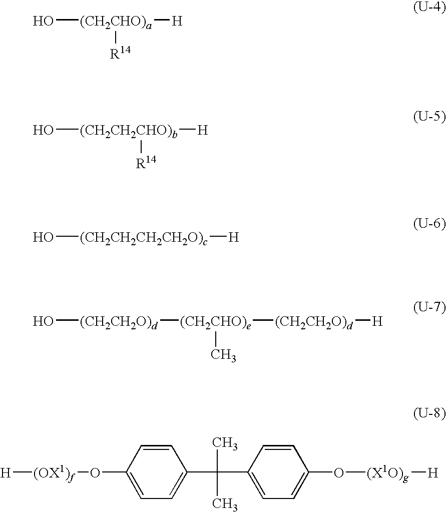

In Formulae (U-4) to (U-8), R¹⁴ represents a hydrogen atom or a methyl group, and X¹ represents the following groups. And, a, b, c, d, e, f, and g each indicate independently an integer of 2 or more, preferably an integer of 2 to 100.

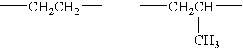

Examples of the polyether diol compounds represented by Formulae (U-4) and (U-5) include the following compounds.

That is, examples thereof include diethylene glycol, triethylene glycol, tetraethylene glycol, pentaethylene glycol, hexaethylene glycol, heptaethylene glycol, octaethylene glycol, di-1,2-propylene glycol, tri-1,2-propylene glycol, tetra-1,2-propylene glycol, hexa-1,2-propylene glycol, di-1,3-propylene glycol, tri-1,3-propylene glycol, tetra-1,3-propylene glycol, di-1,3-butylene glycol, tri-1,3-butylene glycol, hexa-1,3-butylene glycol, polyethylene glycol having a weight average molecular weight of 1000, polyethylene glycol having a weight average molecular weight of 1500, polyethylene glycol having a weight average molecular weight of 2000, polyethylene glycol having a weight average molecular weight of 3000, polyethylene glycol having a weight average molecular weight of 7500, polypropylene glycol having a weight average molecular weight of 400, polypropylene glycol having a weight average molecular weight of 700, polypropylene glycol having a weight average molecular weight of 1000, polypropylene glycol having a weight average molecular weight of 2000, polypropylene glycol having a weight average molecular weight of 3000, and polypropylene glycol having a weight average molecular weight of 4000.

Examples of the polyether diol compound represented by Formula (U-6) include the following compounds.

That is, examples thereof include PTMG650, PTMG1000, PTMG2000, and PTMG3000 (trade name) manufactured by Sanyo Chemical Industries, Ltd.

Further, examples of the polyether diol compound represented by Formula (U-7) include the following compounds.

That is, examples thereof include New Pole PE-61, New Pole PE-62, New Pole PE-64, New Pole PE-68, New Pole PE-71, New Pole PE-74, New Pole PE-75, New Pole PE-78, New Pole PE-108, New Pole PE-128, New Pole PE-61 (trade name) manufactured by Sanyo Chemical Industries, Ltd.

Examples of the polyether diol compound represented by Formula (U-8) include the following compounds.

That is, examples thereof include New Pole BPE-20, New Pole BPE-20F, New Pole BPE-20NK, New Pole BPE-20T, New Pole BPE-20G, New Pole BPE-40, New Pole BPE-60, New Pole BPE-100, New Pole BPE-180, New Pole BPE-2P, New Pole BPE-23P, New Pole BPE-3P, and New Pole BPE-5P (trade name) manufactured by Sanyo Chemical Industries, Ltd.

Examples of the random copolymer of ethylene oxide and propylene oxide having hydroxy groups at the terminal positions include the following copolymers.

That is, examples thereof include New Pole 50HB-100, New Pole 50HB-260, New Pole 50HB-400, New Pole 50HB-660, New Pole 50HB-2000, and New Pole 50HB-5100 (trade name) manufactured by Sanyo Chemical Industries, Ltd.

Examples of the polyester diol compound include compounds represented by the following formulas (U-9), and (U-10).

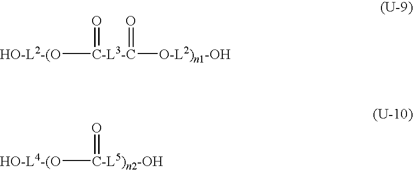

In Formulae (U-9) and (U-10), L², L³, and L⁴ may be the same or different, and each represent a divalent aliphatic or aromatic hydrocarbon group, and L⁵ represents a divalent aliphatic hydrocarbon group. Preferably, L² to L⁴ each represent independently an alkylene group, an alkenylene group, an alkynylene group, or an allylene group, and L⁵ represents an alkylene group. In L² to L⁵, other functional group which does not react with an isocyanate group, for example, an ether group, a carbonyl group, an ester group, a cyano group, an olefin group, a urethane group, an amido group, a ureido group, or a halogen atom may be present. And, n1 and n2 are an integer of 2 or more, respectively, preferably represent an integer of 2 to 100.

Examples of the polycarbonate diol compound include a compound represented by Formula (U-11).

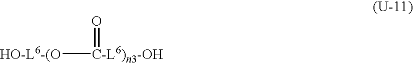

In Formula (U-11), two L⁶s may be the same or different, and each represent a divalent aliphatic or aromatic hydrocarbon group. Preferably, L⁶ represents an alkylene group, an alkenylene group, an alkynylene group, or an arylene group. In L⁶, other functional group which does not react with an isocyanate group, for example, an ether group, a carbonyl group, an ester group, a cyano group, an olefin group, a urethane group, an amido group, a ureido group, or a halogen atom may be present. And, n3 is an integer of 2 or more, preferably represents an integer of 2 to 100.

Examples of the diol compounds represented by Formula (U-9), (U-10), or (U-11) include the following compounds [exemplified compounds (No. 1) to (No. 18)]. In examples, n represents an integer of 2 or more.

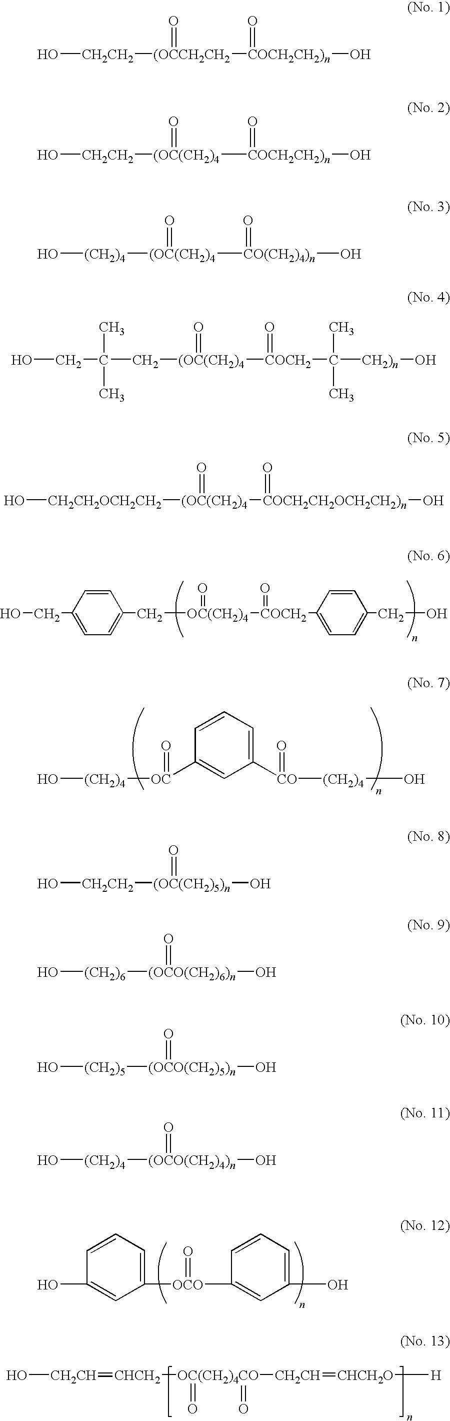

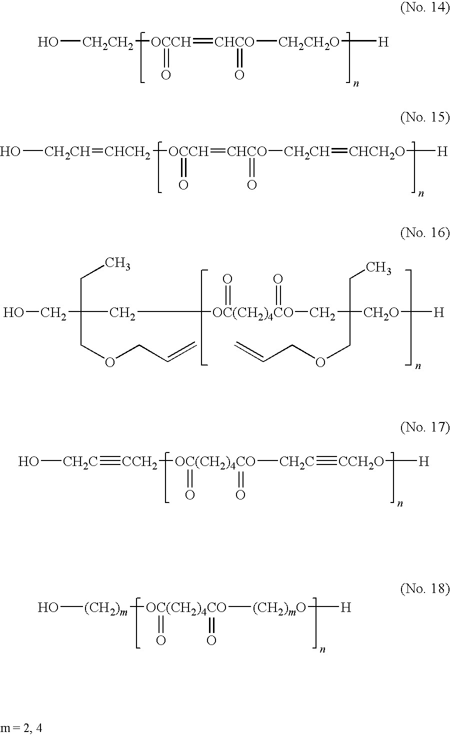

In addition, for synthesizing a polyurethane resin used as the specific binder polymer, in addition to the aforementioned diol compounds, a diol compound having a substituent which does not react with an isocyanate group may be used together. Examples of such a diol compound include the following compounds.

That is, for example, compounds represented by the following formulas (U-12), and (U-13) are used.

HO-L⁷-O—CO-L⁸-CO—O-L⁷-OH (U-12)

HO-L⁸-CO—O-L⁷-OH (U-13)

In Formulae (U-12) and (U-13), L⁷ and L⁸ may be the same or different, and each represent a divalent aliphatic hydrocarbon group, aromatic hydrocarbon group or heterocyclic group, each optionally having a substituent (e.g. alkyl group, aralkyl group, aryl group, alkoxy group, aryloxy group, halogen atom (—F, —Cl, —Br, —I) etc.). If necessary, L⁷ and L⁸ may have other functional group which does not react with an isocyanate group, for example, a carbonyl group, an ester group, a urethane group, an amido group, and a ureido group. L⁷ and L⁸ may form a ring.

Further, for synthesizing a polyurethane resin used as the specific binder polymer, a diol compound having an acid group such as a carboxyl group, a sulfone group, and a phosphoric acid group may be used together. Particularly, a diol compound having a carboxyl group is preferable from a viewpoint of improvement in a film strength, and water resistance due to a hydrogen bond.

Examples of the diol compound having a carboxyl group include, for example, compounds represented by the following formulas (U-14) to (U-16).

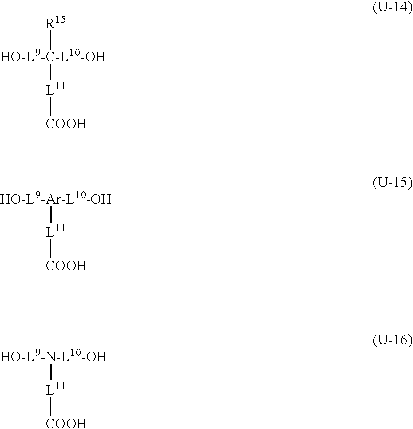

In Formulae (U-14) to (U-16), R¹⁵ represents a hydrogen atom, an alkyl group optionally having a substituent [e.g. cyano group, nitro group, halogen atom such as —F, —Cl, —Br, —I etc., —CONH₂, —COOR¹⁶, —OR¹⁶, —NHCONHR¹⁶, —NHCOOR¹⁶, —NHCOR¹⁶, —OCONHR¹⁶ (wherein R¹⁶ represents an alkyl group having 1 to 10 carbon atoms, or an aralkyl group having 7 to 15 carbon atoms) etc.], an aralkyl group, an aryl group, an alkoxy group, or an aryloxy group, preferably represents a hydrogen atom, an alkyl group having 1 to 8 carbon atoms, or an aryl group having 6 to 15 carbon atoms. L⁹, L¹⁰ and L¹¹ may be the same or different, and represent a single bond, or a divalent aliphatic or aromatic hydrocarbon group optionally having a substituent (for example, each group of alkyl, aralkyl, aryl, alkoxy, and halogeno is preferable), preferably represent an alkylene group having 1 to 20 carbon atoms, an arylene group having 6 to 15 carbon atoms, and further preferably represent an alkylene group having 1 to 8 carbon atoms. If necessary, L⁹ to L¹¹ may have other functional group which does not react with an isocyanate group, for example, a carbonyl group, an ester group, a urethane group, an amido group, a ureido group, or an ether group. Two or three of R¹⁵, L⁷, L⁸ and L⁹ may form a ring. Ar represents a trivalent aromatic hydrocarbon group optionally having a substituent, and preferably represents an aromatic group having 6 to 15 carbon atoms.

Examples of the diol compounds having a carboxyl group represented by Formulae (U-14) to (U-16) include the following compounds.

That is, examples of the diol compounds include 3,5-dihydroxybenzoic acid, 2,2-bis(hydroxymethyl)propionic acid, 2,2-bis(2-hydroxyethyl)propionic acid, 2,2-bis(3-hydroxypropyl)propionic aid, bis(hydroxymethyl)acetic acid, bis(4-hydroxyphenyl)acetic acid, 2,2-bis(hydroxymethyl)butyric acid, 4,4-bis(4-hydroxyphenyl)pentanoic acid, tartaric acid, N,N-dihydroxyethylglycine, and N,N-bis(2-hydroxyethyl)-3-carboxy-propionamide.

In addition, for synthesizing a polyurethane resin used as the specific binder polymer, compounds obtained by ring-opening of tetracarboxylic acid dianhydrides represented by the following formulas (U-17) to (U-19) with a diol compound may be used together.

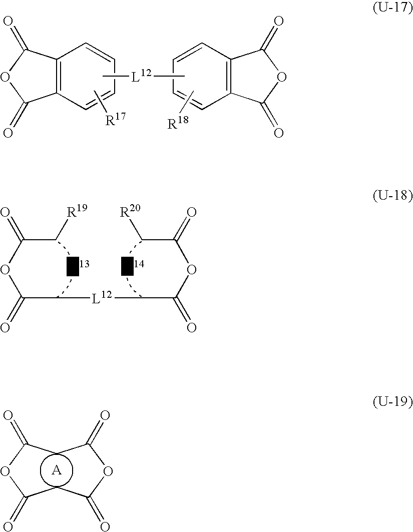

In Formulae (U-17) to (U-19), L¹² represents a single bond, a divalent aliphatic or aromatic hydrocarbon group optionally having a substituent (e.g. alkyl group, aralkyl group, aryl group, alkoxy group, halogeno group, ester group, and amido group are preferable), —CO—, —SO—, —SO₂—, —O—, or —S—, and preferably represents a single bond, a divalent aliphatic hydrocarbon group having 1 to 15 carbon atoms, —CO—, —SO₂—, —O—, or —S—. R¹⁷ and R¹⁸ may be the same or different, and represent a hydrogen atom, an alkyl group, an aralkyl group, an aryl group, an alkoxy group, or a halogeno group, and preferably represent a hydrogen atom, an alkyl group having 1 to 8 carbon atoms, an aryl group having 6 to 15 carbon atoms, an alkoxy group having 1 to 8 carbon atoms, or a halogeno group. Two of L¹², R¹⁷ and R¹⁸ may be linked to form a ring. R¹⁹ and R²⁰ may be the same or different, and represent a hydrogen atom, an alkyl group, an aralkyl group, an aryl group, or a halogeno group, and preferably represent a hydrogen atom, an alkyl group having 1 to 8 carbon atoms, or an aryl group having 6 to 15 carbon atoms. Two of L¹², R¹⁹ and R²⁰ may be linked to form a ring. L¹³ and L¹⁴ may be the same or different, and represent a single bond, a double bond, or a divalent aliphatic hydrocarbon group, and preferably represent a single bond, a double bond, or a methylene group. A represents a mononuclear or polynuclear aromatic ring, and preferably represents an aromatic ring having 6 to 18 carbon atoms.

Examples of the compounds represented by Formula (U-17), (U-18), or (U-19) include the following compounds.

That is, examples thereof include aromatic tetracarboxylic dianhydrides such as pyromellitic dianhydride, 3,3′,4,4′-benzophenonetetracarboxylic dianhydride, 3,3′,4,4′-diphenyltetracarboxylic dianhydride, 2,3,6,7-naphthalenetetracarboxylic dianhydride, 1,4,5,8-naphthalenetetracarboxylic dianhydride, 4,4′-sulfonyldiphthalic dianhydride, 2,2-bis(3,4-dicarboxyphenyl)propane dianhydride, bis(3,4-dicarboxyphenyl)ether dianhydride, 4,4′-[3,3′-(alkylphosphoryldiphenylene)-bis(iminocarbonyl)]diphthalic dianhydride, an adduct of hydroquinonediacetate and trimellic anhydride, and an adduct of diacetyldiamine and trimellic anhydride; alicyclic tetracarboxylic dianhydrides such as 5-(2,5-dioxotetrahydrofuryl)-3-methyl-3-cyclohexy-1,2-dicarboxylic anhydride (trade name: EPICHLONE B-4400, manufactured by Dainippon Ink and Chemicals Inc.), 1,2,3,4-cyclopentanetetracarboxylic dianhydride, 1,2,4,5-cyclohexanetetracarboxylic dianhydride, and tetrahydrofurantetracarboxylic dianhydride; and aliphatic tetracarboxylic dianhydrides such as 1,2,3,4-butanetetracarboxylic dianhydride and 1,2,4,5-pentanetetracarboxylic dianhydride.

As a method of introducing a compound obtained by ring-opening of these tetracarboxylic dianhydrides with a diol compound, into a polyurethane resin, for example, there are the following methods.
a) A method of reacting a compound having an alcoholic terminal obtained by ring-opening of a tetracarbxylic dianhydride with a diol compound, and a diisocyanate compound.
b) A method of reacting a urethane compound having an alcoholic terminal obtained by reacting a diisocyanate compound under the condition of an excessive diol compound, and a tetracarboxylic dianhydride.

Examples of the diol compound used in the ring-opening reaction thereupon include the following compounds.

That is, examples thereof include ethylene glycol, diethylene glycol, triethylene glycol, tetraethylene glycol, propylene glycol, dipropylene glycol, polyethylene glycol, polypropylene glycol, neopentyl glycol, 1,3-butylene glycol, 1,6-hexanediol, 2-butene-1,4-diol, 2,2,4-trimethyl-1,3-pentanediol, 1,4-bis-β-hydroxyethoxycyclohexane, cyclohaxanedimethanol, tricyclodecanedimethanol, hydrogenated bisphenol A, hydrogenated bisphenol F, an ethylene oxide adduct of bisphenol A, an propylene oxide adduct of bisphenol A, an ethylene oxide adduct of bisphenol F, a propylene oxide adduct oxide of bisphenol F, an ethylene oxide adduct of hydrogenated bisphenol A, a propylene oxide adduct of hydrogenated bisphenol A, hydroquinonedihydroxyethyl ether, p-xylylene glycol, dihydroxyethylsulfone, bis(2-hydroxyethyl)-2,4-tolylene dicarbamate, 2,4-tolylene-bis(2-hydroxyethylcarbamide), bis(2-hydroxyethyl)-m-xylylene dicarbamate, and bis(2-hydroxyethyl)isophthalate.

Other Copolymerizable Components

A polyurethane resin used as the specific binder polymer in the invention may contain an organic group containing at least one of an ether bond, an amido bond, a urea bond, an ester bond, a urethane bond, a biuret bond, and an allophanate bond as a functional group, in addition to a urethane bond.

It is preferable that a polyurethane resin used as the specific binder polymer further has a unit having an ethylenic unsaturated bond. It is preferable that the polyurethane resin having a unit having an ethylenic unsaturated bond has at least one of functional groups represented by the following formulas (E1) to (E3) in a side chain of a polyurethane resin. First, functional groups represented by the following formulas (E1) to (E3) will be explained.

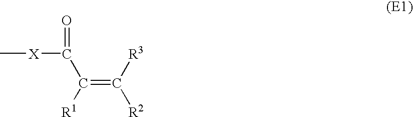

In Formula (E1), R¹ to R³ each represent independently a hydrogen atom or a monovalent organic group. Examples of R¹ include preferably a hydrogen atom, and an alkyl group optionally having a substituent and, among them, a hydrogen atom, and a methyl group are preferable due to high radical reactivity. R² and R³ each represent independently a hydrogen atom, a halogen atom, an amino group, a carboxyl group, an alkoxycarbonyl group, a sulfo group, a nitro group, a cyano group, an alkyl group optionally having a substituent, an aryl group optionally having a substituent, an alkoxy group optionally having a substituent, an aryloxy group optionally having a substituent, an alkylamino group optionally having a substituent, an arylamino group optionally having a substituent, an alkylsulfonyl group optionally having a substituent, or an arylsulfonyl group optionally having a substituent and, among them, a hydrogen atom, a carboxyl group, an alkoxy carbonyl group, an alkyl group optionally having a substituent, and an aryl group optionally having a substituent are preferable due to high radical reactivity.

X represents an oxygen atom, a sulfur atom, or —N(R¹²)—, and R¹² represents a hydrogen atom, or a monovalent organic group. Herein, example of the monovalent organic group include an alkyl group optionally having a substituent. Among them, R¹² is preferably a hydrogen atom, a methyl group, an ethyl group, or an isopropyl group due to high radical reactivity.

Herein, examples of the substituent which may be introduced include an alkyl group, an alkenyl group, an alkynyl group, an aryl group, an alkoxy group, an aryloxy group, a halogen atom, an amino group, an alkyl amino group, an arylamino group, a carboxyl group, an alkoxycarbonyl group, a sulfo group, a nitro group, a cyano group, an amido group, an alkylsulfonyl group, and an arylsulfonyl group.

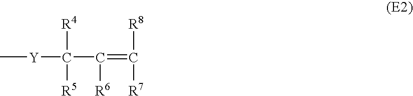

In Formula (E2), R⁴ to R⁸ each represent independently a hydrogen atom or a monovalent organic group. R⁴ to R⁸ preferably represent a hydrogen atom, a halogen atom, an amino group, a dialkylamino group, a carboxyl group, an alkoxycarbonyl group, a sulfo group, a nitro group, a cyano group, an alkyl group optionally having a substituent, an aryl group optionally having a substituent, an alkoxy group optionally having a substituent, an aryloxy group optionally having a substituent, an alkylamino group optionally having a substituent, an arylamino group optionally having a substituent, an alkylsulfonyl group optionally having a substituent, and an arylsulfonyl group optionally having a substituent and, among them, a hydrogen atom, a carboxyl group, an alkoxycarbonyl group, an alkyl group optionally having a substituent, and an aryl group optionally having a substituent are preferable.

As a group which may be introduced as the substituent, the same substituents as those for Formula (E1) are exemplified. Y represents an oxygen atom, a sulfur atom, or —N(R¹²)—. R¹² has the same meaning as that of R¹² of Formula (E1), and a preferable example is similar.

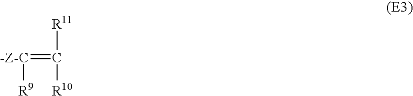

In Formula (E3), R⁹ to R¹¹ each represent independently a hydrogen atom or a monovalent organic group. Examples of R⁹ include preferably a hydrogen atom and an alkyl group optionally having a substituent and, among them, a hydrogen atom, and a methyl group are preferable due to high radical reactivity. R¹⁰ and R¹¹ each represent independently a hydrogen atom, a halogen atom, an amino group, a dialkylamino group, a carboxyl group, an alkoxycarbonyl group, a sulfo group, a nitro group, a cyano group, an alkyl group optionally having a substituent, an aryl group optionally having a substituent, an alkoxy group optionally having a substituent, an aryloxy group optionally having a substituent, an alkylamino group optionally having a substituent, an arylamino group optionally having a substituent, an alkylsulfonyl group optionally having a substituent, or an arylsulfonyl group optionally having a substituent and, among them, a hydrogen atom, a carboxyl group, an alkoxycarbonyl group, an alkyl group optionally having a substituent, and an aryl group optionally having a substituent are preferable due to high radical reactivity.

Herein, as a group which may be introduced as the substituent, the same groups as those for Formula (E1) are exemplified. Z represents an oxygen atom, a sulfur atom, —N(R¹³)—, or a phenylene group optionally having a substituent. R¹³ represents an alkyl group optionally having a substituent and, inter alia, a methyl group, an ethyl group, and an isopropyl group are preferable due to high radical reactivity.

As a method of introducing an ethylenic unsaturated bond into a side chain of a polyurethane resin, a method of using a diol compound containing an ethylenic unsaturated bond as a raw material for producing a polyurethane resin is also suitable. Such a diol compound may be a commercially available compound such as trimethylolpropane monoallyl ether, or may be a compound which is easily produced by a reaction of a halogenated diol compound, a triol compound, or an aminodiol compound, and a carboxylic acid, acid chloride, isocyanate, alcohol, amine, thiol, or a halogenated alkyl compound containing an ethylenic unsaturated bond. Specific examples of these compounds are not limited to, but include the following compounds.

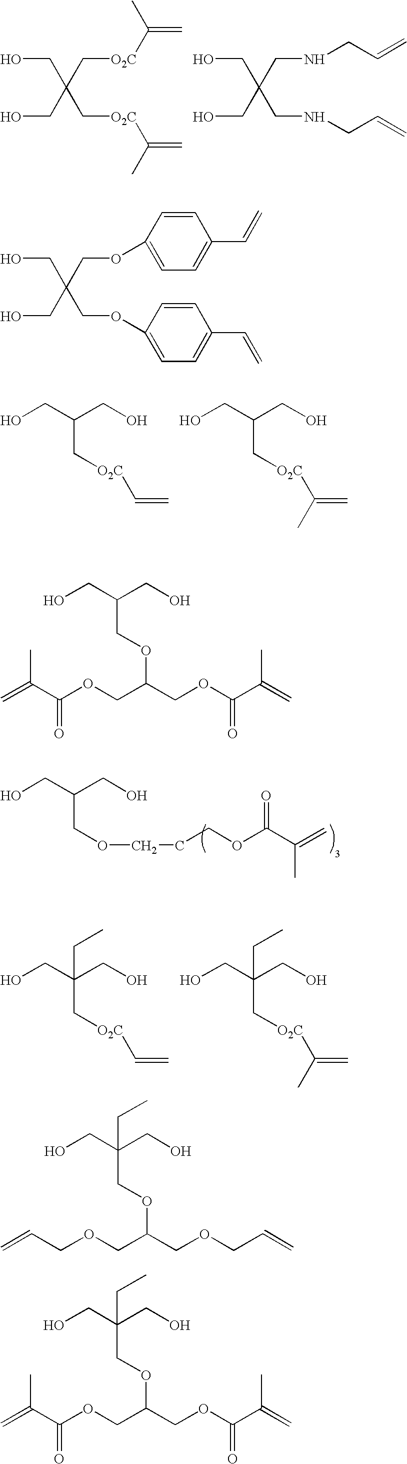

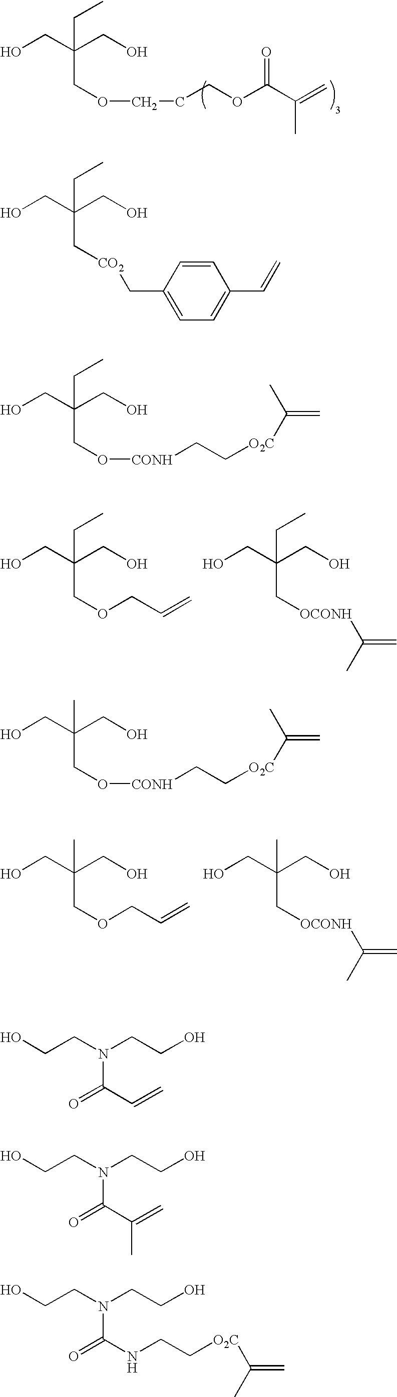

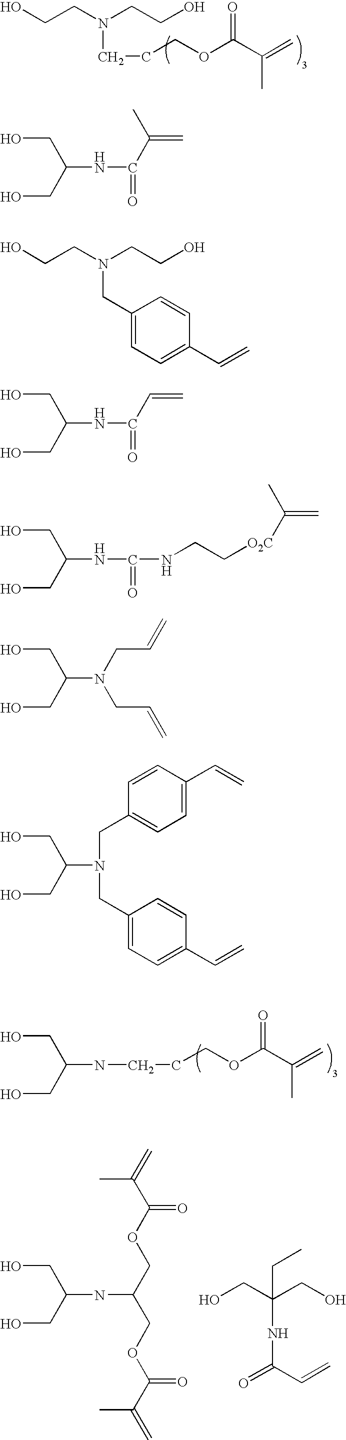

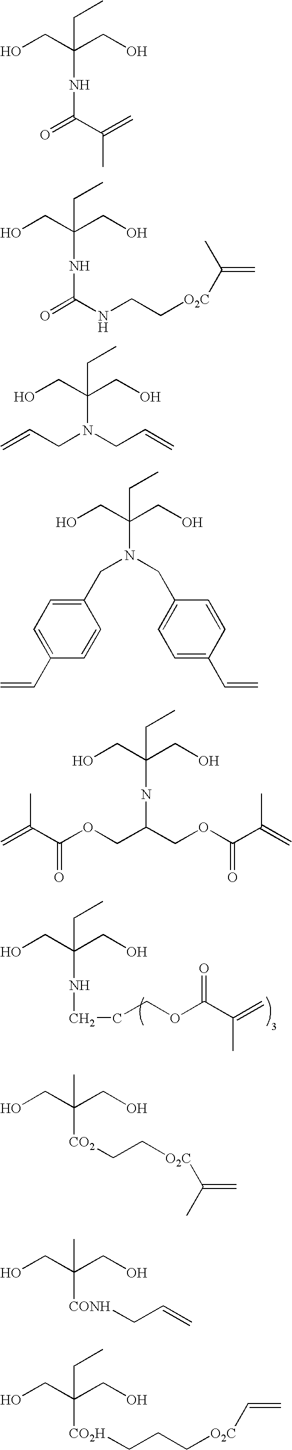

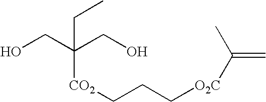

In addition, as a more preferable polyurethane resin, a polyurethane resin obtained using a diol compound represented by the following Formula (G) as at least one of diol compounds having an ethylenic unsaturated bond group upon synthesis of a polyurethane resin is exemplified.

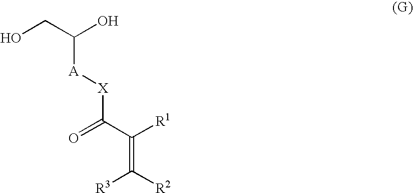

In Formula (G), R¹ to R³ each represent independently a hydrogen atom or a monovalent organic group, A represents a divalent organic residue, X represents an oxygen atom, a sulfur atom, or —N(R¹²)—, and R¹² represents a hydrogen atom, or a monovalent organic group.

R¹ to R³ and X in this Formula (G) have the same meanings as those of R¹ to R³ and X in Formula (E1), and a preferable embodiment is similar.

A divalent organic residue represented by the A is a divalent organic linking group which contains a carbon atom and a hydrogen atom, and optionally an atom selected from an oxygen atom, a nitrogen atom, and a sulfur atom. Preferable is a divalent organic linking group which is constructed by suitably combining —C(═O)—, —C(═O)—O—, —C(═O)—NH—, —NH—C(═O)—O—, —NH—C(═O)—NH—, alkylene group, allylene group, or a group constructed by combining them and further —O—, —S—, or —NH—. The number of atoms constructing a linking chain contained in this divalent organic linking group is suitably within 60 and, from a viewpoint that film forming property is kept good, is preferably within 50, more preferably within 40.

It is thought that, by using a polyurethane resin derived from these diol compounds, the effect of suppressing excessive molecular motion of a polymer main chain due to a secondary alcohol having great steric hindrance is obtained, and improvement in a film strength of the film formed by using the resin composition of the invention is attained.

Examples of the diol compound represented by Formula (G) which is suitably used in synthesizing a polyurethane resin will be shown below.

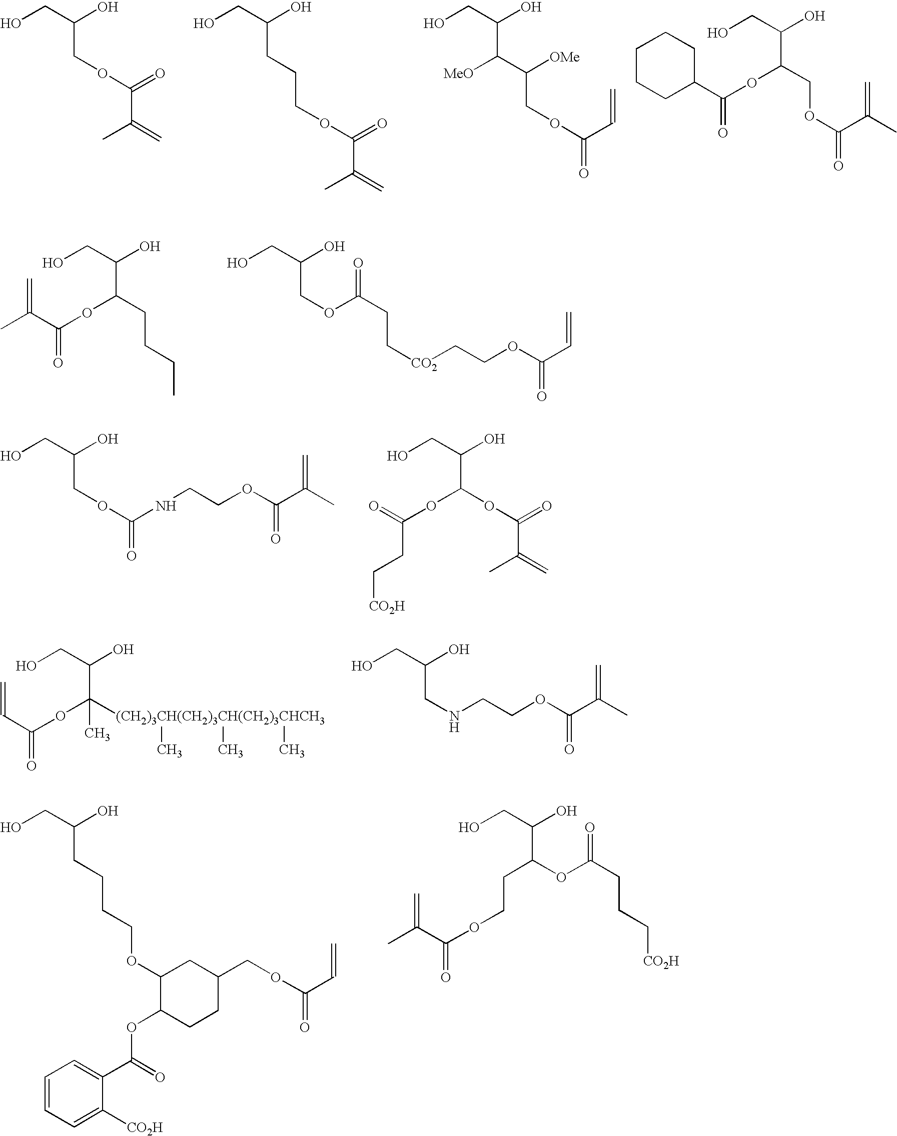

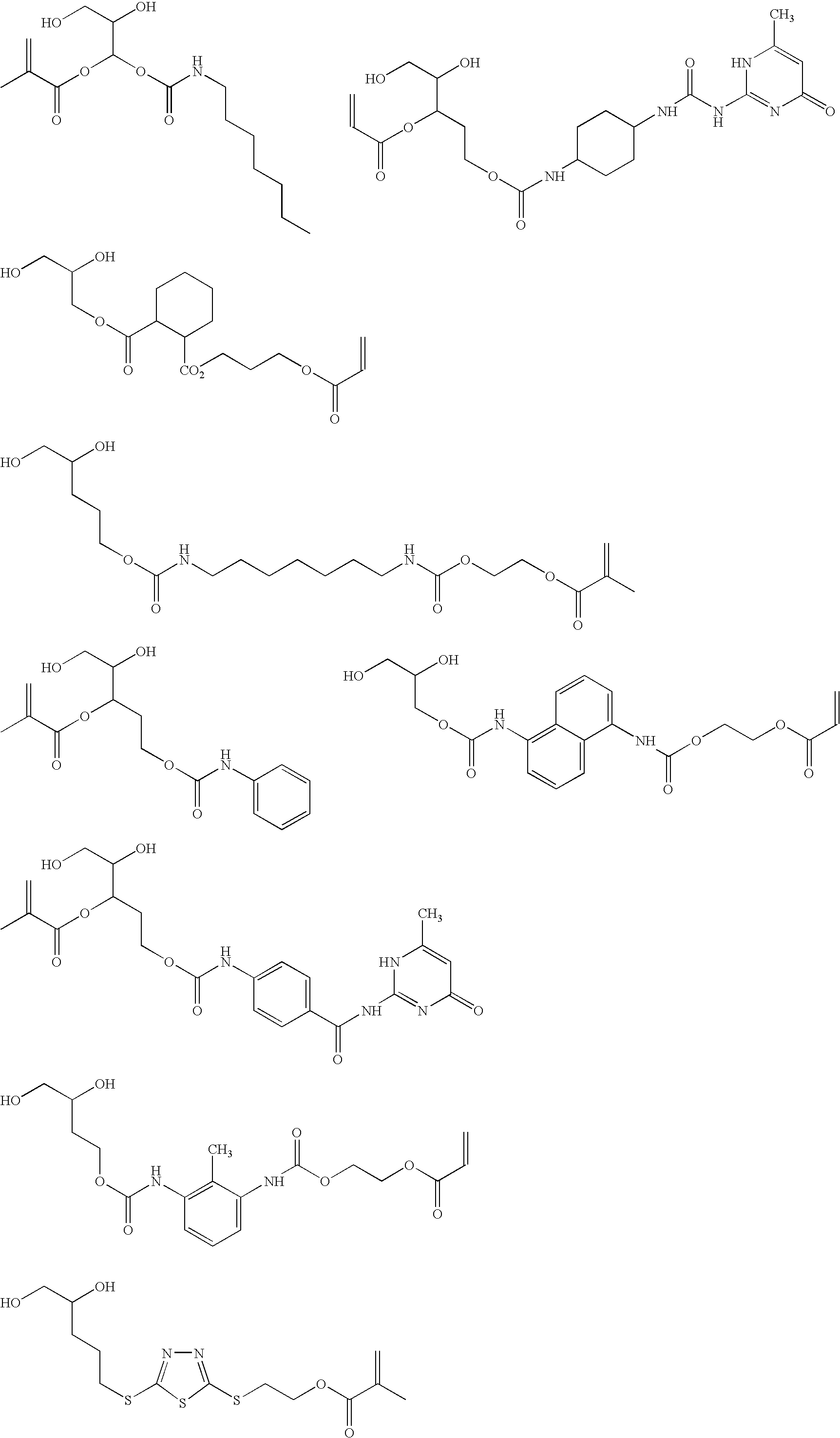

When synthesizing a polyurethane resin under the NCO group excessive condition where an NCO/OH ratio is 1 or more, a main chain terminal is an NCO group, and thus, by separately adding hereto an alcohol having an ethylenic unsaturated bond (2-hydroxyethyl(meth)acrylate, trade name: BLEMMER PME200, manufactured by NOF Corporation) etc.), an ethylenic unsaturated bond may be introduced into a main chain terminal.

That is, as a polyurethane resin suitable in the invention, a resin having an ethylenic unsaturated group not only in a side chain but also in a main chain terminal is also preferable.

As a polyurethane resin suitable in the invention, as described above, in addition to a resin having an ethylenic unsaturated bond in a side chain, a resin having an ethylenic unsaturated bond in a main chain terminal and/or a main chain is also suitably used.

As a method of introducing an ethylenic unsaturated bond into a main chain terminal of a polyurethane resin, there is the following method.

That is, when synthesizing a polyurethane resin, in a step of treating an isocyanate group remaining in a main chain terminal of the resulting intermediate product with alcohols or amines, alcohols or amines having an ethylenic unsaturated group may be used.

As a method of introducing an ethylenic unsaturated bond into a main chain of a polyurethane resin, there is a method of using a diol compound having an ethylenic unsaturated bond in a chain linking an OH group and an OH group in synthesis of a polyurethane resin. Examples of the diol compound having an ethylenic unsaturated bond in a chain linking an OH group and an OH group include the following compounds.

That is, examples thereof include cis-2-butene-1,4-diol, trans-2-butene-1,4-diol, and polybutadiendiol.

From a viewpoint that an introduction amount is easily controlled, and an introduction amount may be increased, or a crosslinking reaction efficacy is improved, it is preferable that an ethylenic unsaturated bond is introduced into a side chain rather than into a main chain terminal of a polyurethane resin.

As an ethylenic unsaturated bond group to be introduced, from a viewpoint of crosslinked cured film forming property, a mathacryloyl group, an acryloyl group, and styryl group are preferable and, a methacryloyl group and an acryloyl group are more preferable. From a viewpoint of realization of both of forming property and unused stock storability of a crosslinked cured film, a methacryloyl group is further preferable.

Regarding an amount of an ethylenic unsaturated bond contained in a polyurethane resin used in the invention, an ethylenic unsaturated bond group is contained in a side chain in an amount of preferably 0.3 meq/g or more, further preferably 0.35 to 1.50 meq/g as expressed by equivalent. That is, a polyurethane resin containing a methacryloyl group in a side chain in an amount of 0.35 to 1.50 meq/g is most preferable.

A weight average molecular weight of a polyurethane resin as the specific binder polymer in the invention is preferably 10,000 or more, more preferably in the range of 40,000 to 200,000. Particularly, when a polyurethane resin having a molecular weight in this range is used, a strength of a formed resin molded product such as relief layer is excellent.

A polyurethane resin used as the specific binder polymer in the invention is synthesized by heating the diisocyanate compound and the diol compound in an aprotic solvent with the addition of the known catalyst having activity according to each reactivity. A molar ratio (Mₐ:M_{b}) of the diisocyanate and diol compounds used in synthesis is preferably 1:1 to 1.2:1.1 and, by treating with alcohols or amines, a product having desired physical properties such as a molecular weight and a viscosity is synthesized in such a final form that an isocyanate group does not remain.

Inter alia, synthesis using a bismuth catalyst is more preferable than a tin catalyst which has been previously used frequently, from a viewpoint of the environment and a polymerization rate. As such a bismuth catalyst, trade name: NEOSTAN U-600 manufactured by NITTO CHEMICAL INDUSTRY co., ltd.. is particularly preferable.

Examples of the specified polyurethane resin used in the invention are shown below, but the invention is not limited by them.

| Polyurethane | |
|---|---|
| resin | Diisocyanate compound used (mol %) |
| P-1 | 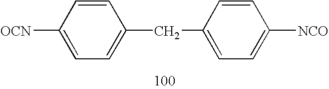 |
| P-2 | 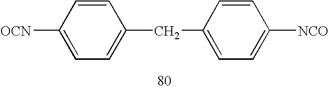 |
| | 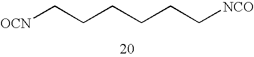 |
| P-3 | 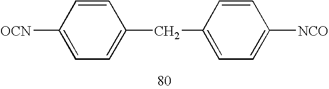 |
| | 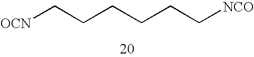 |
| P-4 | 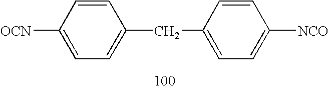 |
| P-5 | 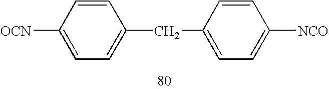 |
| | 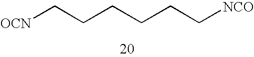 |
| P-6 | 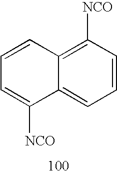 |
| P-7 | 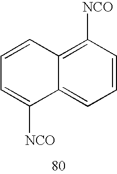 |
| | 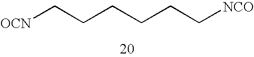 |
| P-8 | 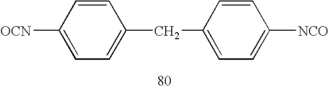 |
| | 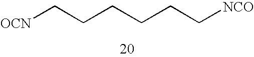 |
| P-9 | 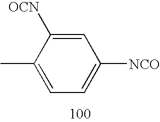 |
| P-10 | 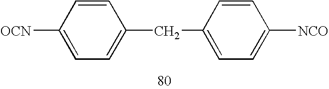 |
| | 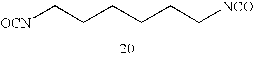 |
| P-11 | 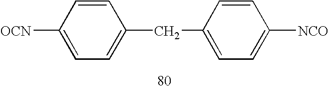 |
| | 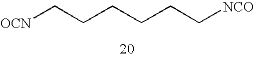 |
| P-12 | 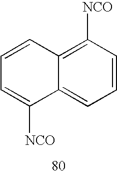 |
| | 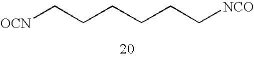 |
| P-13 | 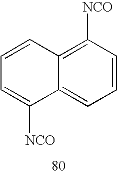 |
| | 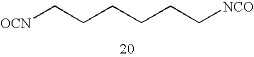 |
| P-14 | 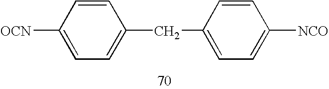 |
| | 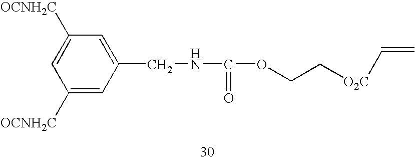 |
| P-15 | 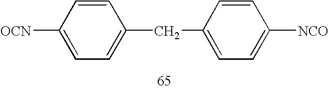 |
| | 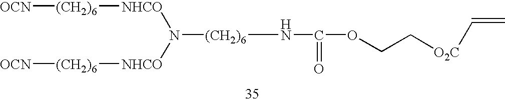 |
| P-16 | 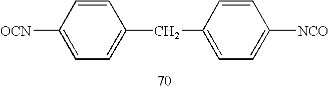 |
| | 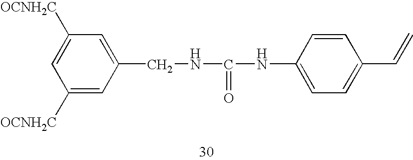 |
| P-17 | 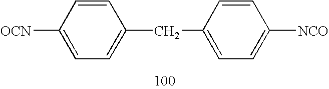 |
| P-18 | 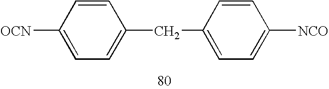 |
| | 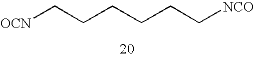 |
| P-19 | 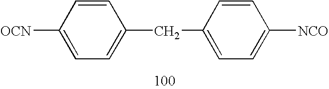 |
| P-20 | 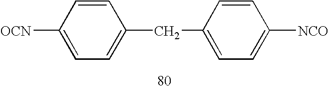 |
| | 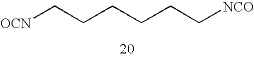 |
| P-21 | 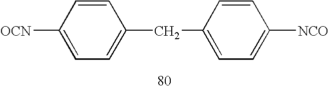 |
| | 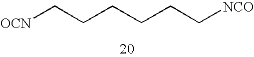 |
| P-22 | 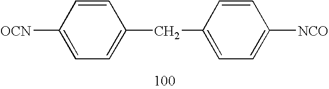 |
| P-23 | 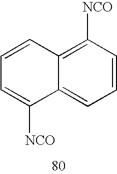 |
| | 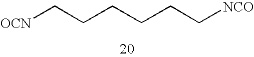 |
| P-24 | 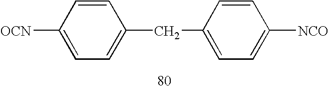 |
| | 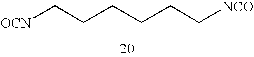 |
| P-25 | 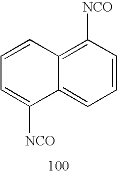 |
| P-26 | 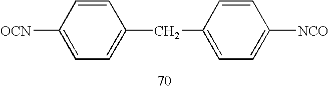 |
| | 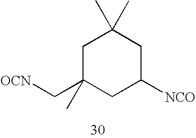 |
| P-27 | 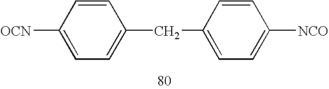 |
| | 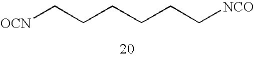 |
| P-28 | 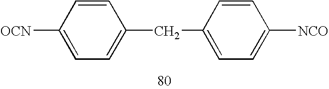 |
| | 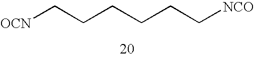 |
| P-29 | 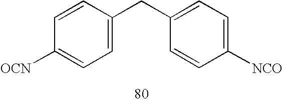 |
| | 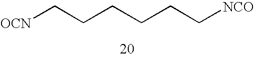 |
| P-30 | 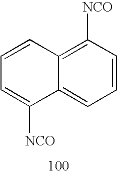 |
| P-31 | 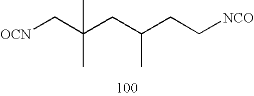 |
| P-32 | 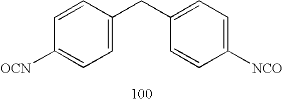 |
| P-33 | 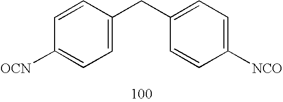 |

| | | Weight |
|---|---|---|
| | | average |
| Polyurethane | | molecular |
| resin | Diol compound used (mol %) | weight |
| P-1 | 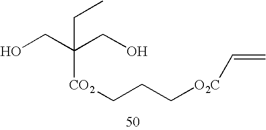 | 95,000 |
| | 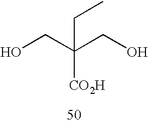 | |
| P-2 | 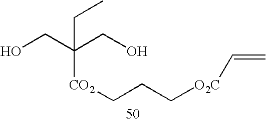 | 98,000 |
| | 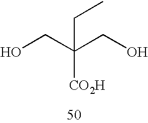 | |
| P-3 | 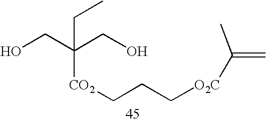 | 103,000 |
| | 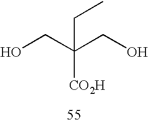 | |
| P-4 | 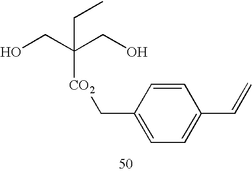 | 108,000 |
| | 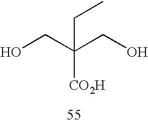 | |
| P-5 | 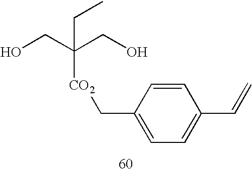 | 99,000 |
| | 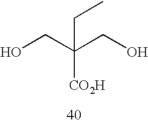 | |
| P-6 | 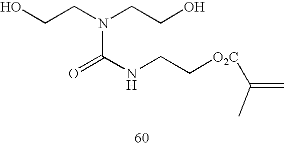 | 96,000 |
| | 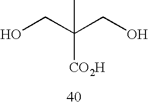 | |
| P-7 | 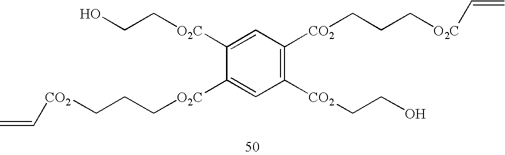 | 68,000 |
| | 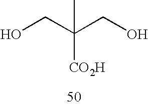 | |
| P-8 | 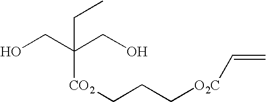 | 96,000 |
| | 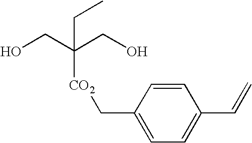 | |
| | 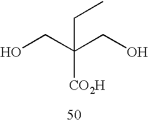 | |
| P-9 | 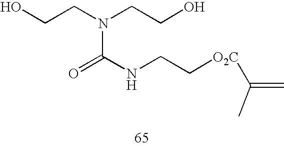 | 100,000 |
| | 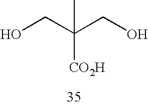 | |
| P-10 | 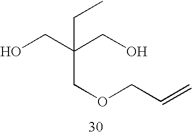 | 69,000 |
| | 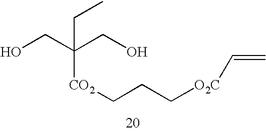 | |
| | 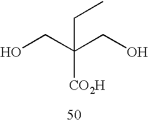 | |
| P-11 | 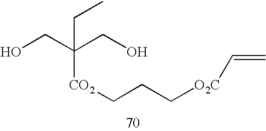 | 120,000 |
| | 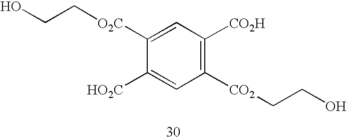 | |
| P-12 | 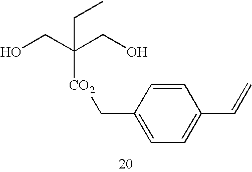 | 78,000 |
| | 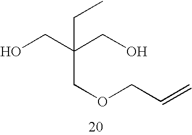 | |
| | 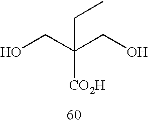 | |
| P-13 | 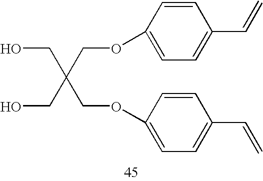 | 103,000 |
| | 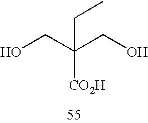 | |
| P-14 | 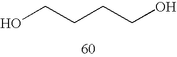 | 65,000 |
| | 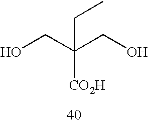 | |
| P-15 | 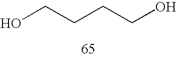 | 78,000 |
| | 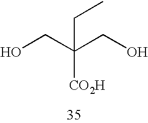 | |
| P-16 | 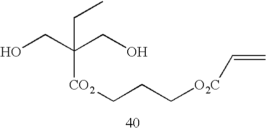 | 69,000 |
| | 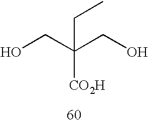 | |
| P-17 | 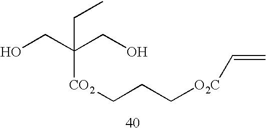 | 99,000 |
| | 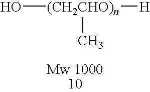 | |
| | 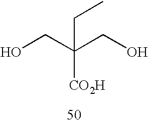 | |
| P-18 | 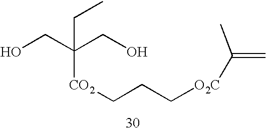 | 87,000 |
| | 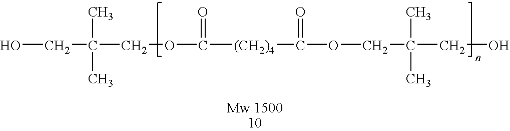 | |
| | 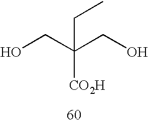 | |
| P-19 | 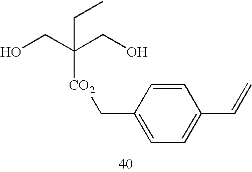 | 97,000 |
| | 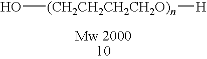 | |
| | 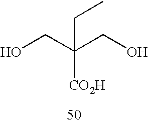 | |
| P-20 | 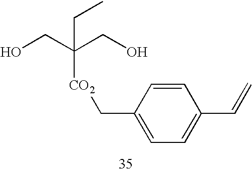 | 103,000 |
| | 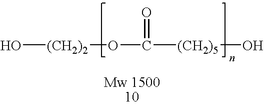 | |
| | 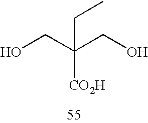 | |
| P-21 | 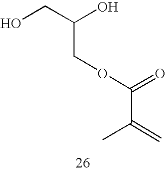 | 60,000 |
| | 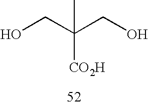 | |
| | 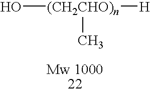 | |
| P-22 | 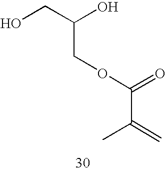 | 70,000 |
| | 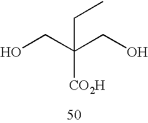 | |
| | 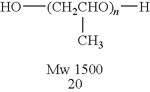 | |
| P-23 | 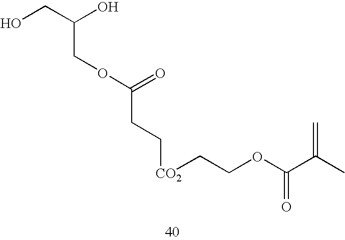 | 50,000 |
| | 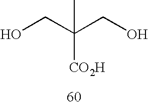 | |
| P-24 | 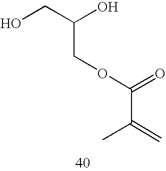 | 75,000 |
| | 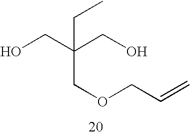 | |
| | 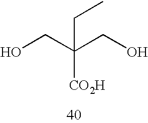 | |
| P-25 | 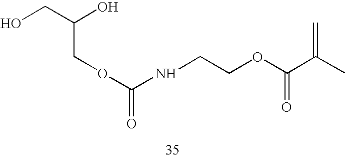 | 80,000 |
| | 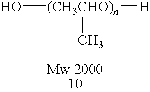 | |
| | 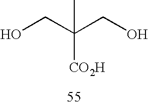 | |
| P-26 | 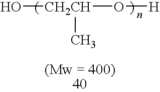 | 50,000 |
| | 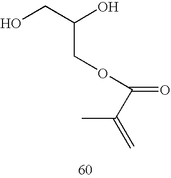 | |
| P-27 | 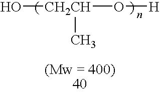 | 60,000 |
| | 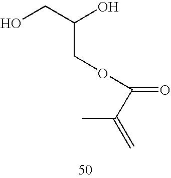 | |
| | 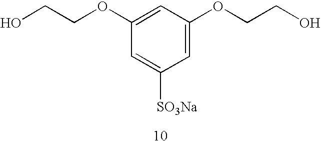 | |
| P-28 | 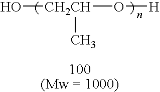 | 59,000 |
| P-29 | 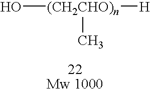 | 63,000 |
| | 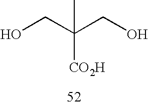 | |
| | 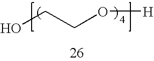 | |
| P-30 | 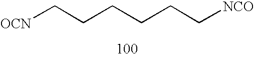 | 32,000 |
| P-31 | 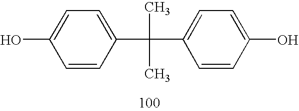 | 21,000 |
| P-32 | 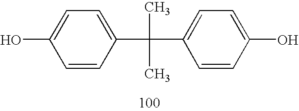 | 29,000 |
| P-33 | 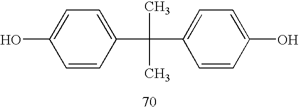 | 41,000 |
| | 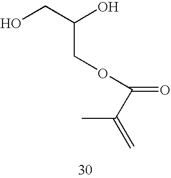 | |

A polyurethane resin as the specific binder polymer in the invention has the characteristic that it is thermally decomposed at a relatively low temperature (lower than 250° C.) as compared with a binder polymer used in the normal resin composition for laser engraving (in the case of a commercially available general-use resin, it is thermally decomposed at a high temperature of 300° C. to 400° C. in most cases). Therefore, the resin composition containing such a polyurethane resin may be decomposed at a high sensitivity.

In addition, in a system in which such a polyurethane resin is used as the specific binder polymer and an additional binder polymer described later is used together, even in the state where these polymers are not uniformly mixed and are phase-separated, first, this polyurethane resin is decomposed by heat production with laser irradiation and, as a result, a gas (nitrogen etc.) generated upon thermal decomposition and vaporization of the polyurethane resin assists and promotes vaporization of the additional binder polymer. For this reason, the relief forming layer using such a polyurethane resin as the specified alcoholphilic polymer also has an advantage that, even when the additional binder polymer is present, laser decomposability is improved, and a high sensitivity is attained.

The content of the specific binder polymer in the resin composition of the invention is preferably 2% by mass to 95% by mass, more preferably 5% by mass to 80% by mass, and particularly preferably 10% by mass to 60% by mass, from the viewpoint of satisfying, in a well-balanced manner, the shape retention, water resistance and engraving sensitivity of the resin molded product formed from the resin composition.

Other Binder Polymers

The resin composition of the invention may contain, in addition to the specific binder polymer, a known binder polymer which is not included in the specific binder polymer.

Hereinafter, such a binder polymer that is used in combination with the specific binder polymer will be referred to as an “other binder” in the following descriptions.

As the other binder, usually a thermoplastic resin, a thermoplastic elastomer and the like are used according to the purpose, from the viewpoint of the recording sensitivity to laser light.

That is, the other binder is used for the purpose of imparting desired properties to a resin molded product such as a relief forming layer, when used in combination with the specific binder polymer.

For example, when the other binder is used for the purpose of enhancing strength through curing by heating or exposure, a polymer having a carbon-carbon unsaturated bond in the molecule is selected. When the other binder is used for the purpose of forming a pliable film having flexibility, a soft resin or a thermoplastic elastomer is selected.

From the viewpoints of the ease of preparation of a coating liquid for relief forming layer used for forming a relief forming layer, or an enhancement of resistance to oily ink in relief printing plates that are obtained, it is preferable to use a hydrophilic polymer or an alcoholphilic polymer.

From the viewpoint of laser engraving sensitivity, a polymer including a partial structure which is thermally decomposed by exposure or heating is preferable.

As such, binder polymers that are suitable for the purpose may be selected in consideration of the properties in accordance with the application use of the resin composition of the invention, and the other binder polymers may be used singly or in combination of two or more species thereof, together with the specific binder polymer described above.

The total amount of the binder polymers (that is, the total amount of the specific binder polymer and the other binder) in the resin composition of the invention is preferably from 2% by mass to 99% by mass, and more preferably from 5% by mass to 80% by mass.

Hereinafter, various polymers that may be used as the other binder according to the invention will be described.

Polymer Having Carbon-Carbon Unsaturated Bond

A polymer having carbon-carbon unsaturated bonds in the molecule, which is not included in the specific binder polymer, may be suitably used as the other binder. The carbon-carbon unsaturated bonds may be present in either the main chain or the side chains, or may also be present in both of the chains. Hereinafter, the carbon-carbon unsaturated bond may also be simply referred to as an “unsaturated bond”, and a carbon-carbon unsaturated bond present at an end of the main chain or side chain may also be referred to as a “polymerizable group”.

In the case where the polymer has carbon-carbon unsaturated bonds in the main chain thereof, the polymer may have the unsaturated bonds at one terminal thereof, at both terminals thereof, and/or within the main chain thereof. Furthermore, in the case where the polymer has carbon-carbon unsaturated bonds in a side chain thereof, the unsaturated bonds may be directly attached to the main chain, and/or may be attached to the main chain via an appropriate linking group.

Examples of the polymer containing carbon-carbon unsaturated bonds in the main chain include SB (polystyrene-polybutadiene), SBS (polystyrene-polybutadiene-polystyrene), SIS (polystyrene-poly isoprene-polystyrene), SEBS (polystyrene-polyethylene/polybutylene-polystyrene), and the like.

In the case of using a polymer having a highly reactive polymerizable unsaturated group such as a methacryloyl group as the polymer having carbon-carbon unsaturated bonds in the side chain, a film having very high mechanical strength may be produced. Particularly, highly reactive polymerizable unsaturated groups may be relatively easily introduced into the molecule into polyurethane thermoplastic elastomers and polyester thermoplastic elastomers.

Any known method may be employed when introduce unsaturated bonds or polymerizable groups into the binder polymer. Examples of the method include: a method of copolymerizing the polymer with a structural unit having a polymerizable group precursor which is formed by attaching a protective group to the polymerizable group, and eliminating the protective group to restore the polymerizable group; and a method of producing a polymer compound having a plurality of reactive groups such as a hydroxyl group, an amino group, an epoxy group, a carboxyl group, an acid anhydride group, a ketone group, a hydrazine residue, an isocyanate group, an isothiacyanate group, a cyclic carbonate group or an ester group, subsequently reacting the polymer compound with a binding agent which has a plurality of groups capable of binding with the reactive group (for example, polyisocyanate and the like for the case of a hydroxyl group or an amino group), to thereby carry out adjustment of the molecular weight and conversion to a bindable group at the chain end, and then reacting this group which is capable of reacting with the terminal bindable group, with an organic compound having a polymerizable unsaturated group, to thus introduce a polymerizable group by means of a polymer reaction. When these methods are used, the amount of introduction of the unsaturated bond or the polymerizable group into the polymer compound may be controlled.

It is also preferable to use the polymer having an unsaturated bond in combination with a polymer which does not have an unsaturated bond. That is, since a polymer obtainable by adding hydrogen to the olefin moiety of the polymer having carbon-carbon unsaturated bonds, or a polymer obtainable by forming a polymer using as a raw material a monomer in which an olefin moiety has been hydrogenated, such as a monomer resulting from hydrogenation of butadiene, isoprene or the like, has excellent compatibility, the polymer may be used in combination with the polymer having unsaturated bonds, so as to regulate the amount of unsaturated bonds possessed by the binder polymer.

In the case of using these in combination, the polymer which does not have unsaturated bonds may be used in a proportion of generally 1 parts by mass to 90 parts by mass, and preferably 5 parts by mass to 80 parts by mass, with respect to 100 parts by mass of the polymer having unsaturated bonds.

As will be discussed later, in aspects where curability is not required for the binder polymer, such as in the case of using another polymerizable compound in combination, the binder polymer does not necessarily contain an unsaturated bond, and a variety of polymers which do not have unsaturated bonds may be solely used as the binder polymer in the relief forming layer. Examples of the polymer which does not have unsaturated bonds and can be used in such a case include polyesters, polyamides, polystyrene, acrylic resins, acetal resins, polycarbonates and the like.

The binder polymer suitable for the use in the invention, which may or may not have unsaturated bonds, has a number average molecular weight preferably in the range of from 1,000 to 1,000,000, and more preferably in the range of from 5,000 to 500,000. When the number average molecular weight of the binder polymer is in the range of 1,000 to 1,000,000, the mechanical strength of the film to be formed may be secured. Here, the number average molecular weight is a value measured using gel permeation chromatography (GPC), and reduced with respect to polystyrene standard products with known molecular weights.

Thermoplastic Polymer and Polymer having Decomposability

Examples of the other binder polymer which may be preferably used from the viewpoint of assuring laser engraving sensitivity include a thermoplastic polymer which can be liquefied by being imparted with energy by means of exposure and/or heating, and a polymer having a partial structure which can be decomposed by being imparted with energy by means of exposure and/or heating.

Examples of the polymer having decomposability include those polymers containing, as a monomer unit having in the molecular chain a partial structure which is likely to be decomposed and cleaved, styrene, a-methylstyrene, a-methoxystyrene, acryl esters, methacryl esters, ester compounds other than those described above, ether compounds, nitro compounds, carbonate compounds, carbamoyl compounds, hemiacetal ester compounds, oxyethylene compounds, aliphatic cyclic compounds, and the like.

In view of the reasons similar to those for the binder polymer (A), the other binder can be preferably selected from those having a glass transition temperature (Tg) of 20° C. or more and less than 200° C., more preferably from those having a Tg being in a range from 20° C. to 170° C., and particuarly preferably from those having a Tg being in a range from 25° C. to 150° C.

Among these, polyethers such as polyethylene glycol, polypropylene glycol and polytetraethylene glycol, aliphatic polycarbonates, aliphatic carbamates, polymethyl methacrylate, polystyrene, nitrocellulose, polyoxyethylene, polynorbornene, polycyclohexadiene hydrogenation products, or a polymer having a molecular structure having many branched structures such as dendrimers, may be particularly preferably exemplified in terms of decomposability.

A polymer containing a number of oxygen atoms in the molecular chain is preferable from the viewpoint of decomposability. From this point of view, compounds having a carbonate group, a carbamate group or a methacryl group in the polymer main chain, may be suitably exemplified.

For example, a polyester or polyurethane synthesized from a (poly)carbonate diol or a (poly)carbonate dicarboxylic acid as the raw material, a polyamide synthesized from a (poly)carbonate diamine as the raw material, and the like may be exemplified as the examples of polymers having good thermal decomposability. These polymers may also be those containing a polymerizable unsaturated group in the main chain or the side chains. Particularly, in the case of a polymer having a reactive functional group such as a hydroxyl group, an amino group or a carboxyl group, it is also easy to introduce a polymerizable unsaturated group into such a thermally decomposable polymer.

The thermoplastic polymer may be an elastomer or a non-elastomer resin, and may be selected according to the purpose of the resin composition of the invention, while it can be preferably a non-elastomer resin, namely a polymer having a Tg of 20° C. or more and less than 200° C., more preferably those having a Tg being in a range from 20° C. to 170° C., and particuarly preferably those having a Tg being in a range from 25° C. to 150° C.

Examples of the thermoplastic elastomer include urethane thermoplastic elastomers, ester thermoplastic elastomers, amide thermoplastic elastomers, silicone thermoplastic elastomers and the like. For the purpose of enhancing the laser engraving sensitivity of such a thermoplastic elastomer, an elastomer in which an easily decomposable functional group such as a carbamoyl group or a carbonate group has been introduced into the main chain, may also be used. A thermoplastic polymer may also be used as a mixture with the thermally decomposable polymer.

The thermoplastic elastomer is a material showing rubber elasticity at normal temperature, and the molecular structure includes a soft segment such as polyether or a rubber molecule, and a hard segment which prevents plastic deformation near normal temperature, as vulcanized rubber does. There exist various types of hard segments, such as frozen state, crystalline state, hydrogen bonding and ion bridging. Such thermoplastic elastomers may be suitable in the case of applying the resin composition of the invention to the production of, for example, relief printing plates requiring plasticity, such as flexo plates.

The kind of the thermoplastic elastomer can be selected according to the purpose. For example, in the case where solvent resistance is required, urethane thermoplastic elastomers, ester thermoplastic elastomers, amide thermoplastic elastomers and fluorine thermoplastic elastomers are preferable. In the case where thermal resistance is required, urethane thermoplastic elastomers, olefin thermoplastic elastomers, ester thermoplastic elastomers and fluorine thermoplastic elastomers are preferable. The hardness of a resin molded product formed from the resin composition can be largely varied according to the selection of the kind of the thermoplastic elastomer.

The use of the thermoplastic elastomer can be effective to provide flexibility to a film formed from the resin composition to provide a so-called flexo printing plate. The content of the thermoplastic elastomer compounded in the resin composition should be in a certain range so as not to adversely affect functions derived from the specific binder polymer. Specifically, the content of the thermoplastic elastomer is 30% by mass or less with respect to the total amount of the specific binder polymer.

Examples of the non-elastomeric resin include polyester resins include unsaturated polyester resins, polyamide resins, polyamideimide resins, polyurethane resins, unsaturated polyurethane resins, polysulfone resins, polyethersulfone resins, polyimide resins, polycarbonate resins, all aromatic polyester resins, and hydrophilic polymers containing hydroxyethylene units (for example, polyvinyl alcohol compounds).

(C) Polymerizable Compound

The resin composition of the invention preferably contains a polymerizable compound.

The “polymerizable compound” in the invention means a compound having at least one carbon-carbon unsaturated bond capable of radical polymerization triggered by the generation of a starting radical derived from a polymerization initiator. More specific explanation will be given with taking an example of using an addition polymerizable compound as the polymerizable compound.

Examples of the polymerizable compound that can be preferably used in the invention include an addition polymerizable compound having at least one ethylenic unsaturated double bond. This addition polymerizable compound is preferably selected from compounds having at least one, preferably two or more, terminal ethylenic unsaturated bonds. The family of such compounds is widely known in the pertinent industrial field, and these compounds may be used in the invention without any particular limitations. These compounds respectively have a chemical form such as a monomer, a prepolymer such as a dimer or a trimer, an oligomer, a copolymer thereof, or a mixture of any of these. Examples of the monomer include unsaturated carboxylic acids (for example, acrylic acid, methacrylic acid, itaconic acid, crotonic acid, isocrotonic acid, maleic acid, and the like), esters thereof, and amides thereof. Preferable examples thereof include esters of an unsaturated carboxylic acid and an aliphatic polyhydric alcohol compound and amides of an unsaturated carboxylic acid and an aliphatic polyvalent amine compound. Further, unsaturated carboxylic acid esters having a nucleophilic substituent such as a hydroxyl group, an amino group or a mercapto group; adducts of an amide with a monofunctional or polyfunctional isocyanate or an epoxy compound; dehydration condensation reaction products of an amide with a monofunctional or polyfunctional carboxylic acid, and the like may also be suitably used. Unsaturated carboxylic acid esters having an electrophilic substituent such as an isocyanate group or an epoxy group; adducts of an amide with a monofunctional or polyfunctional alcohol, an amine or a thiol; unsaturated carboxylic acid esters having a detachable substituent such as a halogen group or a tosyloxy group; substitution reaction products of an amide with a monofunctional or polyfunctional alcohol, an amine or a thiol, are also suitable. A family of compounds formed by modifying the above-described compounds by introducing an unsaturated phosphonic acid, styrene, vinyl ether or the like in place of the unsaturated carboxylic acid may also be used.

Specific examples of the monomer of an ester between an aliphatic polyhydric alcohol compound and an unsaturated carboxylic acid include, as acrylic acid esters, ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethyelne glycol diacrylate, pentaerythritol diacrylate, pentaerythritol triacrylate, pentaerythritol tetraacrylate, dipentaerythritol diacrylate, dipentaerythritol hexaacrylate, sorbitol triacrylate, sorbitol tetraacrylate, sorbitol pentaacrylate, sorbitol hexaacrylate, tri(acryloyloxyethyl)isocyanurate, a polyester acrylate oligomer, and the like.

Examples of methacrylic acid esters include tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacry late, hexanediol dimethacry late, pentaerythritol dimethacry late, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl]dimethylmethane, bis-[p-(methacryloxyethoxy)phenyl]dimethylmethane, and the like.

Examples of itaconic acid esters include ethylene glycol diitaconate, propylene glycol diitaconate, 1,3-butanediol diitaconate, 1,4-butanediol diitaconate, tetramethylene glycol diitaconate, pentaerythritol diitaconate, sorbitol tetraitaconate, and the like.

Examples of crotonic acid esters include ethylene glycol dicrotonate, tetramethylene glycol dicrotonate, pentaerythritol dicrotonate, sorbitol tetracrotonate, and the like.

Examples of isocrotonic acid esters include ethylene glycol diisocrotonate, pentaerythritol diisocrotonate, sorbitol tetraisocrotonate, and the like.

Examples of maleic acid esters include ethylene glycol dimaleate, triethyelen glycol dimaleate, pentaerythritol dimaleate, sorbitol tetramaleate, and the like.

As examples of other esters, for example, the aliphatic alcohol-based esters described in JP-B Nos. 46-27926, 51-47334 and JP-A No. 57-196231; the esters having an aromatic-based skeleton described in JP-A Nos. 59-5240, 59-5241 and 2-226149; and the esters containing an amino group described in JP-A No. 1-165613; and the like, may also be suitably used.

The ester monomers described above may also be used as mixtures.

Specific examples of the monomer of an amide between an aliphatic polyvalent amine compound and an unsaturated carboxylic acid, include methylenebisacrylamide, methylenebismethacrylamide, 1,6-hexamethylenebisacrylamide, 1,6-hexamethylenebismethacrylamide, diethylenetriamine trisacrylamide, xylylenebisacrylamide, xylylenebismethacrylamide, and the like.

Examples of other preferable amide-based monomers include the monomers having a cyclohexylene structure described in JP-B No. 54-21726.

Furthermore, urethane-based addition polymerizable compounds produced by using an addition reaction between an isocyanate group and a hydroxyl group are also suitable, and specific examples thereof include, for example, the vinylurethane compounds containing two or more polymerizable vinyl groups in one molecule, produced by adding a vinyl monomer containing a hydroxyl group as represented by the following Formula (B), to a polyisocyanate compound having two or more isocyanate groups in one molecule, as described in JP-B No. 48-41708, and the like.

CH₂═C(R¹)COOCH₂CH(R²)OH (B)

wherein R¹ and R² each represent H or CH₃.

The urethane acrylates such as those described in JP-A No. 51-37193, JP-B Nos. 2-32293 and 2-16765; or the urethane compounds having an ethylene oxide-based skeleton described in JP-B Nos. 58-49860, 56-17654, 62-39417 and 62-39418, are also suitable.

If the addition polymerizable compounds having an amino structure or a sulfide structure in the molecule, as described in JP-A Nos. 63-277653, 63-260909 and 1-105238, are used, rapidly curable resin compositions may be obtained.

Other examples thereof include polyfunctional acrylates or methacrylates such as the polyester acrylates and epoxy acrylates obtained by reacting an epoxy resin and (meth)acrylic acid, such as those described in JP-A No. 48-64183, JP-B Nos. 49-43191 and 52-30490; the specific unsaturated compounds described in JP-B Nos. 46-43946, 1-40337 and 1-40336; the vinylphosphonic acid-based compounds described in JP-A No. 2-25493; and the like. Under certain circumstances, the structure containing a perfluoroalkyl group described in JP-A No. 61-22048 is also suitably used. The compounds introduced in Journal of the Adhesion Society of Japan, Vol. 20, No. 7, pp. 300-308 (1984) as photocurable monomers and oligomers, may also be used.

In view of the speed of reaction, compounds having a structure having a large content of unsaturated groups per molecule are preferable, and in many cases, bifunctional or higher-functional compounds are preferred. Furthermore, in order to increase the strength of the image areas, that is, the cured film, trifunctional or higher-functional compounds are desirable, and a method of controlling both reactivity and strength by using compounds having different functionalities or different polymerizable groups (for example, acrylic acid esters, methacrylic acid esters, styrene-based compounds, and vinyl ether-based compounds) in combination, is also effective. The addition polymerizable compound is used in an amount in the range of preferably 10% by mass to 60% by mass, and more preferably 15% by mass to 40% by mass, of the resin composition of the invention.

These polymerizable compounds may be used singly, or in combination of two or more species thereof. When the polymerizable compounds are used, film properties, for example, brittleness and flexibility, may be adjusted.

Preferable specific examples of the polymerizable compound usable in the resin composition of the invention are shown below, while the invention is not limited thereby.

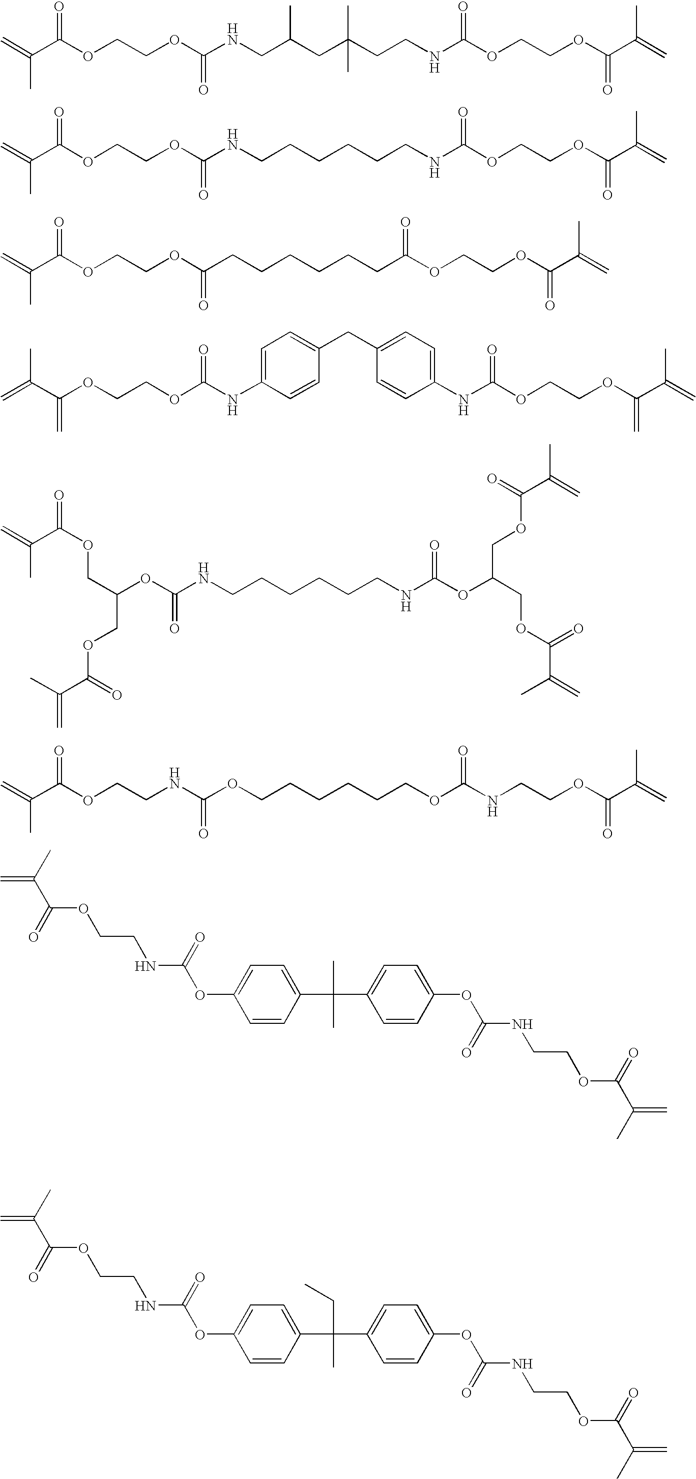

In the case of applying a resin composition for laser engraving containing the polymerizable compound to a relief forming layer of a relief printing plate precursor, compounds containing sulfur (S) atoms are particularly preferred among the polymerizable compounds, from the viewpoint that edge fusion of the relief may hardly occur and thus provide sharp (well-defined) relief can be easily obtained. That is, a compound contains a sulfur atom in a crosslinked network therein are preferable.

While a polymerizable compound which contains a sulfur atom and a polymerizable compound which does not contain a sulfur atom may also be used in combination, it is preferable to use the polymerizable compound containing a sulfur is singly used from the viewpoint that edge fusion of a relief formed from the relief forming layer containing thereof may hardly occur. A use of plural sulfur-containing polymerizable compounds having different characteristics in combination may contribute to the control of the film flexibility and the like.

Examples of the polymerizable compound containing a sulfur atom include the following compounds.

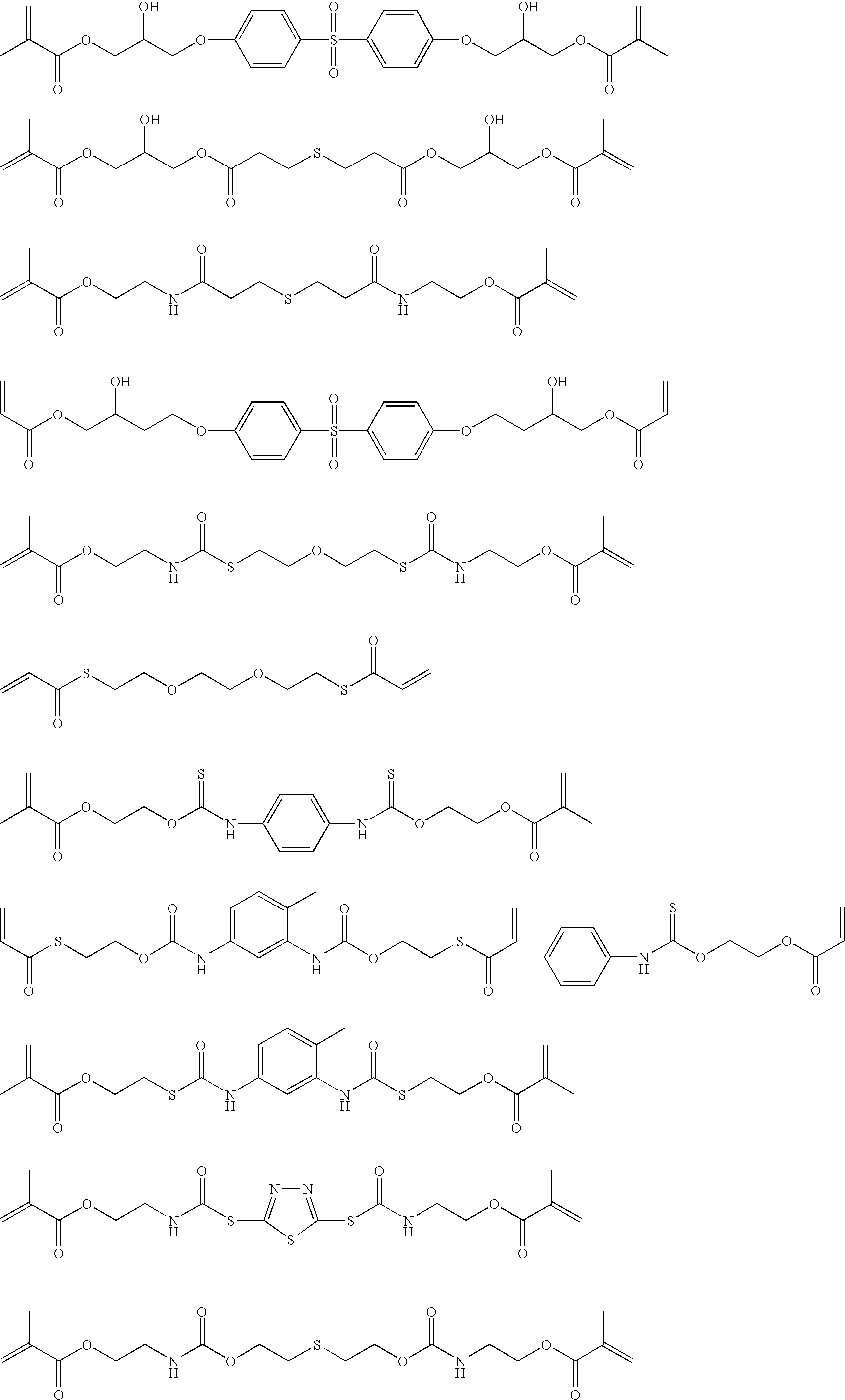

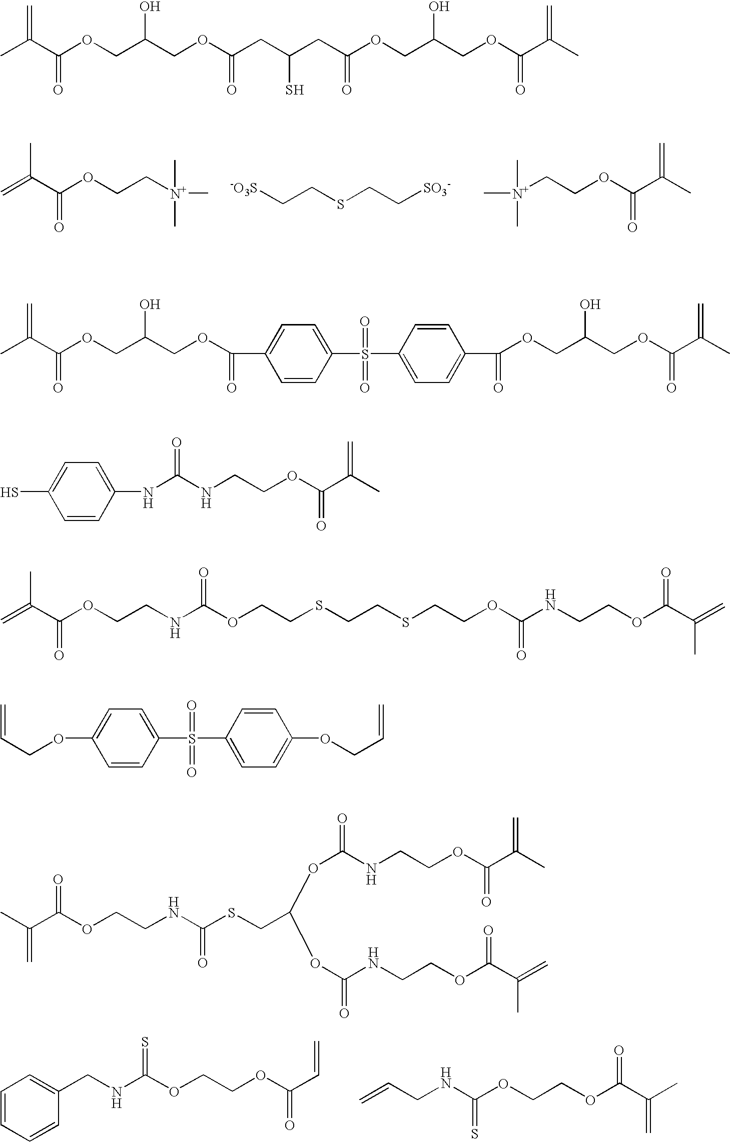

(D) Polymerization Initiator

The resin composition of the invention preferably contains a polymerization initiator.

Any polymerization initiator that is known to those having ordinary skill in the art may be used in the invention without particular limitation. Specific examples thereof are extensively described in Bruce M. Monroe, et al., Chemical Revue, 93 435 (1993) or R. S. Davidson, Journal of Photochemistry and Biology A: Chemistry, 73, 81 (1993); J. P. Faussier, “Photoinitiated Polymerization—Theory and Applications”: Rapra Review Vol. 9, Report, Rapra Technology (1998); M. Tsunooka et al., Prog. Polym. Sci., 21, 1 (1996); and the like. Also known is a family of compounds which oxidatively or reductively cause bond cleavage, such as those described in F. D. Saeva, Topics in Current Chemistry, 156, 59 (1990); G. G. Maslak, Topics in Current Chemistry, 168, 1 (1993); H. B. Shuster et al., JACS, 112, 6329 (1990); I. D. F. Eaton et al., JACS, 102, 3298 (1980); and the like.

Hereinafter, specific examples of preferable polymerization initiators will be discussed in detail, particularly with regard to a radical polymerization initiator which is a compound capable of generating a radical by the action of photo and/or thermal energy, and initiating and accelerating a polymerization reaction with a polymerizable compound, while the invention is not intended to be restricted thereby.

According to the invention, preferable examples of the radical polymerization initiator include (a) aromatic ketone, (b) onium salt compound, (c) organic peroxide, (d) thio compound, (e) hexaarylbiimidazole compound, (f) keto oxime ester compound, (g) borate compound, (h) azinium compound, (i) metallocene compound, (j) active ester compound, (k) compound having a carbon-halogen bond, (l) azo compound, and the like. Specific examples of the compounds of (a) to (l) will be shown in the followings, while the invention is not limited thereto.

(a) Aromatic Ketone

Examples of the (a) aromatic ketone which is preferable as the radical polymerization initiator usable in the invention include the compounds having a benzophenone skeleton and a thioxanthone skeleton as described in “RADIATION CURING IN POLYMER SCIENCE AND TECHNOLOGY”, J. P. Fouassier and J. F. Rabek (1993), p. 77-117. For example, the following compounds may be mentioned.

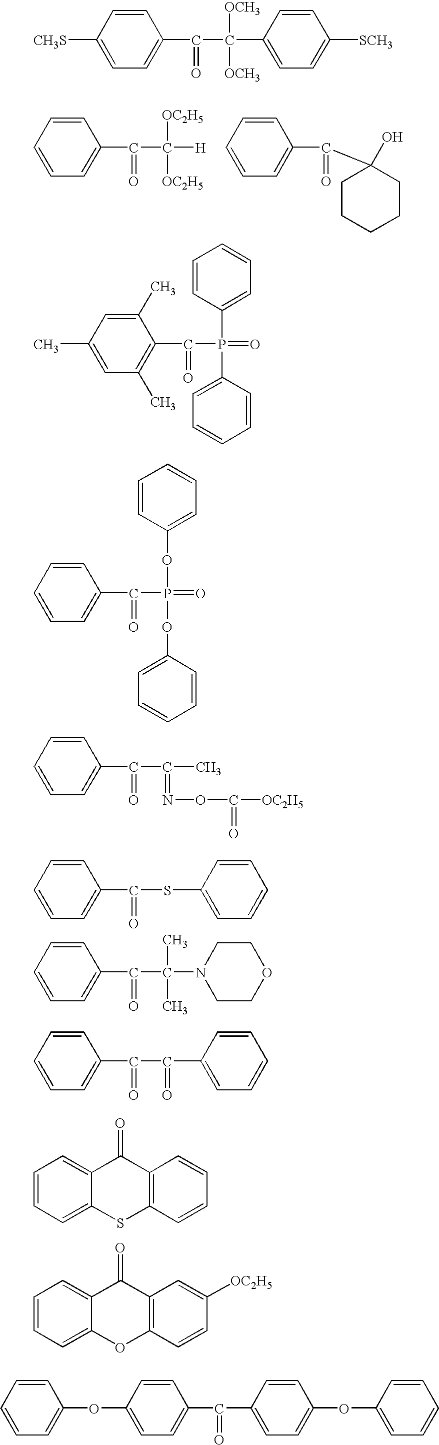

Among them, particularly preferable examples of the (a) aromatic ketone include the following compounds.

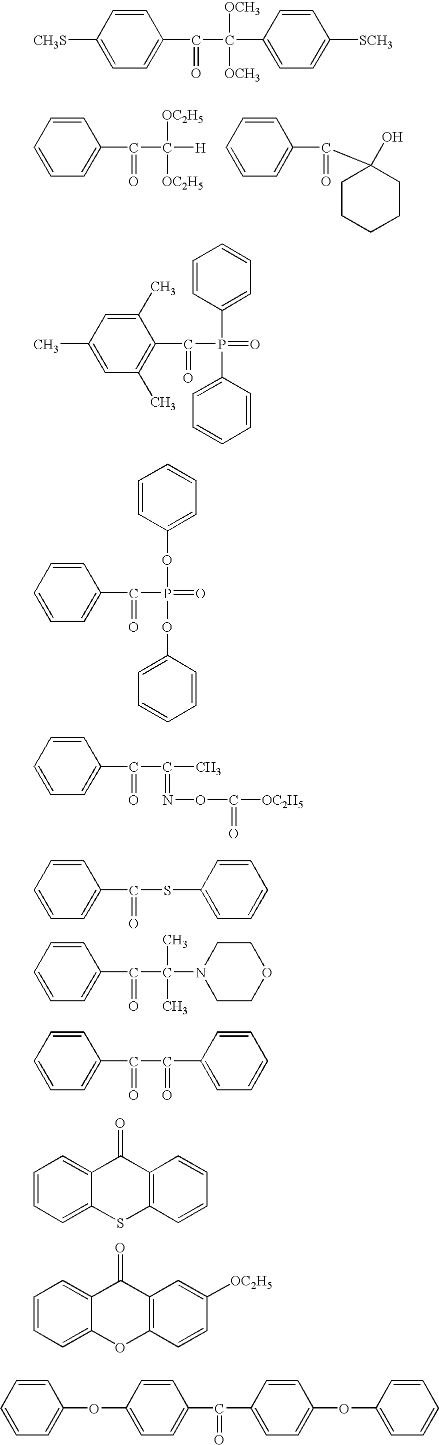

(b) Onium Salt Compound

Examples of the (b) onium salt compound which is preferable as the radical polymerization initiator usable in the invention include compounds represented by any one of the following Formulae (1) to (3).

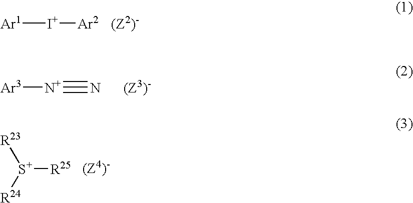

In Formula (I), Ar¹ and Ar² each independently represent an aryl group having up to 20 carbon atoms, which may be substituted; and (Z²)⁻ represents a counterion selected from the group consisting of a halogen ion, a perchlorate ion, a carboxylate ion, a tetrafluoroborate ion, a hexafluorophosphate ion and a sulfonate ion, and is preferably a perchlorate ion, a hexafluorophosphate ion or an arylsulfonate ion.

In Formula (2), Ar³ represents an aryl group having up to 20 carbon atoms, which may be substituted; and (Z³)⁻ represents a counter ion which is defined in the same manner as (Z²)⁻.

In Formula (3), R²³, R²⁴ and R²⁵, which may be the same or different from each other, each represent a hydrocarbon group having up to 20 carbon atoms, which may be substituted; and (Z⁴)³¹ represents a counter ion which is defined in the same manner as (Z²)⁻.

Specific examples of the onium salt which may be suitably used in the invention include those described in paragraphs (0030) to (0033) of JP-A No. 2001-133969 or those described in paragraphs (0015) to (0046) of JP-A No. 2001-343742, which have been previously suggested by the Applicant, and the specific aromatic sulfonium salt compounds described in JP-A Nos. 2002-148790, 2001-343742, 2002-6482, 2002-116539 and 2004-102031.

(c) Organic Peroxide

Examples of the (c) organic peroxide which is preferable as the radical polymerization initiator usable in the invention include nearly all of organic compounds having one or more oxygen-oxygen bonds in the molecule. Specific examples thereof include t-butyl peroxy benzoate, methyl ethyl ketone peroxide, cyclohexanone peroxide, 3,3,5-trimethylcyclohexanon peroxide, methylcyclohexanone peroxide, acetylacetone peroxide, 1,1-bis(tertiary-butylperoxy)-3,3,5-trimethylcyclohexane, 1,1-bis(tertiary-butylperoxy)cyclohexane, 2,2-bis(tertiary-butylperoxy)butane, tertiary-butyl hydroperoxide, cumene hydroperoxide, diisopropylbenzene hydroperoxide, paramethane hydroperoxide, 2,5-dimethylhexane-2,5-dihydroperoxide, 1,1,3,3-tetramethylbutyl hydroperoxide, di-tertiary-butyl peroxide, tertiary-butylcumyl peroxide, dicumyl peroxide, bis(tertiary-butylperoxyisopropyl)benzene, 2,5-dimethyl-2,5-di(tertiary-butylperoxy)hexane, 2,5-xanoyl peroxide, succinic acid peroxide, benzoyl peroxide, 2,4-dichlorobenzoyl peroxide, meta-toluoyl peroxide, diisopropyl peroxydicarbonate, di-2-ethylhexyl peroxydicarbonate, di-2-ethoxyethyl peroxydicarbonate, dimethoxyisopropyl peroxycarbonate, di(3-methyl-3-methoxybutyl)peroxydicarbonate, tertiary-butyl peroxyacetate, tertiary-butyl peroxypivalate, tertiary-butyl peroxyneodecanoate, tertiary-butyl peroxyoctanoate, tertiary-butyl peroxy-3,5,5-trimethylhexanoate, tertiary-butyl peroxylaurate, tertiary-carbonate, 3,3′,4,4′-tetra(t-butlperoxycarbonyl)benzophenone, 3,3′,4,4′-tetra(t-amylperoxycarbonyl)benzophenone, 3,3′4,4′-tetra(t-hexylperoxycarbonyl)benzophenone, 3,3′4,4′-tetra-(t-octylperoxycarbonyl)benzophenone, 3,3′,4,4′-tetra-(cumylperoxycarbonyl)benzophenone, 3,3′4,4′-tetra-(p-isopropylcumylperoxycarbonyl)benzophenone, carbonyl di(t-butylperoxy dihydrogen diphthalate), carbonyl di(t-hexylperoxy dihydrogen diphthalate), and t-butyl hydroperoxide.

Among them, 3,3′,4,4′-tetra(t-butylperoxycarbonyl)benzophenone, 3,3′4,4′-tetra-(t-amylperoxycarbonyl)benzophenone, 3,3′,4,4′-tetra-(t-hexylperoxycarbonyl)benzophenone, 3,3′4,4′-tetra-(t-octylperoxycarbonyl)benzophenone, t-butyl peroxy benzoate, dicumyl peroxide, t-butyl hydroperoxide, 3,3′,4,4′-tetra-(cumylperoxycarbonyl)benzophenone, 3,3′4,4′-tetra-(p-isopropylcumylperoxycarbonyl)benzophenone, and di-t-butyl diperoxyisophthalate are preferable, and t-butyl peroxy benzoate, dicumyl peroxide, and t-butyl hydroperoxide are more preferable.

The (c) organic peroxide is found as being preferable as the polymerization initiator usable in the invention in view of improving crosslinking property of the relief forming layer as well as obtaining unexpected effect of improving the engraving sensitivity.

In view of improving the engraving sensitivity, it is particularly preferable that the (c) organic peroxide is combined in combination with the specific binder polymer and the other binder polymer having a glass transition temperature not lower than normal temperature.

That is, when the resin composition is cured by thermal crosslinking with the organic peroxide, unreacted portions of the organic peroxide uninvolved with radical generation may remain. The remaining organic peroxide may serve as an autoreactive additive, which may be exothermically decomposed during laser engraving. Consequently, the generated heat can be added to the laser energy, which can result in the increase in the engraving sensitivity.

In particular, when the glass transition temperature of the specific polymer binder is not lower than the room temperature, the heat generated by the decomposition of the organic peroxide can be efficiently transferred to the specific binder polymer, and effectively used for the thermal decomposition of the specific polymer binder, which may result in the further increase in the engraving sensitivity.

These effects can be markedly achieved when carbon black is used as the photo-thermal conversion agent, details about which will be given in the explanation of the photo-thermal conversion agent. This is likely due to that heat released from carbon black is transferred to the (c) organic peroxide to cause heat generation of the organic peroxide, which results in synergistic generation of thermal energy to be used for the decomposition of the specific binder polymer and others.

(d) Thio Compound

Examples of the (d) thio compound which is preferable as the radical polymerization initiator usable in the invention include compounds having a structure represented by following Formula (4).

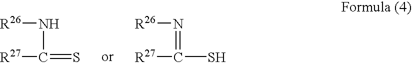

In Formula (4), R²⁶ represents an alkyl group, an aryl group or a substituted aryl group; R²⁷ represents a hydrogen atom or an alkyl group; and R²⁶ and R²⁷ may be bound to each other to represent a non-metallic atomic group necessary for forming a 5- to 7-membered ring which may contain a heteroatom selected from an oxygen atom, a sulfur atom and a nitrogen atom.

Specific examples of the thio compound represented by Formula (4) include the compounds shown below.

| No. | R²⁶ | R²⁷ |
|---|---|---|
| 1 | —H | —H |
| 2 | —H | —CH₃ |
| 3 | —CH₃ | —H |
| 4 | —CH₃ | —CH₃ |
| 5 | —C₆H₅ | —C₂H₅ |
| 6 | —C₆H₅ | —C₄H₉ |
| 7 | —C₆H₄Cl | —CH₃ |
| 8 | —C₆H₄Cl | —C₄H₉ |
| 9 | —C₆H₄—CH₃ | —C₄H₉ |
| 10 | —C₆H₄—OCH₃ | —CH₃ |
| 11 | —C₆H₄—OCH₃ | —C₂H₅ |
| 12 | —C₆H₄—OC₂H₆ | —CH₃ |
| 13 | —C₆H₄—OC₂H₅ | —C₂H₅ |
| 14 | —C₆H₄—OCH₃ | —C₄H₉ |

| | |
|---|---|
| 15 | —(CH₂)₂— |
| 16 | —(CH₂)₂—S— |
| 17 | —CH(CH₃)—CH₂—S— |
| 18 | —CH₂—CH(CH₃)—S— |
| 19 | —C(CH₃)₂—CH₂—S— |
| 20 | —CH₂—C(CH₃)₂—S— |
| 21 | —(CH₂)₂—O— |
| 22 | —CH(CH₃)—CH₂—O— |
| 23 | —C(CH₃)₂—CH₂—O— |
| 24 | —CH═CH—N(CH₃)— |
| 25 | —(CH₂)₃—S— |
| 26 | —(CH₂)₂—CH(CH₃)—S— |
| 27 | —(CH₂)₃—O— |
| 28 | —(CH₂)₅— |
| 29 | —C₆H₄—O— |
| 30 | —N═C(SCH₃)—S— |
| 31 | —C₆H₄—NH— |
| 32 | 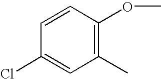 |

(e) Hexaarylbiimidazole Compound

Examples of the (e) Hexaarylbiimidazole compound which is preferable as the radical polymerization initiator usable in the invention include the rofin dimers described in JP-B Nos. 45-37377 and 44-86516. Specific examples thereof include 2,2′-bis(o-chlorophenyl)-4,4′,5,5′-tetraphenylbiimidazole, 2,2′-bis(o-bromophenyl)-4,4′,5,5′-tetraphenylbiimidazole, 2,2′-bis(o,p-dichlorophenyl)-4,4′,5,5′-tetraphenylbiimidazole, 2,2′-bis(o-chlorophenyl)-4,4′,5,5′-tetra(m-methoxyphenyl)biimidazole, 2,2′-bis(o,o′-dichlorophenyl)-4,4′,5,5′-tetraphenylbiimidazole, 2,2′-bis(o-nitrophenyl)-4,4′,5,5′-tetraphenylbiimidazole, 2,2′-bis(o-methylphenyl)-4,4′,5,5′-tetraphenylbiimidazole, 2,2′-bis(o-triflourophenyl)-4,4′,5,5′-tetraphenylbiimidazole, and the like.

(f) Keto Oxime Ester Compounds

Examples of the (f) keto oxime ester compound which is preferable as the radical polymerization initiator in the invention include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-p-toluenesulfonyloxyiminobutan-2-one, 2-ethoxycarbonyloxyimino-1-phenylpropan-1-one, and the like.

(g) Borate Compounds

Examples of the (g) Borate compounds which is preferable as the radical polymerization initiator usable in the invention include compounds represented by following Formula (5).

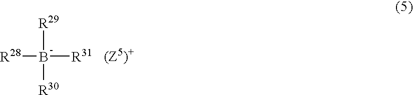

In Formula (5), R²⁸, R²⁹, R³⁰ and R³¹, which may be the same or different from each other, each represent a substituted or unsubstituted alkyl group, a substituted or unsubstituted aryl group, a substituted or unsubstituted alkenyl group, a substituted or unsubstituted alkynyl group, or a substituted or unsubstituted heterocyclic group, and two or more groups among R²⁸, R²⁹, R³⁰ and R³¹ may be bound with each other to form a cyclic structure, with the proviso that at least one among R²⁸, R²⁹, R³⁰ and R³¹ is a substituted or unsubstituted alkyl group; and (Z⁵)⁺ represents an alkali metal cation or a quaternary ammonium cation.

Specific examples of the compound represented by Formula (5) include the compounds described in U.S. Pat. Nos. 3,567,453 and 4,343,891, and European Patent Nos. 109,772 and 109,773, and the compounds shown below.

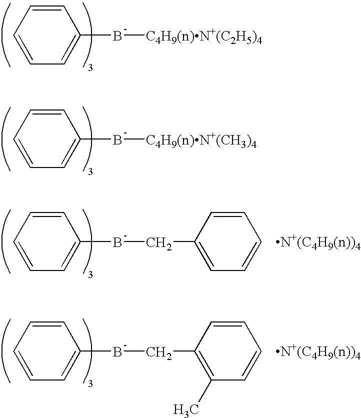

(h) Azinium Compounds

Examples of the (h) azinium salt compound which is preferable as the radical polymerization initiator usable in the invention include the compounds having an N—O bond as described in JP-A Nos. 63-138345, 63-142345, 63-142346 and 63-143537, and JP-B No. 46-42363.

(i) Metallocene Compounds

Examples of the (i) Metallocene compounds which is preferable as the radical polymerization initiator usable in the invention include the titanocene compounds described in JP-A Nos. 59-152396, 61-151197, 63-41484, 2-249 and 2-4705, and the iron arene complexes described in JP-A Nos. 1-304453 and 1-152109.

Specific examples of the titanocene compounds include dicyclopentadienyl-Ti-dichloride, dicyclopentadienyl-Ti-bisphenyl, dicyclopentadienyl-Ti-bis-2,3,4,5,6-pentafluorophen-1-yl, dicyclopentadienyl-Ti-bis-2,3,5,6-tetrafluorophen-1-yl, dicyclopentadienyl-Ti-bis-2,4,6-trifluorophen-1-yl, dicyclopentadienyl-Ti-2,6-difluorophen-1-yl, dicyclopentadienyl-Ti-bis-2,4-difluorophen-1-yl, dimethylcyclopentadienyl-Ti-bis-2,3,4,5,6-pentafluorophen-1-yl, dimethylcyclopentadienyl-Ti-bis-2,3,5,6-tetrafluorophen-1-yl, dimethylcyclopentadienyl-Ti-bis-2,4-difluorophen-1-yl, bis(cyclopentadienyl)-bis(2,6-difluoro-3-(pyrr-1-yl)phenyltitaniumbis(cyclopentadienyl) bis[2,6-difluoro-3-(methylsulfonamido)phenyl]titanium, bis(cyclopentadienyl)bis[2,6-difluoro-3-(N-butylbiaroylamino)phenyl]titanium, bis(cyclopentadienyl)bis[2,6-difluoro-3-(N-butyl-(4-chloropbenzoyl)amino)phenyl]titanium, bis(cyclopentadienyl)bis[2,6-difluoro-3-(N-benzyl-2,2-dimehylpentanoylamino)phenyl]titanium,

bis(cyclopentadienyl)bis[2,6-difluoro-3-(N-(2-ethylhexyl-4-tolylsulfonyl)amino)phenyl]titanium, bis(cyclopentadienyl)bis[2,6-difluoro-3-(N-(3-oxaheptyl)benzoylamino)phenyl]titanium, bis(cyclopentadienyl)bis[2,6-difluoro-3-(N-(3,6-dioxadecyl)benzoylamino)phenyl]titanium, bis(cyclopentadienyl)bis[2,6-difluoro-3-(trifluoromethylsulfonylamino)phenyl]titanium, bis(cyclopentadienyl)bis[2,6-difluoro-3-(trifluoroacetylamino)phenyl]titanium, bis(cyclopentadienyl)bis[2,6-difluoro-3-(2-chlorobenzoylamino)phenyl]titanium, bis(cyclopentadienyl)bis[2,6-difluoro-3-(4-chlorobenzoylamino)phenyl]titanium, bis(cyclopentadienyl)bis[2,6-difluoro-3-(N-(3,6-dioxadecyl)-2,2-dimethylpentanoylamino)phenyl]titanium, bis(cyclopentadienyl)bis[2,6-difluoro-3-(N-(3,7-dimethyl-7-methoxyoctyl)benzoylamino)phenyl]titanium, bis(cyclopentadienyl)bis[2,6-difluoro-3-(N-cyclohexylbenzoylamino)phenyl]titanium, and the like.

(j) Active Ester Compounds

Examples of the (j) active ester compound which is preferable as the radical polymerization initiator usable in the invention include the imidosulfonate compounds described in JP-A No. 62-6223, and the active sulfonates described in JP-B No. 63-14340 and JP-A No. 59-174831.

(k) Compounds Having Carbon-Halogen Bond

Examples of the (k) compound having a carbon-halogen bond which is preferable as the radical polymerization initiator usable in the invention include compounds represented by any one of the following Formulae (6) to (12).

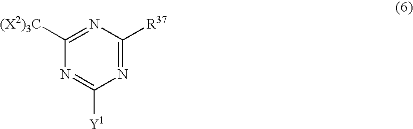

In Formula (6), X² represents a halogen atom; Y¹ represents —C(X²)₃, —NH₂, —NHR³⁸, —NR³⁸, or —OR³⁸ ; R³⁸ represents an alkyl group, a substituted alkyl group, an aryl group or a substituted aryl group; and R³⁷ represents —C(X²)₃, an alkyl group, a substituted alkyl group, an aryl group, a substituted aryl group, or a substituted alkenyl group.

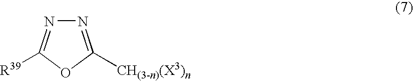

In Formula (7), R³⁹ represents an alkyl group, a substituted alkyl group, an alkenyl group, a substituted alkenyl group, an aryl group, a substituted aryl group, a halogen atom, an alkoxy group, a substituted alkoxy group, a nitro group, or a cyano group; X³ represents a halogen atom; and n represents an integer from 1 to 3.

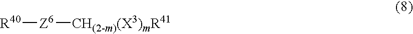

In Formula (8), R⁴⁰ represents an aryl group or a substituted aryl group; R⁴¹ represents any one of the groups shown below, or a halogen atom; Z⁶ represents —C(═O)—, —C(═S)— or —SO₂—; X³ represents a halogen atom; and m represents 1 or 2.

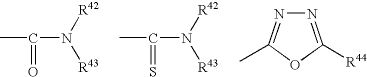

wherein R⁴² and R⁴³ are each an alkyl group, a substituted alkyl group, an alkenyl group, a substituted alkenyl group, an aryl group or a substituted aryl group; and R⁴⁴ has the same meaning as defined for R³⁸ in Formula (6).

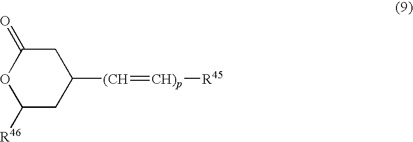

In Formula (9), R⁴⁵ represents an aryl group or a heterocyclic group, each of which may be substituted; R⁴⁶ represents a trihaloalkyl group or a trihaloalkenyl group, each having 1 to 3 carbon atoms; and p represents 1, 2 or 3.

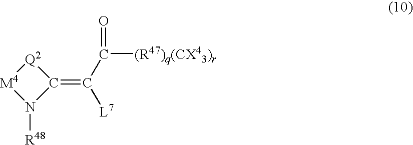

Formula (10) represents a carbonylmethylene heterocyclic compound having a trihalogenomethyl group. In Formula (10), L⁷ represents a hydrogen atom or a substituent of formula: CO—(R⁴⁷)_{q}(C(X⁴)₃)ᵣ; Q² represents a sulfur atom, a selenium atom, an oxygen atom, a dialkylmethylene group, an alken-1,2-ylene group, a 1,2-phenylene group, or an N—R group, in which R represents an alkyl group having 1 to 6 carbon atoms; M⁴ represents a substituted or unsubstituted alkylene or alkenylene group, or represents a 1,2-arylene group; R³⁸ represents an alkyl group, an aralkyl group or an alkoxyalkyl group; R⁴⁷ represents a carbocyclic or heterocyclic divalent aromatic group; X⁴ represents a chlorine atom, a bromine atom or an iodine atom; and either q=0 and r=1, or q=1 and r=1 or 2.

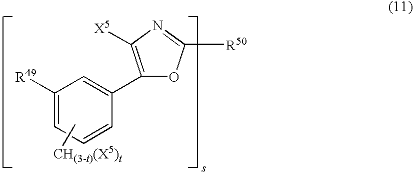

Formula (11) represents a 4-halogeno-5-(halogenomethylphenyl)oxazole compound. In Formula (11), X⁵ represents a halogen atom; t represents an integer from 1 to 3; s represents an integer from 1 to 4; R⁴⁹ represents a hydrogen atom or a CH₃₋ₜX⁵ₜ group; R⁵⁰ represents an unsaturated organic group which has a valency of s and may be substituted.

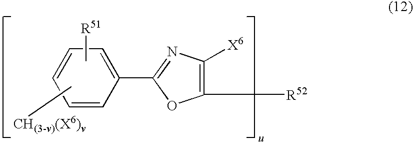

Formula (12) represents a 2-(halogenomethylphenyl)-4-halogeno-oxazole derivative. In Formula (12), X⁶ represents a halogen atom; v represents an integer from 1 to 3; u represents an integer from 1 to 4; R⁵¹ represents a hydrogen atom or a CH₃₋ᵥX⁶ᵥ group; and R⁵² represents an unsaturated organic group which has a valency of u and may be substituted.

Specific examples of the compounds having a carbon-halogen bond include the compounds described in Wakabayashi, et al., Bull. Chem. Soc. Japan, 42, 2924 (1969), for example, 2-phenyl-4,6-bis(trichlormethyl)-S-triazine, 2-(p-chlorphenyl)-4,6-bis(trichlormethyl)-S-triazine, 2-(p-tolyl)-4,6-bis(trichlormethyl)-3-triazine, 2-(p-methoxyphenyl)-4,6-bis(trichlormethyl)-S-triazine, 2-(2′,4′-dichlorphenyl)-4,6-bis(trichlormethyl)-S-triazine, 2,4,6-tris(trichlormethyl)-S-triazine, 2-methyl-4,6-bis(trichlormethyl)-S-triazine, 2-n-nonyl-4,6-bis(trichlormethyl)-S-triazine, 2-(α,α,β-trichlorethyl)-4,6-bis(trichlormethyl)-S-triazine, and the like. In addition, the compounds described in U.K. Patent No. 1388492, for example, 2-styryl-4,6-bis(trichlormethyl)-S-triazine, 2-(p-methylstyryl)-4,6-bis(trichlormethyl)-S-triazine, 2-(p-methoxystyryl)-4,6-bis(trichlormethyl)-S-triazine, 2-(p-methoxystyryl)-4-amino-6-trichlormethyl-S-triazine, and the like; the compounds described in JP-A No. 53-133428, for example, 2-(4-methoxy-naphth-1-yl)-4,6-bis-trichlormethyl-S-triazine, 2-(4-ethoxy-naphth-1-yl)-4,6-bis-trichlormethyl-S-triazine, 2-[4-(2-ethoxyethyl)-naphth-1-yl]-4,6-bis-trichlormethyl-S-triazine, 2-(4,7-dimethoxy-naphth-1-yl)-4,6-bis-trichlormethyl-S-triazine, 2-(acenaphth-5-yl)-4,6-bis-trichlormethyl-S-triazine, and the like; the compounds described in German Patent No. 3337024, for example, the compounds shown below; and the like may also be mentioned. Furthermore, there may be mentioned a family of compounds as shown below, which can be easily synthesized by a person having ordinary skill in the art according to the synthesis method described in M. P. Hutt, E. F. Elslager and L. M. Herbel, “Journal of Heterocyclic Chemistry”, Vol. 7, No. 3, p. 511- (1970), for example, the following compounds.

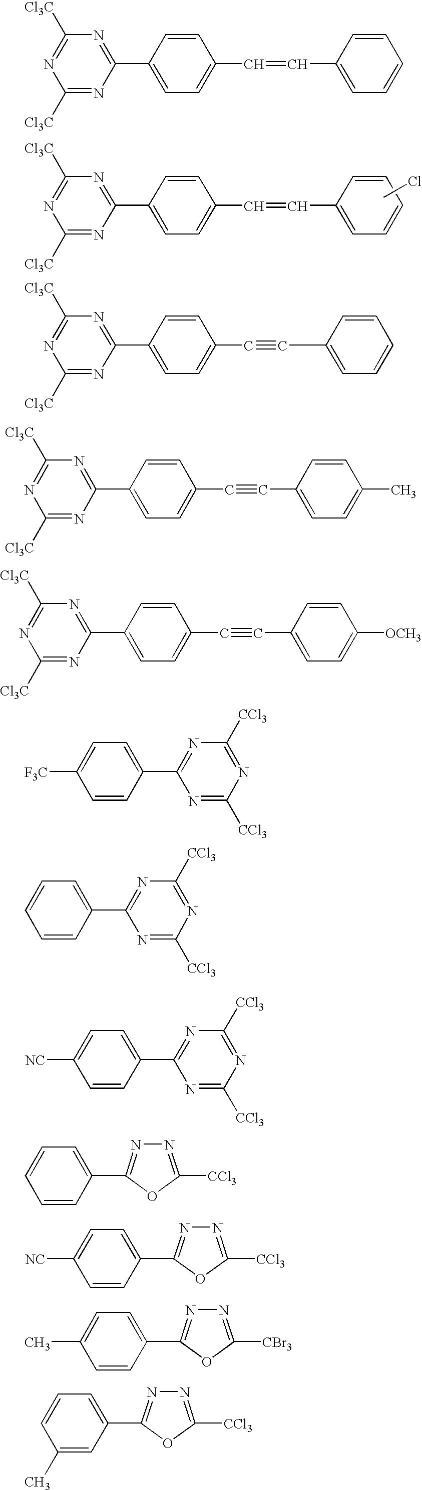

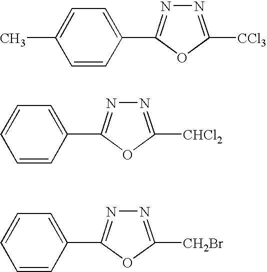

(l) Azo Compound

Examples of the (l) azo compound which is preferable as the radical polymerization initiator usable in the invention include 2,2′-azobisisobutyronitrile, 2,2′-azobispropionitrile, 1,1′-azobis(cyclohexane-1-carbonitrile), 2,2′-azobis(2-methylbutyronitrile), 2,2′-azobis(2,4-dimethylvaleronitrile), 2,2′-azobis(4-methoxy-2,4-dimethylvaleronitrile), 4,4′-azobis(4-cyanovaleric acid), dimethyl 2,2′-azobisisobutyrate, 2,2′-azobis(2-methylpropionamideoxime), 2,2′-azobis[2-(2-imidazolin-2-yl)propane], 2,2′-azobis{2-methyl-N-[1,1-bis(hydroxymethyl)-2-hydroxyethyl]propionamide}, 2,2′-azobis[2-methyl-N-(2-hydroxyethyl)propionamide], 2,2′-azobis(N-butyl-2-methylpropionamide), 2,2′-azobis(N-cyclohexyl-2-methylpropionamide), 2,2′-azobis[N-(2-propenyl)-2-methylpropionamide], 2,2′-azobis(2,4,4-trimethylpentane), and the like.

More preferable examples of the radical polymerization initiator for the invention include the (a) aromatic ketone, (b) onium salt compound, (c) organic peroxide, (e) hexaarylbiimidazole compound, (i) metallocene compound, and (k) compound having a carbon-halogen bond, and most preferable examples thereof include an aromatic iodonium salt, an aromatic sulfonium salt, a titanocene compound, and a trihalomethyl-S-triazine compound represented by Formula (6).

The amount of the (D) polymerization initiator used in the invention may be preferably 0.01% by mass to 10% by mass, and more preferably 0.1% by mass to 3% by mass, relative to the total solid content of the resin composition containing the (C) polymerizable compound.

The polymerization initiators are suitably used by using them individually alone, or in combination of two or more species.

The resin composition of the invention preferably contains, together with the (A) complex formed between a layered inorganic compound and a cationic organic compound, the (B) binder polymer insoluble in water and soluble in an alcohol having 1 to 4 carbon atoms, the (C) polymerizable compound, and the (D) polymerizable initiator, which are described as the essential ingredients above, arbitrary ingredients such as a (E) photothermal conversion agent, or a (F) a plasticizer. Each of the ingredients is more specifically explained below.

(E) Photothermal Conversion Agent

The resin composition of the invention preferably contains a photothermal conversion agent which is capable of absorbing a light having a wavelength of 700 nm to 1300 nm.

When the resin composition contains such a photothermal conversion agent, in the case of performing laser engraving on the resin composition of the invention using, for example, a laser emitting an infrared light having a wavelength of 700 nm to 1300 nm (a YAG laser, a semiconductor laser, a fiber laser, a surface emitting laser, or the like) as the light source, the engraving sensitivity of the process may be increased. That is, such a photothermal conversion agent absorbs laser light to generate heat, and enhances thermal decomposition of the resin composition.

The photothermal conversion agent according to the invention is a compound having the maximum absorption wavelength in the wavelength region of 700 nm to 1300 nm. Particularly, the photothermal conversion agent is preferably a dye or a pigment having the maximum absorption at a wavelength ranging from 700 nm to 1300 nm.

Commercially available dyes and known dyes that are described in literatures such as “Handbook of Dyes” (edited by the Society of Synthetic Organic Chemistry, Japan, 1970), may be used as for the dye. Specific examples thereof include azo dyes, metal complex azo dyes, pyrazolone azo dyes, naphthoquinone dyes, anthraquinone dyes, phthalocyanine dyes, carbonium dyes, diimmonium compounds, quinonimine dyes, methine dyes, cyanine dyes, squarylium colorants, pyrylium salts, and metal thiolate complexes.

Preferable examples of the dye include the cyanine dyes described in JP-A Nos. 58-125246, 59-84356, 59-202829, 60-78787 and the like; the methine dyes described in JP-A Nos. 58-173696, 58-181690, 58-194595, and the like; the naphthoquinone dyes described in JP-A Nos. 58-112793, 58-224793, 59-48187, 59-73996, 60-52940, 60-63744 and the like; the squarylium colorants described in JP-A No. 58-112792 and the like; the cyanine dyes described in U.K. Patent No. 434,875; and the like.

Preferable examples of the dye further include the near-infrared absorption sensitizers described in U.S. Pat. No. 5,156,938, the substituted arylbenzo(thio)pyrylium salts described in U.S. Pat. No. 3,881,924; the trimethinethiapyrylium salts described in JP-A No. 57-142645 (U.S. Pat. No. 4,327,169); the pyrylium-compounds described in JP-A Nos. 58-181051, 58-220143, 59-41363, 59-84248, 59-84249, 59-146063 and 59-146061; the cyanine dyes described in JP-A No. 59-216146; the pentamethinethiopyrylium salts and the like described in U.S. Pat. No. 4,283,475; and the pyrylium compounds described in JP-B Nos. 5-13514 and 5-19702. Preferable examples of the dye furthermore include the near-infrared absorption dyes represented by formulae (I) and (II) in U.S. Pat. No. 4,756,993.

Preferable examples of the photo-thermal conversion agent of the invention include the specific indolenine cyanine colorants described in JP-A No. 2002-278057.

Particularly preferable examples among these dyes include cyanine colorants, squarylium colorants, pyrylium salts, nickel thiolate complexes, and indolenine cyanine colorants. Cyanine colorants or indolenine cyanine colorants are even more preferable.

Specific examples of the cyanine colorants which may be suitably used in the invention include those described in paragraphs 0017 to 0019 of JP-A No. 2001-133969, paragraphs 0012 to 0038 of JP-A No. 2002-40638, and paragraphs 0012 to 0134 of JP-A No. 2002-23360.

The colorants represented by following Formula (d) or Formula (e) are preferable from the viewpoint of photo-thermal conversion property.

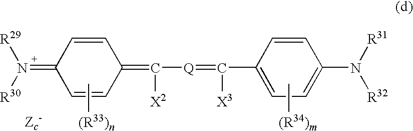

In Formula (d), R²⁹ to R³¹ each independently represent a hydrogen atom, an alkyl group or an aryl group; R³³ and R³⁴ each independently represent an alkyl group, a substituted oxy group, or a halogen atom; n and m each independently represent an integer from 0 to 4; R²⁹ and R³⁰, or R³¹ and R³² may be respectively be bound to each other to form a ring, and R²⁹ and/or R³⁰ may be bound to R³³, and R³¹ and/or R³² may be bound to R³⁴, to respectively form a ring; if a plurality of R³³ are present, the R³³s may be bound to each other to form a ring; if a plurality of R³⁴ are present, the R³⁴s may be bound to each other to form a ring; X² and X³ each independently represent a hydrogen atom, an alkyl group or an aryl group, and at least one of X² and X³ represents a hydrogen atom or an alkyl group; Q represents a trimethine group or pentamethine group which may be substituted, and may form a cyclic structure together with a divalent organic group; and Zc⁻ represents a counter-anion. However, if the colorant represented by Formula (d) has an anionic substituent in the structure and does not require charge neutralization, Zc⁻ is not necessary. Preferably, Zc⁻ is a halogen ion, a perchloric acid ion, a tetrafluoroborate ion, a hexafluorophosphate ion or a sulfonic acid ion, from the viewpoint of the storage stability of the photosensitive layer coating solution, and particularly preferably, Zc⁻ is a perchloric acid ion, a hexafluorophosphate ion or an arylsulfonic acid ion.

Specific examples of the dyes represented by Formula (d), which may be suitably used in the invention, include those shown below.

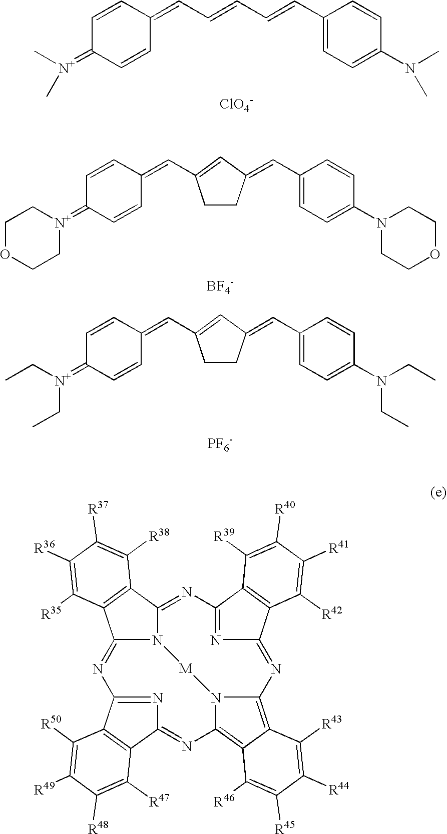

In Formula (e), R³⁵ to R⁵⁰ each independently represent a hydrogen atom, a halogen atom, a cyano group, an alkyl group, an aryl group, an alkenyl group, an alkynyl group, a hydroxyl group, a carbonyl group, a thio group, a sulfonyl group, a sulfinyl group, an oxy group, an amino group, or an onium salt structure, and if it is possible to introduce substituents to these groups, the groups may be substituted; M represents two hydrogen atoms or metal atoms, a halo-metal group, or an oxy-metal group, and as the metal atoms included therein, there may be mentioned the atoms of Groups IA, IIA, IIIB and IVB of the Period Table of Elements, the first-row, second-row and third-row transition metals, and lanthanoid elements. Among them, copper, magnesium, iron, zinc, cobalt, aluminum, titanium and vanadium are preferable.

Specific examples of the dyes represented by Formula (e), which may be suitably used in the invention, include those shown below.

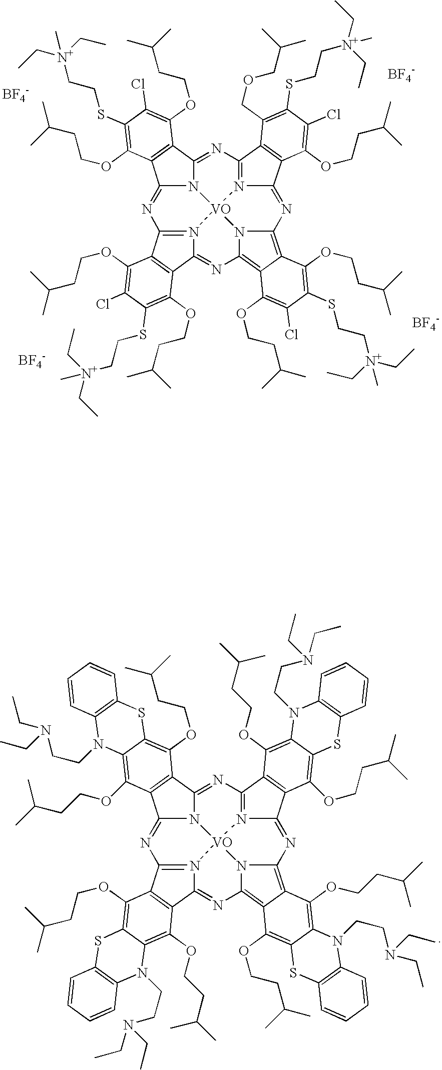

Examples of the pigment which may be used in the invention include commercially available pigments, and the pigments described in the Color Index (C.I.) Handbook, “Handbook of New Pigments” (edited by Japan Association of Pigment Technology, 1977), “New Pigment Application Technology” (published by CMC, Inc., 1986), and “Printing Ink Technology” (published by CMC, 1984).

Examples of the pigments include black pigments, yellow pigments, orange pigments, brown pigments, red pigments, magenta pigments, blue pigments, green pigments, fluorescent pigments, metal powder pigments, and other polymer-bound pigments. Specifically, insoluble azo pigments, azo lake pigments, condensed azo pigments, chelate azo pigments, phthalocyanine pigments, anthraquinone pigments, perylene- and perinone pigments, thio indigo pigments, quinacridone pigments, dioxazine pigments, isoindolinone pigments, quinophthalone pigments, dyed lake pigments, azine pigments, nitroso pigments, nitro pigments, natural pigments, fluorescent pigments, inorganic pigments, carbon black, and the like may be used. Among these pigments, carbon black is preferable.

These pigments may be used without being subjected to a surface treatment, or may be used after being subjected to a surface treatment. Examples of a method of the surface treatment include a method of coating the pigment surface with resin or wax, a method of adhering surfactants to the pigment surface, a method of binding a reactive substance (for example, a silane coupling agent, an epoxy compound, polyisocyanate, or the like) to the pigment surface, and the like. These surface treatment methods are described in “Properties and Applications of Metal Soaps” (published by Saiwai Shobo Co., Ltd.), “Printing Ink Technology” (published by CMC, Inc., 1984), and “New Pigment Application Technology” (published by CMC, Inc., 1986).

The particle size of the pigment is preferably in the range of 0.01 μm to 10 μm, more preferably in the range of 0.05 μm to 1 μm, and particularly preferably in the range of 0.1 μm to 1 μm. When the particle size of the pigment is 0.01 μm or larger, the dispersion stability of the pigment in the coating solution can be increased. Also, when the particle size is 10 μm or less, the uniformity of the layer formed from the resin composition can be improved.

Any known dispersing technologies that are used in the production of ink or in the production of toner may be used as the method for dispersing the pigment. Examples of the dispersing instrument used in the dispersing include an ultrasonic dispersing machine, a sand mill, an attritor, a pearl mill, a super mill, a ball mill, an impeller, a disperser, a KD mill, a colloid mill, Dynatron, a triple-roll mill, a pressurized kneader, and the like. Details are described in “New Pigment Application Technology” (published by CMC, Inc., 1986).

In embodiments, the photo-thermal conversion agent used in the invention can be at least one selected from cyanine compounds and phthalocyanine compounds, which are preferable from the viewpoint of high engraving sensitivity. The engraving sensitivity tends to be further increased and is thus preferable when at least one of these photo-thermal conversion agents are used in a combination under a condition that the thermal decomposition temperature of the photo-thermal conversion agent is equal to or higher than the thermal decomposition temperature of a hydrophilic polymer which is suitable as the binder polymer.

Specific examples of the photo-thermal conversion agent that may be used in the invention include a colorant which have a maximum absorption wavelength in the range of 700 nm to 1,300 nm and is selected from cyanine colorants such as heptamethine cyanine colorants, oxonol colorants such as pentamethine oxonol colorants, indolium colorants, benzindolium colorants, benzothiazolium colorants, quinolinium colorants, phthalide compounds reacted with a color developing agent, and the like. Photo-absorption properties of colorants greatly vary depending on the type and the intramolecular position of the substituent, the number of conjugate bonds, the type of counterion, the surrounding environment around the colorant molecule, or the like.

Commercially available laser colorants, hypersaturated absorption colorants, and near-infrared absorption colorants may also be used. Examples of the laser colorants include “ADS740PP”, “ADS745HT”, “ADS760MP”, “ADS740WS”, “ADS765WS”, “ADS745HO”, “ADS790NH” and “ADS800NH” (all trade names, manufactured by American Dye Source, Inc. (Canada)); and “NK-3555”, “NK-3509” and “NK-3519” (all trade names, manufactured by Hayashibara Biochemical Labs, Inc.). Examples of the near-infrared absorption colorants include “ADS775MI”, “ADS775MP”, “ADS775H”, “ADS775PI”, “ADS775PP”, “ADS780MT”, “ADS780BP”, “ADS793EI”, “ADS798MI”, “ADS798MP”, “ADS800AT”, “ADS805PI”, “ADS805PP”, “ADS805PA”, “ADS805PF”, “ADS812MI”, “ADS815EI”, “ADS818HI”, “ADS818HT”, “ADS822MT”, “ADS830AT”, “ADS838MT”, “ADS840MT”, “ADS845BI”, “ADS905AM”, “ADS956BI”, “ADS1040T”, “ADS1040P”, “ADS1045P”, “ADS1050P”, “ADS1060A”, “ADS1065A”, “ADS1065P”, “ADS 1100T”, “ADS1120F”, “ADS1120P”, “ADS780WS”, “ADS785WS”, “ADS790WS”, “ADS805WS”, “ADS820WS”, “ADS830WS”, “ADS850WS”, “ADS780H”, “ADS810CO”, “ADS820HO”, “ADS821NH”, “ADS840NH”, “ADS880MC”, “ADS890MC” and “ADS920MC” (all trade names, manufactured by American Dye Source, Inc. (Canada)); “YKR-2200”, “YKR-2081”, “YKR-2900”, “YKR-2100” and “YKR-3071” (all trade names, manufactured by Yamamoto Chemical Industry Co., Ltd.); “SDO-1000B” (trade name, manufactured by Arimoto Chemical Co., Ltd.); and “NK-3508” and “NKX-114” (both trade names, manufactured by Hayashibara Biochemical Labs, Inc.), while the examples are not intended to be limited to these.

Those described in Japanese Patent No. 3271226 may be used as the phthalide compound reacted with a color developing agent. Phosphoric acid ester metal compounds, for example, the complexes of a phosphoric acid ester and a copper salt described in JP-A No. 6-345820 and WO 99/10354, may also be used as the photo-thermal conversion agent. Further, ultramicroparticles having light absorption characteristics in the near-infrared region, and having a number average particle size of preferably 0.3 μm or less, more preferably 0.1 μm or less, and even more preferably 0.08 μm or less, may also be used as the photo-thermal conversion agent. Examples thereof include metal oxides such as yttrium oxide, tin oxide and/or indium oxide, copper oxide or iron oxide, and metals such as gold, silver, palladium or platinum. Also, compounds obtained by adding metal ions such as the ions of copper; tin, indium, yttrium, chromium, cobalt, titanium, nickel, vanadium and rare earth elements, into microparticles made of glass or the like, which have a number average particle size of 5μm or less, and more preferably 1 μm or less, may also be used as the photo-thermal conversion agent. In the case that the colorant may react with a component contained in the resin composition of the invention and causes a change in its maximum absorption wavelength of light absorption, the colorant may be encapsulated in microcapsules. In that case, the number average particle size of the capsules is preferably 10 μm or less, more preferably 5 μm or less, and even more preferably 1 mm or less. Compounds obtained by adsorbing metal ions of copper, tin, indium, yttrium, rare earth elements or the like on ion-exchanged microparticles, may also be used as the photo-thermal conversion agent. The ion-exchanged microparticles may be any of organic resin microparticles or inorganic microparticles. Examples of the inorganic microparticles include amorphous zirconium phosphate, amorphous zirconium phosphosilicate, amorphous zirconium hexametaphosphate, lamellar zirconium phosphate, reticulated zirconium phosphate, zirconium tungstate, zeolites and the like. Examples of the organic resin microparticles include generally used ion-exchange resins, ion-exchange celluloses, and the like.

The most suitable embodiment of the photothermal conversion agent used in the invention is carbon black, from the viewpoint of providing high engraving sensitivity. Since carbon black has high heat resistance as compared with organic dyes or organic pigments, carbon black is less susceptible to self-decomposition caused by the heat generated by photothermal conversion thereof during laser irradiation, and since carbon black can stably emit heat during laser irradiation, carbon black is presumed to be advantageous in enhancing the crosslinking efficiency of the thermal crosslinking process. Further, organic dyes and organic pigments have low heat resistance, due to the properties of organic compounds, and undergo self-decomposition caused by the heat generated by photothermal conversion thereof during laser irradiation, and are thus inferior to carbon black in terms of stable heat emission during laser irradiation.

For the above reasons, it is thought that when carbon black is used, the sensitivity becomes particularly high.

Any kind of carbon black may be used as long as the carbon black has stable dispersibility or the like in the resin composition. The carbon black may be a product ° classified according to the American Society for Testing and Materials (ASTM) standard or may be those usually used in various applications such as coloring, rubber making, or batteries. Examples of the carbon black include furnace black, thermal black, channel black, lamp black, acetylene black, and the like. In addition, black-colored colorants such as carbon black may be used in the form of color chips or color pastes, in which the colorants have been dispersed in advance in nitrocellulose, a binder or the like, using a dispersant as necessary, in order to facilitate dispersion thereof. Such chips or pastes can be easily obtained as commercially available products.

When carbon black is used, photo-crosslinking utilizing UV light or the like is not suitable, and thermal crosslinking is preferable in terms of the curability of the film formed by the resin composition. Further, from the viewpoint of achieving remarkably high engraving sensitivity, it is more preferable that carbon black is used in combination with the organic peroxide which is the (D) polymerization initiator described as the arbitrary ingredient above.

When the resin composition is subjected to thermal crosslinking with the organic peroxide used as the polymerization initiator, unreacted portions of the organic peroxide remain in the film. The remaining portions of the organic peroxide serve as an autoreactive additive, and are exothermically decomposed during laser engraving. Consequently, the heat generated therefrom can be added to the laser energy, which results in the increase in the engraving sensitivity. When the carbon black coexists in the system, heat generated by the photo-thermal conversion function of the carbon black can be transferred to the organic peroxide as well as the binder polymer. As a result of this, heat can be generated not only from the carbon black but also from the organic peroxide, which results in synergistic generation of thermal energy to be used for the decomposition of the binder polymer. In this regard, organic dyes and pigments other than carbon black may also act in the same manner. However, organic dyes and pigments, which have low heat resistance, may be not endure the above-described synergetic heat generation, and may be thus decomposed. Accordingly, uses of organic dyes and pigments other than carbon black may not achieve as high sensitivity as that achieved by carbon black.

When the glass transition temperature of the binder polymer such as the specific binder polymer and the like is not lower than room temperature, the heat generated by the decomposition of the organic peroxide and released from the carbon black can be efficiently transferred to the binder polymer, and the heat can be effectively used for the thermal decomposition of the binder polymer, which may result in the achievement of the above-described effects.

The content of the photothermal conversion agent in the resin composition of the invention may vary largely depending on the magnitude of the molecular extinction coefficient inherent to the molecule, but the content is preferably in the range of from 0.01% by mass to 20% by mass, more preferably in the range of from 0.05% by mass to 10% by mass, and particularly preferably in the range of from 0.1% by mass to 5% by mass, with respect to the total solid content of the resin composition.

(F) Plasticizer

The resin composition of the invention preferably contains a plasticizer. Examples of the plasticizer include dioctyl phthalate, didodecyl phthalate, triethylene glycol dicaprylate, methyl glycol phthalate, tricresyl phosphate, dioctyl adipate, dibutyl sebacate, triacetylglycerin, and the like. Examples of the plasticizer further include polyethylene glycols, polypropylene glycol (mono-ol type, diol type and the like), and polypropylene glycol (mono-ol type, diol type and the like).

Since the plasticizer is expected to have an effect to soften a molded article which is formed from a resin composition, the plasticizer is desired to have good compatibility with the binder polymer. In general, a highly hydrophilic compound has good compatibility with the binder polymer. Among highly hydrophilic compounds, an ether compound containing a heteroatom in a straight chain, or a compound having a structure in which a hydrophilic group such as secondary amine and a hydrophobic group are alternately repeated, can be preferably used. The presence of the hydrophilic group such as —O— or —NH— achieves the compatibility of such compounds with PVA compounds, and the other hydrophobic group weakens the intermolecular force of PVA compounds, to thereby contribute to the softening.

A compound having fewer hydroxyl groups which are capable of forming hydrogen bonding between PVA compounds can be also preferably used as the plasticizer. Examples of such compound include ethylene glycol, propylene glycol, and dimers, trimers, and homo-oligomers or co-oligomers such as tetramer or higher-mers of ethylene glycol and propylene glycol, and secondary amines such as diethanolamine and dimethylolamine. Among these, ethylene glycols (monomers, dimers, trimers and oligomers) having small steric hindrance, excellent compatibility and low toxicity, are particularly preferably used as the plasticizer.

Ethylene glycols are roughly classified into three types according to the molecular weight. The first group includes ethylene glycol, which is a monomer; the second group includes diethylene glycol, which is a dimer, and triethylene glycol, which is a trimer; and the third group includes polyethylene glycol, which is a tetramer or higher one. Polyethylene glycol is roughly classified into liquid polyethylene glycol having a molecular weight in the range of 200 to 700, and solid polyethylene glycol having a molecular weight of 1000 or greater, and those are commercially available under names followed by the average molecular weight in many cases.

The lower molecular weight of the plasticizer is, the effect of the plasticizer to soften a resin is enhanced. In consideration of this, compounds which may be particularly preferably used as the plasticizer are ethylene glycol which belongs to the first group, diethylene glycol and triethylene glycol which belong to the second group, and tetraethylene glycol (tetramer) which belongs to the third group. Among them, diethylene glycol, triethylene glycol and tetraethylene glycol can be more preferably used as the plasticizer from the viewpoints of low toxicity, absence of extraction from the resin composition, and excellent handling property thereof. Mixtures of two or more of the plasticizers can be also preferably used.

The plasticizer may be added in a proportion of 10% by mass or less with respect to the total mass of the solid content of the resin composition.

Additives for Enhancing Engraving Sensitivity

### (Nitrocellulose)

It is more preferable that nitrocellulose as an additive for improving the engraving sensitivity is added to the resin composition of the invention.

Nitrocellulose, that is a self-reactive compound, generates heat at the time of laser engraving to assist thermal decomposition of the co-existing hydrophilic polymer. The engraving sensitivity is assumed to be enhanced as a result thereof.

Any nitrocellulose can be used in the invention as long as it can be thermally decomposed, and can be any one of RS (regular soluble) nitrocellulose, SS (spirit soluble) nitrocellulose and AS (alcohol soluble) nitrocellulose. The content of nitrogen in the nitrocellulose is usually about 10% by mass to 14% by mass, preferably 11% by mass to 12.5% by mass, and more preferably about 11.5% by mass to 12.2% by mass. The degree of polymerization of the nitrocellulose may also be selected from a wide range of about 10 to 1500. The polymerization degree of the nitrocellulose is typically 10 to 900, and preferably about 15 to about 150. Preferable examples of the nitrocellulose include those having a solution viscosity of 20 seconds to 1/10 seconds, more preferably about 10 seconds to ⅛ seconds, measured according to the method of viscosity indication provided by Hercules Powder Company, that is also known as JIS K6703 “Nitrocelluloses for Industrial Use”. The nitrocellulose which can be used in the invention typically has a solution viscosity of 5 seconds to ⅛ seconds, which is preferably about 1 second to ⅛ seconds.

The RS nitrocellulose (for example, a nitrocellulose having a nitrogen content of about 11.7% to 12.2%), which is soluble in a ester such as ethyl acetate, a ketone such as methyl ethyl ketone or methyl isobutyl ketone, or an ether such as cellosolve, can be used as a nitrocellulose which can be contained in the resin composition.

The nitrocellulose may be used singly or in combination of two or more thereof as necessary. The content of nitrocellulose may be selected as long as decrease in the engraving sensitivity of the resin composition for laser engraving can be avoided, and the content is typically 5 parts by mass to 300 parts by mass, preferably 20 parts by mass to 250 parts by mass, more preferably 50 parts by mass to 200 parts by mass, and particularly preferably 40 parts by mass to 200 parts by mass, with respect to 100 parts by mass of the binder polymer and the polymerizable compound.

(Highly Thermally Conductive Substance)

In view of improving the engraving sensitivity of the resin composition of the invention, a highly thermally conductive substance can be added to the resin composition of the invention as an additive for assisting heat transfer in the resin composition.

Examples of the highly thermally conductive substance include an inorganic compound such as a metal particle and an organic compound such as an electrically conductive polymer.

Preferable examples of the metal particle include gold microparticles, silver microparticles and copper microparticles, each having a particle size in the order of micrometers to a few nanometers.

Preferable examples of the electrically conductive polymers include polyaniline, polythiophene, polyisothianaphthene, polypyrrole, polyethylene dioxythiophene, polyacetylene and modified compounds thereof. From the viewpoint of being highly sensitive, polyaniline, polythiophene, polyethylene dioxythiophene and modified compounds thereof are further preferable, and polyaniline is paricularly preferable. While the polyaniline can be either in an emeraldine base form or in an emeraldine salt form when added to the resin composition, it can be preferably in an emeraldine salt form in view of higher heat transfer efficiency.

Specific examples of the metal particle and the electrically conductive polymer include commercially available products supplied by Sigma Aldrich Corp., Wako Pure Chemical Industries, Ltd., Tokyo Chemical Industry Co., Ltd., Mitsubishi Rayon Co., Ltd., Panipol Oy and the like. Specific examples which are particularly preferable in view of improving the heat transfer efficiency include AQUAPASS-01x (trade name, manufactured by Mitsubishi Rayon Co., Ltd.), and PANIPOL W and PANIPOL F (both trade names, manufactured by Panipol Oy).

It is preferable that the electrically conductive polymer is added to the resin composition in a form of an aqueous dispersion or an aqueous solution. As described above, the solvent used in preparing the resin composition is water or an alcoholic solvent in the case where an alcoholphilic polymer, which are preferable embodiments of the binder polymer. in the invention, are used. Accordingly, when the electrically conductive polymer is added to the resin composition in a form of an aqueous dispersion or an aqueous solution, miscibility of the electrically conductive polymer with a hydrophilic or an alcoholphilic polymer may become good, which may further result in increasing in the strength of a molded article such as a relief layer and the like formed by the resin composition and also in increasing the engraving sensitivity of the resin composition due to an improvement in its heat transfer efficiency.

Co-Sensitizer

The sensitivity required for photo-curing of the resin composition may be further enhanced by using a co-sensitizer. While the operating mechanism is not clear, it is thought to be largely based on the following chemical process. Namely, it is presumed that various intermediate active species (radicals and cations) generated in the course of a photoreaction initiated by a polymerization initiator and an addition polymerization reaction subsequent thereto, react with the co-sensitizer to generate new active radicals. These intermediate active species may be roughly classified into (a) compounds which are reduced and can generate active radicals; (b) compounds which are oxidized and can generate active radicals; and (c) compounds which react with less active radicals, and are converted to more active radicals or act as a chain transfer agent. However, in many cases, there is no general theory applicable on which individual compound belongs to which class.

Examples of the co-sensitizer which may be applied in the invention include the following compounds.

(a) Compounds which Generate Active Radicals Upon being Reduced

Compounds having a carbon-halogen bond are classified in this group. It is presumed that an active radical is generated when the carbon-halogen bond is reductively cleaved. Specific preferable examples of the compound include trihalomethyl-s-triazines and trihalomethyloxadiazoles.

Compounds having a nitrogen-nitrogen bond are also classified in this group. It is presumed that an active radical is generated when the nitrogen-nitrogen bond is reductively cleaved. Specific preferable examples of the compound include hexaarylbiimidazoles.

Compounds having an oxygen-oxygen bond are also classified in this group. It is presumed that an active radical is generated when the oxygen-oxygen bond is reductively cleaved. Specific preferable examples of the compound include organic peroxides.

Onium compounds are also classified in this group. It is presumed that an active radical is generated when a carbon-heteroatom bond or an oxygen-nitrogen bond in an onium compound is reductively cleaved. Specific preferable examples of the compound include diaryliodonium salts, triarylsulfonium salts, N-alkoxypyridinium salts (azinium) salts, and the like.

Ferrocenes and iron arene complexes are also classified in this group. It is presumed that an active radical is reductively generated therefrom.

(b) Compounds which Generate Active Radicals Upon being Oxidized

Alkylate complexes can be classified in this group. It is presumed that an active radical is generated when a carbon-heteroatom bond therein is oxidatively cleaved. Specific preferable examples thereof include triarylalkylborates.

Alkylamine compounds can be also classified in this group. It is presumed that an active radical is generated when a C—X bond on a carbon atom which is adjacent to a nitrogen atom therein is cleaved through oxidation. Preferable examples of the X include a hydrogen atom, a carboxyl group, a trimethylsilyl group, a benzyl group and the like. Specific preferable examples of the alkylamine compound include ethanolamines, N-phenylglycine, and N-trimethylsilylmethylanilines.

Sulfur-containing or tin-containing compounds, which are obtained by substituting the nitrogen atom of the above-mentioned alkylamine compounds by a sulfur atom or a tin atom, can be also classified in this group and may generate an active radical in a similar manner as the alkylamine compounds. Compounds having an S—S bond are also known to have sensitivity enhancing property by the S—S bond cleavage.

α-substituted methylcarbonyl compounds, which may generate an active radical by the cleavage of a bond between a carbonyl moiety and an α-carbon atom through oxidation, can be also classified in this group. Compounds obtained by converting the carbonyl moiety in the α-substituted methylcarbonyl compounds into an oxime ether also show an effect which is similar to that of the α-substituted methylcarbonyl compounds. Specific examples of the compounds include 2-alkyl-1-[4-(alkylthio)phenyl]-2-morpholinopronone-1's, and oxime ethers obtained by reacting a 2-alkyl-1-[4-(alkylthio)phenyl]-2-morpholinopronone-1 with a hydroxylamine and then etherifying the N—OH moiety in the resultant.

Sulfinic acid salts can be also classified in this group. An active radical may be reductively generated therefrom. Specific examples thereof include sodium arylsulfinate.

(c) Compounds which Convert Less Active Radicals to More Active Radicals by Reacting therewith, and Compounds which Act as a Chain Transfer Agent

Compounds having SH, PH, SiH or GeH within the molecule can be classified in this group. These compounds may generate a radical by donating hydrogen to a less active radical species, or may generate a radical by being oxidized and then deprotonated. Specific examples thereof include 2-mercaptobenzothiazoles, 2-mercaptobenzoxazoles, 2-mercaptobenzimidazoles, and the like.

More specific examples of these co-sensitizers are described in, for example, JP-A No. 9-236913, as additives for enhancing the sensitivity, and those may also be applied in the invention. Some examples thereof will be shown below, while the invention is not limited thereto. In the following formulae, “-TMS” represents a trimethylsilyl group.

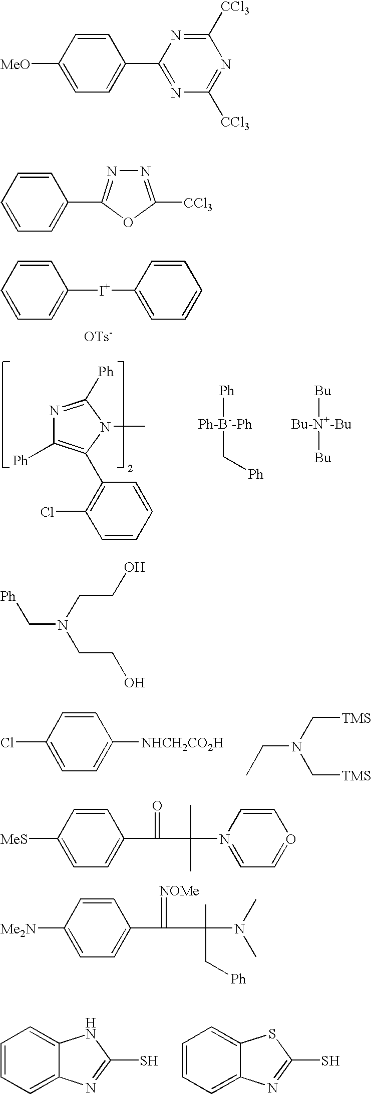

As is similar to the photo-thermal conversion agent, various chemical modifications for improving the properties of the resin composition may be carried out to the co-sensitizer. Examples of a method for the chemical modification include: bonding with the photo-thermal conversion agent, with the polymerizable compound or with some other part; introduction of a hydrophilic site; enhancement of compatibility; introduction of a substituent for suppressing crystal precipitation; introduction of a substituent for enhancing adhesiveness; and conversion into a polymer.

The co-sensitizer may be used singly, or in combination of two or more species thereof.

The content of the co-sensitizer in the resin composition of the invention is preferably 0.05 parts by mass to 100 parts by mass, more preferably 1 parts by mass to 80 parts by mass, and even more preferably 3 parts by mass to 50 parts by mass, with respect to 100 parts by mass of the polymerizable compound.

Polymerization Inhibitor

A small amount of thermal polymerization inhibitor can be preferably added to the resin composition of the invention in view of inhibiting unnecessary thermal polymerization of the polymerizable compound during the production or storage of the resin composition. Suitable examples of the thermal polymerization inhibitor include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), N-nitrosophenylhydroxylamine cerium (I) salt, and the like.

Q-1301 (trade name, manufactured by Wako Pure Chemical Industries, Ltd., a 10% tricresyl phosphate solution) can be preferably used as the polymerization inhibitor from the viewpoint of excellent stability in storage of the resin composition of the invention. When Q-1301 is used in combination with the polymerizable compound, the storage stability of the resin composition of the invention can be significantly excellent, and good laser engraving sensitivity may be obtained. The addition amount of the thermal polymerization inhibitor is preferably 0.01% by mass to 5% by mass with respect to the total mass of the resin composition for laser engraving.

Also, if necessary, in order to prevent the inhibition of polymerization caused by oxygen, a higher fatty acid compound such as behenic acid or behenic acid amide may be added to the resin composition and can be localized at the surface of the layer during the course of drying of the layer performed after the resin composition is applied over (on or above) a support or the like. The addition amount of the higher fatty acid compound can be preferably 0.5% by mass to 10% by mass with respect to the total mass of the resin composition of the invention.

Colorant

A colorant such as a dye or a pigment may also be added to the resin composition of the invention for the purpose of coloring the resin composition.

The addition of the dye or the pigment may enhance properties of the resin composition such as the visibility of the image part, suitability for image density measuring device and the like. A pigment is particularly preferably used as the colorant in the invention. Specific examples of the colorant include pigments such as phthalocyanine pigments, azo pigments, carbon black or titanium oxide; and dyes such as Ethyl Violet, Crystal Violet, azo dyes, anthraquinone dyes or cyanine dyes.

The amount of addition of the colorant is preferably about 0.5% by mass to 5% by mass with respect to the total mass of the resin composition of the invention.

Other Additives

In order to improve the properties of cured products formed from the resin composition of the invention, known additives such as a filler may also be added.

Examples of the filler include carbon black, carbon nanotubes, fullerene, graphite, silica, alumina, aluminum, calcium carbonate and the like, and these fillers can be used individually or as mixtures of two or more thereof.

### 2. Relief Printing Plate Precursor for Laser Engraving

The relief printing plate precursor for laser engraving of the invention has a relief forming layer formed by thermally crosslinking the resin composition of the invention described above. This relief forming layer is preferably provided on a support. Hereinafter, the relief printing plate precursor for laser engraving of the invention may be simply referred to as a “relief printing plate precursor” in the following explanation.

Since the relief forming layer in the relief printing plate precursor of the invention has high engraving sensitivity when subjected to laser engraving as described above, laser engraving may be performed at high speed, and thus the engraving time may be shortened.

The relief printing plate precursor of the invention offers an excellent effect that it is easy to remove the engraving residue from the plate surface after plate making.

The relief printing plate precursor of the invention having such characteristics is not particularly limited, and may be widely applied to the applications of a relief printing plate precursor provided with laser engraving. For example, as will be described later, the relief printing plate precursor of the invention may be applied to a relief printing plate precursor intended for the formation of a convex-shaped relief by laser engraving, as well as to another type of material for forming concavity and convexity or an opening at the surface, for example, an intaglio plate, a porous plate, a stamp or the like, as various printing plate precursors on which images are formed (relief forming) by laser engraving.

The relief printing plate precursor for laser engraving may further have an adhesive layer between a support and a relief forming layer, and a slip coating layer and a protective film on the relief forming layer, as necessary. Hereinafter, the constituent elements of the relief printing plate precursor of the invention will be described.

Relief Forming Layer

The relief forming layer is a layer containing the resin composition of the invention described above. The relief forming layer can be obtained as a crosslinkable one by employing a crosslinkable resin composition as the resin composition. The relief printing plate precursor for laser engraving of the invention preferably has a crosslinkable relief forming layer.

In embodiments, a manufacturing method of a relief printing plate from the relief printing plate precursor for laser engraving preferably includes: crosslinking components of the relief forming layer; and laser engraving the crosslinked relief forming layer to form a relief layer. The crosslinking may enable to suppress wearing of the relief forming layer subjected to printing and provide a relief printing plate having a sharp (well-defined) relief layer by laser engraving.

The total content of the binder polymer in the relief forming layer is preferably from 30 to 80% by mass, and more preferably from 40 to 70% by mass, with respect to the total mass of the solid content in the composition constituting the relief forming layer. When the total content of the binder polymer is in the aforementioned range, the printing plate precursor can be prevented from causing a cold flow, and effects of other components for improving other properties can be sufficiently obtained, and a sufficient print durability as a printing plate may be provided to the relief printing plate resulting therefrom.

The content of the polymerization initiator in the relief forming layer is preferably from 0.01 to 10% by mass, and more preferably from 0.1 to 3% by mass, with respect to the total mass of the solid content in the relief forming layer. When the content of the polymerization initiator is set to 0.01% by mass or more, thermal crosslinking is rapidly carried out upon forming a relief forming layer. When the content is set to 10% by mass or less, there can be no occurrence of the lack of other components, and a sufficient print durability as a printing plate may be provided to the relief printing plate resulting therefrom.

The content of the polymerizable compound in the relief forming layer is preferably from 10% by mass to 60% by mass, and more preferably from 15% by mass to 40% by mass, with respect to the total mass of the solid content of the relief forming layer. When the content of the polymerizable compound is set to 10% by mass or more, the effect of the addition of the polymerization initiator can be sufficiently obtained to provide a sufficient print durability as a printing plate to the relief printing plate resulting therefrom. When the content of the polymerizable compound is set to 60% by mass or less, a sufficient strength as a printing plate may be provided to the relief printing plate resulting therefrom.

The relief forming layer may be formed by using a relief forming layer coating solution containing the resin composition of the invention, and then forming the resin composition in the form of a sheet or sleeve. The relief forming layer is usually provided over (on or above) a surface of a support. Alternatively, the relief forming layer may be directly provided onto a surface of a member such as a cylinder integrated in an apparatus for plate-making or printing, or may be shaped and then fixed onto a surface of such a member.

Explanation is hereinafter given with respect to an embodiment in which the relief forming layer is formed into a sheet shape.

Support

A support which may be used in the relief printing plate precursor for laser engraving will be described.

The material used in the support for the relief printing plate precursor for laser engraving is not particularly limited, but a material having high dimensional stability is preferably used. Examples thereof include metals such as steel, stainless steel and aluminum, plastic resins such as polyester (for example, PET, PBT, or PAN) and polyvinyl chloride, synthetic rubbers such as styrene-butadiene rubber, and plastic resins (epoxy resin, phenolic resin, and the like) reinforced with glass fiber. Among them, a PET (polyethylene terephthalate) film or a steel substrate is preferably used as the support. The shape of the support is determined by whether the relief forming layer is in a sheet shape or in a sleeve shape.

A preferable support that may be used in the case of forming the relief forming layer in a sleeve shape will be described below in detail.

Adhesive Layer

An adhesive layer may be provided between the relief forming layer and the support for the purpose of reinforcing the adhesive strength between the two layers.

Any material, which may enhance the adhesive force after the relief forming layer is formed by thermal crosslinking, can be employed. Here, the adhesive strength means both the adhesive strength between the support and the adhesive layer, and the adhesive strength between the adhesive layer and the relief forming layer.

The adhesive force between the support/the adhesive layer is such that, upon peeling of the adhesive layer and the relief forming layer from a laminate consisting of the support/the adhesive layer/the relief forming layer at the rate of 400 mm/min, the peeling force per 1 cm width of a sample is preferably 1.0 N/cm or more, or unpeelable, more preferably 3.0 N/cm or more, or unpeelable.

The adhesive force of the adhesive layer/the relief forming layer is such that, upon peeling of the adhesive layer from the adhesive layer/the relief forming layer at the rate of 400 mm/min, the peeling force per 1 cm width of a sample is preferably 1.0 N/cm or more, or unpeelable, more preferably 3.0 N/cm or more, or unpeelable.

As a material which may be used in the adhesive layer (adhesive), for example, a material described in I. Skeist, “Handbook of Adhesives”, second edition (1977) may be used.

Protective Film and Slip Coat Layer

The relief forming layer becomes the part at which a relief is formed after the laser engraving. The surface of the convex portion of the relief may generally function as an ink deposition portion. There is almost no concern for generation of damages or dents on the surface of the relief forming layer which might affect printing when the relief forming layer is cured by crosslinking, since the thus-crosslinked relief forming layer has strength and hardness. However, the crosslink-curable relief forming layer which is not subjected to the crosslinking tend to have soft surfaces and are concerned for generation of damages or dents on the surface thereof when they are handled. From the viewpoint of prevention of the damages or dents, a protective film may be provided over (on or above) the relief forming layer.

If the protective film is too thin, the effect of preventing damages and depressions may not be obtained, and if the protective film is too thick, inconvenience may arise upon the handling thereof and production costs therefor may become higher. In consideration of these, the thickness of the protective film is preferably 25 μm to 500 μm, and more preferably 50 μm to 200 μm.

In the protecting film, a material known as the protecting film of the printing plate, for example, a polyester film such as PET (polyethylene terephthalate), and a polyolefin film such as PE (polyethylene) and PP (polypropylene) may be used. A surface of the film may be plain, or may be matted.

When the protecting film is provided on the relief forming layer, the protecting film should be peelable.

When the protecting film is unpeelable, or when the protecting film is hardly adhered on the relief forming layer, a slip coating layer may be provided between both layers.

A material used in the slip coating layer is preferably a material containing, as a main component, a resin which is soluble or dispersible in water, and has little adhering property, such as polyvinyl alcohol, polyvinyl acetate, partially saponified polyvinyl alcohol, hydroxyalkylcellulose, alkylcellulose, and polyamide resin. Among them, from a viewpoint of adhering property, partially saponified polyvinyl alcohol having a saponification degree of 60 mol % to 99 mol %, and hydroxyalkylcellulose and alkylcellulose having an alkyl group having 1 to 5 carbon atoms are particularly preferably used.

When the protecting film is peeled from the relief forming layer (and the slip coating layer)/the protecting film at the rate of 200 mm/min, the peeling force per 1 cm is preferably 5 mN/cm to 200 mN/cm, further preferably 10 mN/cm to 150 mN/cm. When the peeling force is 5 mN/cm or more, working may be performed without peeling of the protecting film during working and, when the peeling force is 200 mN/cm or less, the peeling film may be peeled naturally.

Method of Producing the Relief Printing Plate Precursor for Laser Engraving

The method of producing the relief printing plate precursor for laser engraving will be described.

There is no particular limitation to the preparation of a relief forming layer of a relief printing plate precursor for laser engraving according to the invention. Examples of the method for preparing the relief forming layer include: a method including removing the solvent from the application solution composition for forming a relief forming layer prepared as described above and fusion extruding the composition to on or above a support or a plate cylinder. Alternatively, when the relief forming layer is formed over a support, a method including flowing the application solution composition for forming a relief forming layer over a support and drying the resultant in an oven to remove the solvent from the composition may be employed.

Thereafter, if necessary, the protecting film may be laminated on the relief forming layer. Lamination may be performed by pressing the protecting film and the relief forming layer with a heated calendar roll, or adhering the protecting film to the relief forming layer having a surface impregnated with a small amount of a solvent.

When the protecting film is used, a process of first laminating the relief forming layer on the protecting film and, then, laminating the support may be adopted.

When the adhesive layer is provided, the support coated with an adhesive layer may be used. When the slip coating layer is provided, the protecting film coated with a slip coating layer may be used.

The coating liquid composition for the relief forming layer may be produced, for example, by dissolving components of (A) to (D) as an the essential component and, as an optional component, a photothermal conversion agent and a plasticizer in a suitable solvent and, then, dissolving a polymerizable compound and a polymerization initiator.

Since most of a solvent component is necessary to be removed at a stage of producing the relief printing plate precursor, it is preferable that, as a solvent, an easily vaporized low-molecular alcohol (e.g. methanol) is used, and the total addition amount of the solvent is suppressed as less as possible. When a temperature of the system is high, an addition amount of the solvent may be suppressed, but when a temperature is too high, since a polymerizable compound is easily polymerization-reacted, a temperature for preparing a coating liquid composition after addition of the polymerizable compound and/or the polymerization initiator is preferably 30° C. to 80° C.

A thickness of the relief forming layer of the relief printing plate precursor for laser engraving is preferably 0.05 mm to 10 mm, more preferably 0.05 mm to 7 mm and, particularly preferably, 0.05 mm to 0.3 mm.

Formation of the relief forming layer in a sleeve shape is described. Any known methods for molding a resin may be employed when the relief forming layer is formed in a sleeve shape. Examples thereof include: a casting method; a method including extruding a resin from a nozzle or a dice by a machine such as a pump or an extruder and adjusting a thickness of the resultant by use of a blade or by a calendar processing with rolls. During the molding, heat with a temperature, by which characteristics of a resin composition which configures the relief forming layer are not deteriorated, can be applied to the molding system. A rolling treatment, an abrading treatment, and/or the like may be further performed if necessary.

When the relief forming layer is made into a sleeve shape, the relief forming layer may be formed by being molded into a cylindrical shape at the initial stage of the molding, or may be formed by being molded into a sheet shape at first and then made into a cylindrical shape by being fixed on a cylindrical support or a plate cylinder. There is no particular limitation for the fixing of the sheet-shaped support to the cylindrical support, and examples thereof include: fixing the sheet-shaped support to the cylindrical support by using an adhesive tape having an adhesive layer, a tackifying layer, or the like provided on each of both sides; and fixing the sheet-shaped support to the cylindrical support via a layer containing an adhesive agent.

Examples of the adhesive tape include: a tape having a tackifying agent layer or an adhesive agent layer formed of an acrylic resin, a methacrylic resin, a styrene thermoplastic elastomer or the like formed on both sides of a film base material such as a polyester film or a polyolefin film; and a tape which has a base material formed of a foamed body of a polyolefin resin such as polyethylene or a polyurethane resin and provided with a tackifying agent layer or an adhesive agent layer as described above on both of sides thereof and has a cushioning property. A commercially available tape with adhesive on both sides or a cushion tape having tackifying agent layers on both sides may be appropriately used as well.

The adhesive agent layer used in the case that a cylindrical support and the relief forming layer are fixed via the adhesive agent layer can be formed using any known adhesive agents. Examples of an adhesive agent which can be used for the fixing of the relief forming layer to the cylindrical support include a rubber adhesive agent such as a styrene butadiene rubber (SBR), a chloroprene rubber or a nitrile rubber, and an adhesive agent which is hardened by moisture in air such as a silicone resin or a polyurethane resin having silyl group.

When the relief forming layer is made into a cylindrical shape, the relief forming layer may be formed by being molded into a cylindrical shape by a known method at first and then fixed on a cylindrical support, or may be formed by directly molded into a cylindrical shape by extrusion molding or the like so as to be a sleeve shape. The former method is preferably used in view of the productivity. When the relief forming layer is made into a sleeve shape, the thus-formed sleeve-shaped relief forming layer may still be subjected to crosslinking and hardened after being fixed onto a cylindrical support if necessary, and a rolling treatment, an abrading treatment or the like can be further carried out if desired.

Examples of the cylindrical support used in making the relief forming layer into a sleeve shape include: a metal sleeve formed of a metal such as nickel, stainless steel, iron or aluminum; a plastic sleeve formed by molding a resin; a sleeve formed of a fiber reinforced plastics (FRP sleeve) having a glass fiber, a carbon fiber, an aramid fiber or the like as a reinforcing fiber fiber-reinforced plastic; and a sleeve formed of a polymer film and having a shape maintained by compressed air.

The thickness of the cylindrical support may be arbitrarily selected depending upon the object, and the thickness can be typically sufficient as long as it is 0.1 mm or more and as long as the cylindrical support is not destructed by a pressure applied thereto when it is subjected to printing. In the case that the cylindrical support is a metal sleeve or a hard plastic sleeve, those having a thickness of 5 mm or more may be used as well, and it is also possible to use a cylindrical support having a solid body penetrated by a rotation axis (namely, a cylindrical support which is fixed to a rotating axis).

In view of an effective fixation of a shrinkable relief forming layer to the cylindrical support, the cylindrical support preferably has such characteristics that an inner diameter of the cylindrical support can expand by a air compressed to have pressure of about 6 bars and that it returns to have its initial inner diameter after the compressed air is released. A support having such a structure (namely, a structure with a diameter which can be easily adjusted by compressed air or the like) is preferable since a stress can be applied to the relief forming layer having a sleeve shape from inside thereof, a tightly rolling characteristic of the relief forming layer can work and, the relief layer can be stably fixed on a cylindrical plate or a plate cylinder even when a stress is applied thereto when it is subjected to printing.

### 3. Relief Printing Plate and Production Thereof

The method of producing a relief printing plate by using the relief printing plate precursor of the invention preferably includes: (1) a process of crosslinking the relief forming layer in the relief printing plate precursor for laser engraving of the invention by applying light or heat, and (2) a process of laser engraving the relief forming layer that has been subjected to crosslinking to form a relief layer. By this production method, a relief printing plate having a relief layer on a support can be produced using the relief printing plate precursor of the invention.

A preferable method of producing a relief printing plate according to the invention may further include, subsequently to the process (2), the following processes (3) to (5), as necessary.

Process (3): A process of rinsing the engraved surface of the relief layer after engraving, with water or a liquid consisting water as a main component (rinsing process)

Process (4): A process of drying the engraved relief layer (drying process)

Process (5): A process of further crosslinking the relief layer by supplying energy to the relief layer after engraving (post-crosslinking process).

The crosslinking of the relief forming layer in the process (1) is carried out by irradiation with active light and/or by heating.

When both the process of crosslinking with light and the process of crosslinking by heating are used in the crosslinking of the relief forming layer in the process (1), these two processes may be carried out simultaneously or separately.

The process (1) is a process to crosslinking the relief forming layer of the relief printing plate precursor for laser engraving by light and/or heat.

The relief forming layer contains the specific complex and the specific binder polymer and preferably further contains the photothermal conversion agent, the polymerization initiator and the polymerizable compound. The process (1) is a process in which the polymerizable compound is reacted to form crosslinking by the action of the polymerization initiator, thereby converting the relief forming layer into a hardened (cured) relief forming layer.

The polymerization initiator is preferably a radical generator. Radical generators are roughly classified into photopolymerization initiators and thermal polymerization initiators, depending on whether the trigger of the respective generating radical is light or heat.

When the relief forming layer contains a photopolymerization initiator, a crosslinked structure can be formed in the relief forming layer by irradiating the relief forming layer with actinic ray which serves as the trigger of the photopolymerization initiator (process of crosslinking with light).

The irradiation of actinic ray is generally carried out over the entire surface of the relief forming layer. Examples of the actinic ray include visible light, ultraviolet radiation and an electron beam, but ultraviolet radiation is most generally used. While it is acceptable to perform the irradiation of the actinic ray only to a front surface of a support, which is the opposite side of a rear surface of the relief forming layer which faces a base material such as the support to which the relied forming layer is provided, it is preferable to irradiate the actinic ray also from the rear surface as well as from the front surface when the support is a transparent film which transmits actinic ray. When the protective film is present, the irradiation from the front surface may be carried out with the protective film being provided, or may be carried out after the protective film has been removed. Considering the presence of oxygen which may cause a polymerization inhibition, the irradiation with actinic ray may be carried out after coating the crosslinkable relief forming layer with a vinyl chloride sheet under vacuum.

When the relief forming layer contains a thermal polymerization initiator (some of the photopolymerization initiator described above can also function as a thermopolymerization initiator), a crosslinked structure can be formed in the relief forming layer by heating the relief printing plate precursor for laser engraving (process of crosslinking by heat). Herein, the photopolymerization initiator may be a thermal polymerization initiator in some cases. Examples of the method of heating include a method of heating the printing plate precursor in a hot air oven or a far-infrared oven for a predetermined time and a method of contacting the printing plate precursor with a heated roll for a predetermined time.

When the process (1) is a process of crosslinking with light, an apparatus for applying active light is relatively expensive, but there is almost no limitation to the material to form the relief printing plate precursor, because the temperature of the relief printing plate precursor may not be greatly affected by the irradiation of active ray.

When the process (1) is a process of crosslinking with heat, there is an advantage that a special expensive apparatus is not necessary required. However, the printing plate precursor is heated to high temperature so that a thermoplastic polymer softening at high temperature can be deformed during heating. Accordingly, cares may be necessarily taken to select a compound used in the relief forming layer.

A thermal polymerization initiator can be added upon the crosslinking by heat. Commercially-available thermal polymerization initiator for free radical polymerization can be used as the thermal polymerization initiator. Examples of the thermal polymerization initiator include an appropriate peroxide, a hydroperoxide, and a compound containing an azo group. Typical vulcanizers can also be used for crosslinking. Crosslinking by heat can be also carried out by adding, as a crosslinking ingredient, a thermally crosslinkable resin (heat-curable resin) such as an epoxy resin to the relief forming layer.

The crosslinking by heat can be preferable as a crosslinking method for the relief forming layer in the process (1) with a viewpoint that the relief forming layer can be uniformly cured (crosslinked) from the surface to the inside.

The crosslinking in the relief forming layer has a first advantage that a relief formed after the laser engraving can become sharp as well as a second advantage that stickiness of engraving wastes formed upon laser engraving can be suppressed. When a relief forming layer which is not subjected to crosslinking is laser-engraved, a portion which is not intended to be engraved tends to be melted or deformed by remaining heat prevailing to the periphery of a portion irradiated with the laser to prevent obtaining a sharp relief layer in some cases. Further, In general, the lower a molecular weight of a material, the more the material tends to be liquid rather than solid to increase the stickiness of the material. Stickiness of engraving wastes formed upon engraving the relief forming layer tends to increase as the amount of using the low molecular weight material increases. Since the polymerizable compound, which is a low molecular material, can be formed into a high molecular weight material by crosslinking, the stickiness of the engraving wastes to be formed from the crosslinked relief forming layer tends to be decreased.

In the process (2), the relief forming layer subjected to the crosslinking is engraved with laser to form a relief layer. The engraving process is preferably performed by irradiating the relief forming layer with laser light which corresponds to a desired image to be formed with employing a specific laser described below so that a relief layer to be used for printing can be formed thereby.

More specifically, a relief layer is formed in the process (2) by irradiating the relief forming layer with a laser light and corresponding to a desired image to be formed. The engraving preferably includes controlling the laser head with a computer based on the digital data of a desired image to be formed, and performing scanning irradiation over the relief forming layer. When an infrared laser is irradiated, molecules in the relief forming layer undergo molecular vibration, and thus heat is generated. When a high power laser such as a carbon dioxide laser or a YAG laser is used as the infrared laser, a large amount of heat is generated at the laser-irradiated areas, and the molecules in the photosensitive layer undergo molecular breakage or ionization, so that selective removal (that is, engraving) can be achieved. In a case that a photo-thermal conversion agent is contained in the relief forming layer, heat is generated in the irradiated portion. The heat generated by the photo-thermal conversion agent can also enhance the selective removal.

An advantage of the laser engraving is the ability to three-dimensionally control the structure of the engraved portion since the depth of engraving can be arbitrarily set thereby. For example, when areas for printing fine dots are engraved shallowly or with a shoulder, the relief may be prevented from collapsing under printing pressure. When groove areas for printing cutout characters are engraved deeply, the grooves may be hardly filled with ink, and collapse of the cutout characters may be thus suppressed.

When the engraving is performed with an infrared laser which corresponds to the maximum absorption wavelength of the photo-thermal conversion agent, a more sensitive and well-defined (sharp) relief layer can be obtained.

As an infrared laser used for laser engraving, carbon dioxide gas laser or semiconductor laser is preferable from the viewpoint of improving productivity and reducing costs, a CO₂ laser or a semiconductor laser can be preferably used, and among these, a fiber-coupled semiconductor infrared laser described below can be particularly preferably used.

Platemaking Device Equipped with Semiconductor Laser

In general, a semiconductor laser exhibits high efficiency in laser oscillation, is less expensive and can be made smaller as compared with CO₂ lasers. Moreover, due to its small size, a semiconductor laser can be easily provided in an array. Control of its beam diameter can be done by an imaging lens or a specific optical fiber. A fiber-coupled semiconductor laser can be effective for the image formation of the invention since it can efficiently output laser beam by an optical fiber installed therein. A shape of the laser beam can be controlled by processing the optical fiber. For example, a beam profile of the laser beam can be made into a top-hat shape so as to stably apply energy to a plate surface. Details of the semiconductor laser are described, for example, in “Laser Handbook”, Second Edition, edited by Laser Society and “Practical Laser Technique”, Electronic Communication Society.

In addition, the platemaking apparatus equipped with semiconductor laser with fiber which may be preferably used in the process for producing the relief printing plate using the relief printing plate precursor of the invention is described in detail in JP-A 2009-172658, and this may be used in platemaking of the relief printing plate related to the invention.

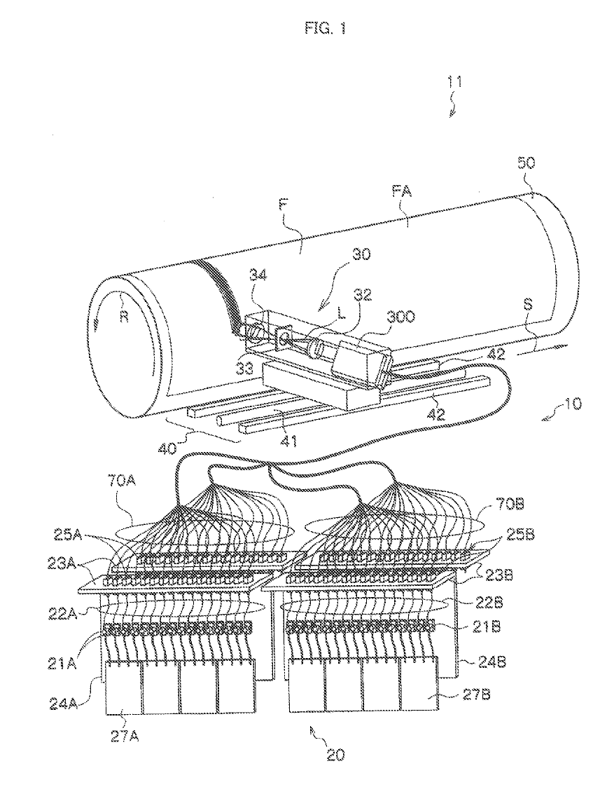

An embodiment of the plate making device equipped with a fiber-coupled semiconductor laser recording device which can be used in the method of making a printing plate of the invention will be illustrated hereinafter with respect its configuration by referring to FIG. 1.

A plate making device 11 which can be used in the method of the invention is equipped with: a fiber-coupled semiconductor laser recording device 10; and a plate making device 11 has a drum 50, which has an outer circumference surface, on which a printing plate precursor F (recording medium) of the invention can be attached. The laser recording device 10 has: a light source unit 20 which generates plural laser beams; a exposure head 30 which expose the relief printing plate precursor F to the plural laser beams generated by the light source unit 20; and a moving unit 40 of exposure head which moves the exposure head 30 in the auxiliary scanning direction.

The plate making device 11 drives the drum 50 to rotate in a main scanning direction (the direction indicated by an arrow R) and, at the same time, have an exposure head 30 to scan the drum 50 in an auxiliary scanning direction, which is at right angle to the main scanning direction and is indicated by an arrow S, while simultaneously emitting plural laser beams corresponding to image data to be engraved (recorded) from the exposure head 30 to the relief printing plate precursor F, so that a two-dimensional image can be engraved (recorded) on the relief printing plate precursor F at high speed. In the case where a narrow region is engraved (namely, when a precise engraving is performed for forming fine lines, fine dots or the like), the relief printing plate precursor F can be engraved shallowly. In the case where a broad region is engraved, the relief printing plate precursor F can be engraved deeply.

The light source unit 20 is equipped with: semiconductor lasers 21A and 21B, each of which has a broad area semiconductor laser to which an end of each of optical fibers 22A or 22B is indivisually coupled; light source supports 24A and 24B, each of which has the semiconductor laser 21A or 21B aligned on the surface thereof; adaptor supports 23A and 23B, each of which is vertically attached to an end of the light source support 24A or 24B and a plural (the same numbers as in the semiconductor lasers 21A, 21B) adaptors of SC-type light connectors 25A or 25B are installed thereon; and LD (laser diode) driver supports 27A and 27B, each of which is horizontally attached to another end of the light source support 24A or 24B and is installed with a LD driver circuit (not shown in FIG. 1) which drives the semiconductor lasers 21A and 21B corresponding to the image data of the image to be engraved (recorded) on the relief printing plate precursor F.

The exposure head 30 is equipped with a fiber array unit 300 by which laser beams emitted from the plural semiconductor lasers 21A and 21B can be emitted together. Each of the laser beams emitted from the semiconductor laser 21A or 21B is conveyed to the fiber array unit 300 by one among plural optical fibers 70A and 70B, which are connected to the SC-type light connector 25A or 25B connected to the adaptor supports 23A or 23B.

As shown in FIG. 1, the exposure head 30 has a collimator lens 32, an opening material 33 and an imaging lens 34 which are aligned in this order with respect to a position in which the fiber array unit 300 is disposed. The opening material 33 is aligned such that its opening resides at the position of a far field when looked from the side of the fiber array unit 300. As a result, a similar degree of light quantity restricting effect can be provided to all laser beams emitted from terminals 71A or 71B of the optical fibers 70A or 70B at the fiber array unit 300.

Laser beam forms an image at a vicinity of the exposure side (surface) FA of the relief printing plate precursor F by an imaging unit having the collimator lens 32 and the imaging lens 34 in its configuration.

The fiber-coupled semiconductor laser can change a shape of the laser beam emitted therefrom. In view of efficient engraving and good reproducibility of fine lines, it is preferable in the invention to control a spot diameter the laser beam to be in a range of 10 μm to 80 μm on the exposed surface (surface of a relief forming layer) FA by, for example, controlling the shape of the laser beam to have the imaging position (image forming position) P be within an area of inner side with respect to the exposure surface FA (the side of forwarding direction of laser beam) or the like.

The exposure head moving unit 40 is equipped with two rails 42 and a ball screw 41 aligned in such a manner that their longitudinal direction are along the auxiliary scanning direction. A pedestal 310 equipped with the exposure head 30 can be moved in an auxiliary scanning direction with being guided by the rail 42 by operating an auxiliary scanning motor 43, which drives and rotates the ball screw 41. The drum 50 can be rotated in the direction of the arrow R when a main scanning motor (not shown) is operated, whereby the main scanning is performed.

It is also possible to control the shape of the engraved region by controlling the amount of energy applied to the surface of the relief forming layer by the laser beam without changing the shape of the laser beam from the fiber-coupled semiconductor laser.

Specific examples of the energy amount controlling-method include a method in which output power of the semiconductor laser is changed and a method in which a time length employed for the laser irradiation is changed.

If engraving remnants remain and adhere to the engraved surface, the rinsing process of rinsing, in which the engraved surface is rinsed with water or with a liquid containing water as a main component to wash away the engraving remnants, may be further performed. Examples of the method of the rinsing include a method of spraying water at high pressure, or a method of brush rubbing the engraved surface, mainly in the presence of water, using a batch type- or conveyor type-brush washout machine known as a developing machine for photosensitive resin letterpress plates, and the like. If the viscous liquid of the engraving remnants cannot be removed by simply washing with the water or the liquid, a rinsing solution containing soap may be used.

When the rinsing process is performed to the engraved surface, it is preferable to further perform the drying process in which the relief layer which has been engraved is dried to volatilize the rinsing solution.

Further, the post-crosslinking process (5) in which a crosslinked structure is formed in the relief layer can be carried out if necessity. By carrying out the post-crosslinking process (5), the relief formed by engraving may be further strengthened.

The relief printing plate according to the invention, that has a relief layer over a support, can be thus obtained.

A thickness of the relief layer of the relief printing plate is preferably in a range of 0.05 mm to 10 mm, more preferably in a range of 0.05 mm to 7 mm, and particularly preferably in a range of 0.05 mm to 3 mm in view of satisfying various applicability to flexographic printing such as wearing resistance or ink transfer property.

The Shore A hardness of the relief forming layer subjected to the crosslinking is preferably from 50° to 90°.

When the Shore A hardness of the relief layer is 50° or more, the fine dots formed by engraving may not be fall and break even under the high printing pressure of a letterpress printing machine, and proper printing may be achieved. When the Shore A hardness of the relief layer is 90° or less, print scratches at solid parts may be prevented even in flexographic printing with a kiss-touch printing pressure.

The “Shore A hardness” herein means a value measured by a durometer (spring type rubber hardness meter), which impinges a presser (referred to as a penetration needle or an indenter) to a surface of an object to cause deformation of the surface, and measures the amount of the deformation (penetration depth) of the surface and expresses the result in a numerical value.

A relief printing plate produced from the relief printing plate precursor of the invention can be used in printing with any of aqueous ink, oily ink and UV ink in a letterpress printing machine, and can also be used in printing with UV ink in a flexographic press. A relief printing plate obtained from the relief printing plate precursor of the invention is excellent both in aqueous ink suitability and in UV ink suitability, and so printing can be performed without worrying about reduction, caused by ink, in the strength of the relief layer and deterioration in printing durability.

According to the invention, a resin composition for layer engraving is provided, which has high engraving sensitivity to laser engraving and allows engraving residue generated during engraving to be easily removed, as described above. According to the invention, a relief printing plate precursor for laser engraving is also provided, which has high engraving sensitivity, enables direct plate-making by laser engraving, and allows engraving residue on a printing plate after plate-making to be easily removable. According to the invention, a method of producing a relief printing plate by using the relief printing plate precursor for laser engraving is also provided, as well as a relief printing plate obtained by the production method.

### Examples

Hereinafter, the present invention will be described in more detail by way of Examples, but the invention is not intended to be limited to these Examples.

The weight average molecular weight (Mw) of a polymer in the Examples indicates, unless stated otherwise, a value measured by a gel permeation chromatography (GPC) method.

### Example 1

1. Preparation of Crosslinkable Resin Composition for Laser Engraving

A three-necked flask equipped with a stirring blade and a cooling tube was charged with 5 parts by mass of Lucentite SPN (manufactured by Co-op Chemical Co., Ltd.) as the specific complex (A), 50 parts by mass of “DENKA BUTYRAL #3000-2” (trade name, manufactured by Denki Kagaku Kogyo Co., Ltd.; polyvinyl butyral derivative, Mw=90,000) as the specific binder polymer (B), 1 part by mass of KETJENBLACK EC600JD (trade name, manufactured by Lion Corp.; carbon black) as the photothermal conversion agent (E), and 47 parts by mass of propylene glycol monomethyl ether acetate as the solvent, and the mixture was heated at 70° C. for 120 minutes while the mixture was stirred, to thereby dissolve the polymer. Subsequently, the solution was cooled to 40° C., and 15 parts by mass of an ethylenically unsaturated monomer M-1 (having a structure shown below) as the polymerizable compound (C) (polyfunctional substance), 33 parts by mass of BLEMMER PME-1000 (trade name, manufactured by NOF Corporation) as the polymerizable compound (C) (monofunctional substance), and 1 part by mass of PERBUTYL Z (trade name, manufactured by NOF Corporation) as the polymerization initiator (D) were added to the solution. The mixture was stirred for 30 minutes, and thus a coating liquid for crosslinkable relief forming layer 1 (resin composition for laser engraving) having fluidity was obtained.

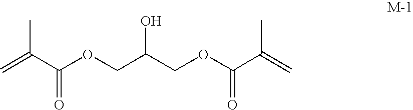

2. Preparation of Relief Printing Plate Precursor for Laser Engraving

A spacer having a predetermined thickness was provided on a PET substrate to form a frame, and the coating solution 1 for the crosslinkable relief forming layer obtained as described was quietly cast into the frame to such an extent as not flowing out of the spacer and dried in an oven at 80° C. for 3 hours to dispose a relief forming layer of about 1 mm thickness.

Furthermore, a protective film (a PET sheet processed by a sandblasting method to impart a surface roughness Ra=0.3 μm) was provided on the surface of the relief forming layer, and thus a relief printing plate precursor for laser engraving 1 was obtained.

3. Preparation of Relief Printing Plates

The relief forming layer in the relief printing plate precursor 1 thus obtained was subjected to a thermal crosslinking treatment by heating at 120° C. for 2.5 hours, and thus a thermally crosslinked relief forming layer was formed.

The relief forming layer after crosslinking was subjected to engraving by the following two types of laser lights, and thereby a relief printing plate 1 was produced.

As for the first laser, engraving by laser irradiation was performed using a high definition CO₂ laser marker ML-9100 series (manufactured by Keyence Corp.) as a carbon dioxide laser engraving machine. First, the protective film was peeled off from the relief printing plate precursor for laser engraving, and then raster engraving was performed on a solid image part which measured 1 cm on each of the four edges, with the carbon dioxide laser engraving machine under the conditions of an output power of 12 W, a head speed of 200 mm/second, and a pitch setup of 2400 DPI. (The results obtained by an evaluation using this first laser will be indicated as “CO₂ laser” in the table shown below.)

As for the second laser, the above-described laser recording device shown in FIG. 1 was used, which was equipped with a fibered semiconductor laser (FC-LD), SDL-6390 (trade name, manufactured by JDSU Corp.; wavelength: 915 nm), having a maximum output power of 8.0 W, as the semiconductor laser engraving machine. Raster engraving was performed on a solid image part which measured 1 cm on each of the four edges, with the semiconductor laser engraving machine under the conditions of a laser output power of 7.5 W, a head speed of 409 mm/second, and a pitch setup of 2400 DPI. (The results obtained by an evaluation using this second laser will be indicated as “FC-LD” in the table shown below.)

As such, relief layers were formed using the two types of lasers, and thus a relief printing plate 1 was obtained for each relief layer.

The thickness of the relief layer of the relief printing plate 1 was appropriately 1 mm.

The Shore A hardness of the relief layer was measured by the measurement method previously described, and was found to be 75°.

### Example 2 to 17, Comparative Examples 1 to 4

1. Preparation of Crosslinking Resin Compositions for Laser Engraving

Coating liquids for relief forming layer 2 to 15 of Examples 2 to 17, and coating liquids for relief forming layer C1 to C4 (resin composition for laser engraving) of Comparative Examples 1 to 4 were prepared in the same manner as in Example 1, except that the specific complex (A), the specific binder polymer (B), the polymerizable compound (C), the polymerization initiator (D), and photothermal conversion agent (E), that had been used in Example 1 were replaced as indicated respectively in Table 2.

Details of the specific complex (A) and the comparative compound, the specific binder polymer (B)and the comparative binder polymer, the polymerization initiator (C), the polymerizable compound (D), and the photothermal conversion agent (E), that were used in the respective Examples and Comparative Examples as indicated in Table 2 are as follows.

(A) Specific Complex and Comparative Layered Inorganic Compound

Lucentite SPN: swellable synthetic smectite (trade name, complex with an alkyl ammonium salt) manufactured by Co-op Chemical Co., Ltd.

Lucentite SEN: swellable synthetic smectite (trade name, complex with an alkyl ammonium salt) manufactured by Co-op Chemical Co., Ltd.

Lucentite STN: swellable synthetic smectite (trade name, complex with an alkyl ammonium salt) manufactured by Co-op Chemical Co., Ltd.

Lucentite SAN: swellable synthetic smectite (trade name, complex with an alkyl ammonium salt) manufactured by Co-op Chemical Co., Ltd. Lucentite STN: swellable synthetic smectite (trade name, complex with an alkyl ammonium salt) manufactured by Co-op Chemical Co., Ltd.

Somasif MEE: swellable synthetic mica (trade name, complex with an alkyl ammonium salt) manufactured by Co-op Chemical Co., Ltd.

Somasif MTE: swellable synthetic mica (trade name, complex with an alkyl ammonium salt) manufactured by Co-op Chemical Co., Ltd.

Somasif MAE: swellable synthetic mica (trade name, complex with an alkyl ammonium salt) manufactured by Co-op Chemical Co., Ltd.

Micromica MK-100: non-swellable synthetic mica (trade name, complex with an inorganic salt) manufactured by Co-op Chemical Co., Ltd.

Somasif ME-100: swellable synthetic mica (trade name, complex with an inorganic salt) manufactured by Co-op Chemical Co., Ltd.

(B) Specific Binder Polymer and Comparative Binder Polymer

Binder 1: Denka Butyral #3000-2 (trade name, polyvinyl butyral manufactured by Denki Kagaku Kogyo Kabushiki Kaisha; Mw=90,000, Tg: 20° C. or more)

Binder 2: Toresin F-30K (trade name, methoxymethylated polyamide manufactured by Nagase Chemtex Corporation, Tg: 20° C. or more)

Binder 3: Biroechol BE-400 (trade name, polylactic acid derivative manufactured by Toyobo, Tg: 20° C. or more)

Binder 4: Ethyl Cellulose 45 (trade name, cellulose derivative manufactured by Wako Pure Chemical Industries, Ltd., Tg: 20° C. or more)

Binder 5: Blemmer PME100/methyl methacrylate (10/90 (molar ratio)) copolymer (Mw=32,000; acrylic resin having a hydrophilic group in a side chain, Tg: 20° C. or more)

SBR: TR2000(trade name, manufactured by JSR Corporation)

Polymerizable Compound (C)

M-1: Ethylenically unsaturated monomer (having a above described structure)

M-2: Ethylenically unsaturated monomer (having a structure shown below)

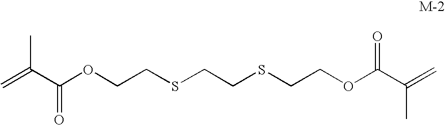

Polymerization Initiator (D)

Perbutyl Z (trade name, manufactured by NOF Corporation, organic peroxide)

Perhexyl E (trade name, manufactured by NOF Corporation, organic peroxide)

Perhexyl I (trade name, manufactured by NOF Corporation, organic peroxide)

V-601 (trade name, manufactured by Wako Pure Chemical Industries,

Ltd.2,2′-dimethyl azobisisobutyrate)

Photothermal Conversion Agent (E)

Carbon black: Ketchen Black EC600JD (trade name, manufactured by Lion Corporation)

ADS-800HO (trade name, manufactured by American Dye Source)

2. Preparation of Relief Printing Plate Precursors for Laser Engraving

Relief printing plate precursors for laser engraving 2 to 17 of Examples and relief printing plate precursors for laser engraving C1 to C4 of Comparative Examples were obtained in the same manner as in Example 1, except that the coating liquid for crosslinkable relief forming layer 1 in Example 1 was changed to the coating liquids for crosslinkable relief forming layer 2 to 17 and the coating liquids for crosslinkable relief forming layer C1 to C4, respectively.

3. Preparation of Relief Printing Plates

Relief printing plates 2 to 17 of Examples, and relief printing plates C1 to C4 of Comparative Examples were obtained by engraving the relief forming layers of the relief printing plate precursors for laser engraving 2 to 17 of Examples and the relief printing plate precursors for laser engraving C1 to C4 of Comparative Examples in the same manner as in Example 1 to form relief layers.

The thickness of the relief layers of these relief printing plates was approximately 1 mm.

Measurement of the Shore A hardness of the relief layers in the respective relief printing plates obtained was carried out in the same manner as in Example 1. The measured Shore A hardness values are shown in Table 2.

4. Physical Properties of the Binder Polymer used in Preparation of the Relief Forming Layer

The binders 1 to 5 (i.e. binders that is insoluble in water and soluble in an alcohol having 1 to 4 carbon atoms) used in Examples and Comparative Examples were evaluated for their properties. The results are listed in Tables 1. Whether these binder polymers are non-elastomers having a glass transition temperature not lower than room temperature (20° C.) or elastomers having a glass transition temperature lower than room temperature (20° C.) are also shown in Table 1.

(4-1) Water Swelling Property

A film having a thickness of 1 mm was formed using each of the sample binder polymer. 5 g of the film was taken as a test sample, and the test sample was immersed in water at 25° C. for 24 hours at room temperature. Thereafter, the test sample was taken out, and weighed after drying at 100° C. for 5 hours.

The ratio of the sample weight measured after the immersion to that measured before the immersion was calculated with setting the sample weight measured before the immersion as 100%. The larger the value is, the more elution of the relief forming layer into water caused by swelling was prevented, indicating its excellence in the resistance to water.

(4-2) Alcohol Solubility

### (4-2-1) Methanol Solubility (Solubility in Alcohol Having One Carbon Atom)

0.1 g of a powdery binder polymer was mixed with 2 ml of methanol, allowed to stand in a container with a cap thereon at room temperature for 24 hours. Thereafter, the solution was visually observed and graded according to the following criteria.

Soluble: The solution (dispersion) contains no precipitate of the binder polymer, and is transparent and uniform.

Insoluble: The solution (dispersion) contains precipitates of the binder polymer, or is cloudy.

### (4-2-2) Ethanol Solubility (Solubility in Alcohol Having Two Carbon Atoms)

Ethanol solubility was evaluated in the same manner as in the evaluation of methanol solubility, except that ethanol was used in place of methanol.

(4-2-3) 1-methoxy-2-propanol Solubility (Solubility in Alcohol Having Four Carbon Atoms)

1-methoxy-2-propanol solubility was evaluated in the same manner as in the evaluation of methanol solubility, except that 1-methoxy-2-propanol was used in place of methanol.

### (4-3) Ethyl Acetate Swelling Property

A film having a thickness of 1 mm was formed using each of the sample binder polymer. 5 g of the film was taken as a test sample, and the test sample was immersed in ethyl acetate at 25° C. for 24 hours at room temperature. Thereafter, the sample was taken out, and weighed after drying at 80° C. for 3 hours.

The ratio of the sample weight measured after the immersion to that measured before the immersion was calculated with setting the sample weight measured before the immersion as 100%. The larger the value is, the more elution of the relief forming layer caused by swelling of the relief forming layer with ethyl acetate was prevented, indicating its excellence in the resistance to solvent.

TABLE 1

| | | | Weight | | | | |
|---|---|---|---|---|---|---|---|
| | | Glass | after water | | | 1-Methoxy-2- | Weight after |
| | | Transition | immersion | Methanol | Ethanol | Propanol | Ethyl Acetate |
| | (B) Specific Binder Polymer | Temperature | (%) | Solubility | Solubility | Solubility | immersion(%) |
| Binder 1 | #3000-2 | 20° C. or | 97 | soluble | soluble | soluble | 95 |
| | | higher | | | | | |
| Binder 2 | Toresin F-30K | 20° C. or | 96 | soluble | soluble | soluble | 98 |
| | | higher | | | | | |
| Binder 3 | Biroechol BE-400 | 20° C. or | 93 | soluble | soluble | soluble | 92 |
| | | higher | | | | | |
| Binder 4 | Ethyl Cellulose 45 | 20° C. or | 90 | soluble | soluble | soluble | 91 |
| | | higher | | | | | |
| Binder 5 | Blemmer PME100/methyl | 20° C. or | 86 | insoluble | soluble | soluble | 84 |
| | methacrylate | higher | | | | | |

5. Thermal Degradability of the Specific Binder Polymer Used in the Relief Forming Layer

Evaluation samples prepared as described below were used to measure the thermal decomposition temperatures of the binder polymers used in the relief forming layers in the Examples and Comparative Examples. A change in the thermal degradability of the specific binder polymer due to its use in combination with the specific complex or the comparative layered compound was confirmed.

(Preparation of Evaluation Samples)

0.95 g of the specific binder polymer (B) used in the preparation of the crosslinking resin composition for laser engraving, and 0.05 g of the specific complex (A) or the comparative layered compound, were dissolved in 10 g of ethanol, then introduced into an aluminum cup and dried for 3 hours in an oven at 100° C. under reduced pressure. The resulting solids were used as the evaluation samples corresponding to the Examples and Comparative Examples.

(Measurement of Thermal Decomposition Temperature)

7 mg of each evaluation sample obtained above was heated at an increasing temperature of 20° C/min. from 30° C. to 500° C. with a thermogravimetric measurement instrument (manufactured by T. A. Instrument Japan), to determine the thermal decomposition initiation temperature, and this measurement value was determined as the thermal decomposition temperature. The “thermal decomposition initiation temperature” means a temperature at which the weight of the resin is reduced by 10% due to the thermal decomposition thereof by heating.

The thermal decomposition temperatures thus determined are shown in the columns in the Examples and Comparative Examples corresponding to the combination of the specific binder polymer and the specific complex or the comparative layered compound in Table 2. As shown in Table 2, it was confirmed that the combined use of the specific binder polymer and the specific complex lowered the thermal decomposition temperature of the specific binder polymer.

6. Evaluation of the Relief Printing Plates

### 6-1. Evaluation of Engraving Sensitivity

The “engraved depth” of the relief layer obtained by laser-engraving the relief forming layer of each of the relief printing plate precursors 1 to 17 and C1 to C4 was measured in the following manner. The “engraved depth” refers to the difference between the engraved position (height) and the non-engraved position (height) when a section of the relief layer was observed. The “engraved depth” in this example was measured by observing a section of the relief layer with an ultra-depth color 3-D shape measuring microscope VK9510 (manufactured by KEYENCE). Greater engraved depth is indicative of higher engraving sensitivity. Table 2 shows the results by each type of laser used in engraving.

6-2. Evaluation of Removability (Rinsing Property) of Engraving Residue

The printing plate engraved in each of the Examples and Comparative Examples was immersed in water, and the engraved portion was rubbed 10 times with a toothbrush (Clinica Toothbrush (flat) manufactured by Lion Corporation). Thereafter, it was confirmed whether or not residue remained on the surface of the relief layer under an optical microscope. Evaluation was performed such that A was given when residue was not present, B was given when residue hardly existed, C was given when residue remained slightly, and D was given when residue could not be removed.

In this evaluation, the same result was obtained regardless of whichever of the 2 lasers had been used in engraving.

The results are shown in Table 2.

TABLE 2

| | Composition of Relief Forming Layer | | | | |
|---|---|---|---|---|---|
| | | (B) Specific | | | |
| | (A) Specific | binder | | | |
| | Complex or | polymer or | | (D) | (E) |
| | comparative | comparative | (C) | (Multifunctional) | Photothermal |
| | layered inorganic | binder | Polymerization | polymerizable | conversion |
| | compound | polymer | initiator | compound | agent |
| Example 1 | Lucentite SPN | Binder 1 | Perbutyl Z | M-1 | carbon black |
| Example 2 | Lucentite SPN | Binder 1 | Perbutyl Z | M-2 | carbon black |
| Example 3 | Lucentite SPN | Binder 1 | Perbutyl Z | M-1 | ADS820HO |
| Example 4 | Lucentite SPN | Binder 2 | Perbutyl Z | M-1 | carbon black |
| Example 5 | Lucentite SPN | Binder 3 | Perbutyl Z | M-1 | carbon black |
| Example 6 | Lucentite SPN | Binder 4 | Perbutyl Z | M-1 | carbon black |
| Example 7 | Lucentite SPN | Binder 5 | Perbutyl Z | M-1 | carbon black |
| Example 8 | Lucentite SEN | Binder 1 | Perhexyl E | M-2 | carbon black |
| Example 9 | Lucentite STN | Binder 1 | Perhexyl E | M-2 | carbon black |
| Example 10 | Lucentite SAN | Binder 1 | Perhexyl E | M-2 | carbon black |
| Example 11 | Somasif MPE | Binder 1 | Perhexyl E | M-2 | carbon black |
| Example 12 | Somasif MEE | Binder 1 | Perhexyl I | M-2 | carbon black |
| Example 13 | Somasif MTE | Binder 1 | Perhexyl I | M-2 | carbon black |
| Example 14 | Somasif MAE | Binder 1 | Perhexyl I | M-2 | carbon black |
| Example 15 | Somasif MAE | Binder 1 | V-601 | M-2 | carbon black |
| Example 16 | Lucentite SPN | Binder 1 | none | none | none |
| Example 17 | Lucentite SPN | Binder 1 | Perbutyl Z | M-1 | none |
| Comparative | Micromica | Binder 1 | Perbutyl Z | M-2 | carbon black |
| Example 1 | MK-100 | | | | |
| Comparative | Somasif | Binder 1 | Perbutyl Z | M-2 | carbon black |
| Example 2 | ME-100 | | | | |
| Comparative | none | Binder 1 | Perbutyl Z | M-2 | carbon black |
| Example 3 | | | | | |
| Comparative | SBR | Binder 1 | Perbutyl Z | M-2 | carbon black |
| Example 4 | | | | | |

| | Evaluation Results | | | | |
|---|---|---|---|---|---|
| | Rinsing | Thermal | | | |
| | property of | decomposition | Engraved | Engraved | Shore A |
| | engraving | initiation | depth (μm) | depth (μm) | hardness |
| | residue | temperature (° C.) | (CO₂ laser) | (FC-LD) | (°) |
| Example 1 | A | 342 | 270 | 320 | 75 |
| Example 2 | A | 335 | 285 | 335 | 78 |
| Example 3 | A | 345 | 250 | 300 | 70 |
| Example 4 | B | 380 | 240 | 290 | 72 |
| Example 5 | B | 350 | 250 | 300 | 81 |
| Example 6 | B | 240 | 290 | 340 | 80 |
| Example 7 | B | 220 | 293 | 343 | 83 |
| Example 8 | A | 330 | 285 | 335 | 69 |
| Example 9 | A | 332 | 285 | 335 | 70 |
| Example 10 | A | 335 | 282 | 332 | 78 |
| Example 11 | A | 358 | 260 | 310 | 78 |
| Example 12 | A | 356 | 261 | 311 | 75 |
| Example 13 | A | 360 | 258 | 308 | 77 |
| Example 14 | A | 355 | 256 | 306 | 76 |
| Example 15 | A | 355 | 255 | 305 | 74 |
| Example 16 | B | 340 | 260 | 0 | 65 |
| Example 17 | B | 342 | 250 | 0 | 70 |
| Comparative | D | 374 | 250 | 280 | 74 |
| Example 1 | | | | | |
| Comparative | C | 355 | 255 | 290 | 74 |
| Example 2 | | | | | |
| Comparative | D | 374 | 250 | 280 | 65 |
| Example 3 | | | | | |
| Comparative | C | 400 | 180 | 200 | 64 |
| Example 4 | | | | | |

As shown in Table 2, the relief printing plates in the Examples, having a relief layer containing the specific complex (A) and the specific binder polymer (B), have large engraved depth, by which the resin compositions for laser engraving prepared in the Examples could be confirmed to have high engraving sensitivity. Further, it can be seen that the relief printing plate precursors in the Examples, when engraved to prepare relief printing plates, have an excellent ability to rinse off engraving residue, as compared with the relief printing plates in the Comparative Examples.

All publications, patent applications, and technical standards mentioned in this specification are herein incorporated by reference to the same extent as if each individual publication, patent application, or technical standard was specifically and individually indicated to be incorporated by reference.

What is claimed is:

1. A resin composition for laser engraving, comprising at least a complex formed between a layered inorganic compound and a cationic organic compound, and a binder polymer that is insoluble in water and soluble in an alcohol having 1 to 4 carbon atoms.

2. The resin composition for laser engraving of claim 1, wherein the glass transition temperature (Tg) of the binder polymer that is insoluble in water and soluble in an alcohol having 1 to 4 carbon atoms is 20° C. to 200° C.

3. The resin composition for laser engraving of claim 1, wherein the binder polymer that is insoluble in water and soluble in an alcohol having 1 to 4 carbon atoms is at least one polymer selected from the group consisting of polyester, polyurethane, polyvinyl butyral, and polyamide.

4. The resin composition for laser engraving of claim 1, wherein the binder polymer that is insoluble in water and soluble in an alcohol having 1 to 4 carbon atoms is at least one polymer selected from the group consisting of a polyester including a hydroxylcarboxylic acid unit and a derivative thereof, polycaprolactone (PCL) and a derivative thereof, poly(butylenesuccinic acid) and a derivative thereof, polyvinyl butyral and a derivative thereof, and a polyamide having a polar group introduced into its main chain.

5. The resin composition for laser engraving of claim 1, further comprising a polymerizable compound.

6. The resin composition for laser engraving of claim 1, further comprising a polymerization initiator.

7. The resin composition for laser engraving of claim 6, wherein the polymerization initiator is selected from the group consisting of an aromatic ketone, an onium salt compound, an organic peroxide, a thio compound, a hexaaryl biimidazole compound, a ketoxime ester compound, a borate compound, an azinium compound, a metallocene compound, an active ester compound, a compound having a carbon-halogen bond, and an azo compound.

8. The resin composition for laser engraving of claim 6, wherein the polymerization initiator is an organic peroxide.

9. The resin composition for laser engraving of claim 1, further comprising a photothermal conversion agent which absorbs light having a wavelength of from 700 nm to 1300 nm.

10. The resin composition for laser engraving of claim 9, wherein the photothermal conversion agent is carbon black.

11. A relief printing plate precursor for laser engraving, having a relief forming layer containing the resin composition for laser engraving of claim 1.

12. A method of producing a relief printing plate, the method comprising:
crosslinking the relief forming layer in the relief printing plate precursor for laser engraving of claim 11 by applying light or heat, and
laser engraving the relief forming layer that has been subjected to crosslinking to form a relief layer.

13. A relief printing plate having a relief layer, the relief layer being produced by the method of producing a relief printing plate of claim 12.

14. The relief printing plate of claim 13, wherein the thickness of the relief layer is 0.05 mm to 10 mm.

15. The relief printing plate of claim 13, wherein the Shore A hardness of the relief layer is 50° to 90°.
